(19) United States
(12) Patent Application Publication
(10) Pub. No.: US 2026/0305158 A1
(43) Pub. Date: Oct. 1, 2026

(54) ORGANIC ELECTROLUMINESCENT MATERIAL AND DEVICE THEREOF

(71) Applicant: BEIJING SUMMER SPROUT TECHNOLOGY CO., LTD., Beijing (CN)

(72) Inventors: Chunliang Zhao, Beijing (CN); Liuhuan Cai, Beijing (CN); Ming Sang, Beijing (CN); Xuechao Tian, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 19/576,798

(22) Filed: Mar. 24, 2026

(30) Foreign Application Priority Data
Mar. 27, 2025 (CN) 202510375442.2

(51) Int. Cl. H10K 85/30; C07F 15/00; C09K 11/02; C09K 11/06; H10K 50/11

(52) U.S. Cl. CPC H10K 85/346; C07F 15/0086; C09K 11/02; C09K 11/06; C09K 2211/1007; C09K 2211/1014; C09K 2211/1022; C09K 2211/1029; C09K 2211/1044; C09K 2211/1088; C09K 2211/185; H10K 50/11

(57) ABSTRACT

Provided are an organic electroluminescent material and device thereof. The organic electroluminescent material is a compound having a structure of Formula 1. These new compounds may be used as light-emitting materials in organic electroluminescent devices and can provide better device performance such as improved current efficiency and power efficiency. Further provided are an organic electroluminescent device comprising a compound having a structure of Formula 1 and a compound composition comprising a compound having a structure of Formula 1.

### CROSS-REFERENCE TO RELATED APPLICATION(S)

This application claims priority to Chinese Patent Application No. 202510375442.2 filed on Mar. 27, 2025, the disclosure of which is incorporated herein by reference in its entirety.

### TECHNICAL FIELD

The present disclosure relates to compounds for organic electronic devices such as organic light-emitting devices. In particular, the present disclosure relates to a compound having a specific structure, an organic electroluminescent device comprising the compound and a compound composition comprising the compound.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

CN113201019A discloses a guest metal light-emitting material including a ligand L_{A}

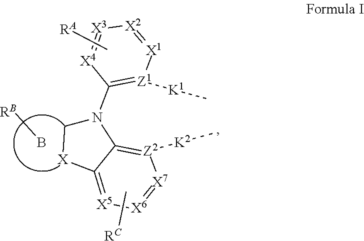

wherein at least two of adjacent X¹ to X³ are C and are fused with the structure

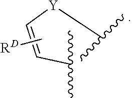

CN113201019A further discloses that the compound has a general formula [L_{A}]Pt[L_{B}]

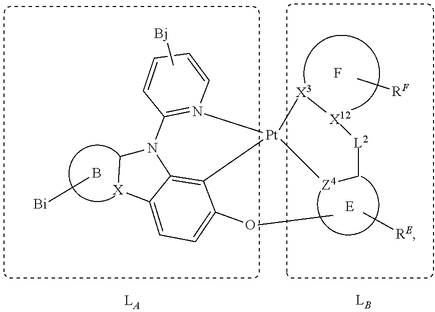

wherein the ligand L_{B} may be selected from a structure such as

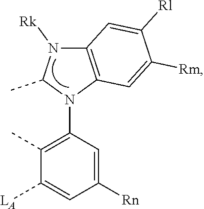

and Rk may be selected from structures including

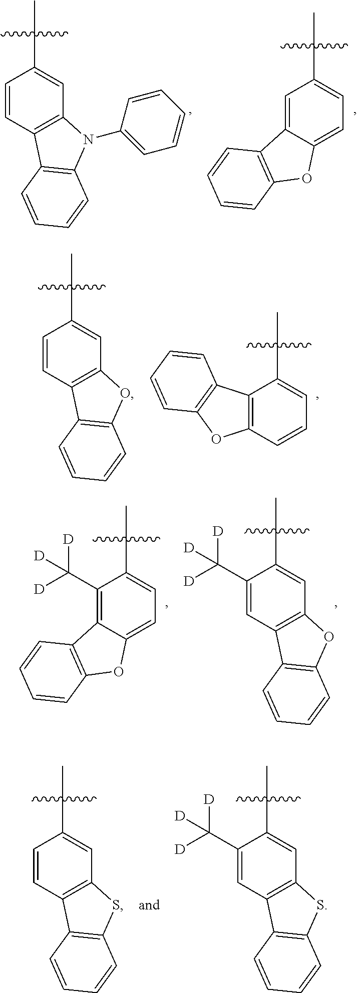

The DBX (dibenzofuran, dibenzothiophene, or carbazole) of the aforementioned Rk structure disclosed therein has no substituents or has only deuterated methyl. CN113201019A does not disclose metal complexes where specific positions of the DBX structure have other specific substituents, nor does it disclose or teach the excellent effects of such metal complexes when used in devices.

The existing art discloses some research on blue phosphorescent luminescent materials for use in blue phosphorescent devices. However, in the study of blue light devices, there are still certain limitations in terms of device efficiency and color saturation. Therefore, the application potential of such materials warrants further research and development.

### SUMMARY

The present disclosure aims to provide a series of compounds each having a structure of Formula 1 to solve at least part of the aforementioned problems. These compounds may be used as light-emitting materials in organic electroluminescent devices. These new compounds can provide better device performance such as improved current efficiency and power efficiency. These advantages are of great help in improving the level of blue phosphorescent devices.

According to an embodiment of the present disclosure, disclosed is a compound having a structure of Formula 1:

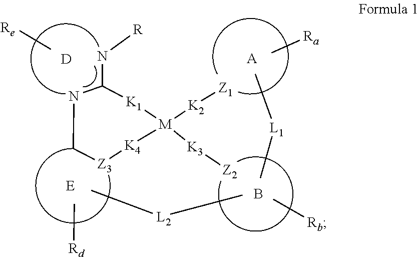

wherein in Formula 1,
the metal M is selected from a metal with a relative atomic mass greater than 40;
the ring A, the ring B and the ring E are, at each occurrence identically or differently, selected from an unsaturated carbocyclic ring having 5 to 30 carbon atoms, an unsaturated heterocyclic ring having 3 to 30 carbon atoms or a combination thereof; and the ring D is selected from an unsaturated heterocyclic ring having 3 to 30 carbon atoms;
L₁ and L₂ are, at each occurrence identically or differently, selected from a single bond, O, S, Se, (CR′R′)_{y}, (SiR′R′)_{y}, PR′, NR′, substituted or unsubstituted arylene having 6 to 30 carbon atoms, substituted or unsubstituted heteroarylene having 3 to 30 carbon atoms or a combination thereof; y is, at each occurrence identically or differently, selected from 0, 1, 2, 3, 4 or 5; and when a plurality of R′ are present at the same time, the plurality of R′ are identical or different;
K₁ to K₄ are, at each occurrence identically or differently, selected from a single bond, O or S;
Z₁ to Z₃ are, at each occurrence identically or differently, selected from C or N;
the substituent R in Formula 1 has a structure represented by Formula 2:

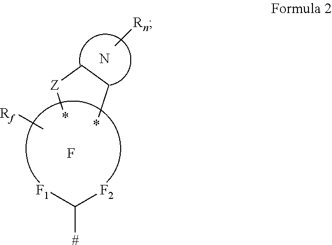

wherein in Formula 2,
“#” represents a position where Formula 2 is joined;
the ring F and the ring N are, at each occurrence identically or differently, selected from an aromatic ring having 6 to 30 carbon atoms, a heteroaromatic ring having 3 to 30 carbon atoms or a combination thereof;
there are two ring atoms that are directly bonded in the ring F, and they are carbon atoms and are connected to two “*”, respectively;
Z is selected from NR_{z}, O, S or Se;
F₁ and F₂ are each independently selected from CR_{f1}, CR_{F} or N, at least one of F₁ and F₂ is selected from CR_{f1}, and R_{f1} is identically or differently selected from the group consisting of: substituted or unsubstituted aryl having 6 to 30 carbon atoms, substituted or unsubstituted heteroaryl having 3 to 30 carbon atoms and combinations thereof;
Rₐ, R_{b}, R_{d}, Rₑ, R_{f} and Rₙ represent, at each occurrence identically or differently, mono-substitution, multiple substitutions or non-substitution;
R′, Rₐ, R_{b}, R_{d}, Rₑ, R_{f}, R_{F}, Rₙ and R_{z} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R′, Rₐ, R_{b}, R_{d}, Rₑ, R_{f}, R_{F}, R_{f1}, Rₙ and R_{z} can be optionally joined to form a ring.

According to an embodiment of the present disclosure, disclosed is an electroluminescent device, which comprises an anode, a cathode and an organic layer disposed between the anode and the cathode, wherein the organic layer comprises the compound having a structure of Formula 1.

According to an embodiment of the present disclosure, disclosed is a compound composition, which comprises the compound having a structure of Formula 1.

The present disclosure discloses a series of compounds each having a structure of Formula 1. These compounds may be used as light-emitting materials in organic electroluminescent devices. These new compounds can provide better device performance such as improved current efficiency and power efficiency. These advantages are of great help in improving the level of blue phosphorescent devices.

### BRIEF DESCRIPTION OF DRAWINGS

FIG. 1 is a schematic diagram of an organic light-emitting apparatus that may include a compound and a compound composition disclosed herein.

FIG. 2 is a schematic diagram of another organic light-emitting apparatus that may include a compound and a compound composition disclosed herein.

### DETAILED DESCRIPTION

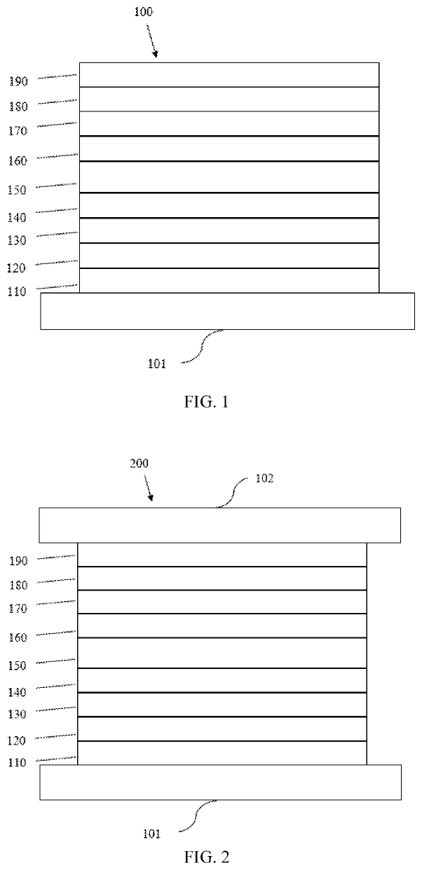

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device includes a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e., P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as the temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in a small AES-T. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, an n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc., means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g., phenyl, phenylene, naphthyl, dibenzofuryl) or as if it were the whole molecule (e.g., benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to their enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions, etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fused cyclic, etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

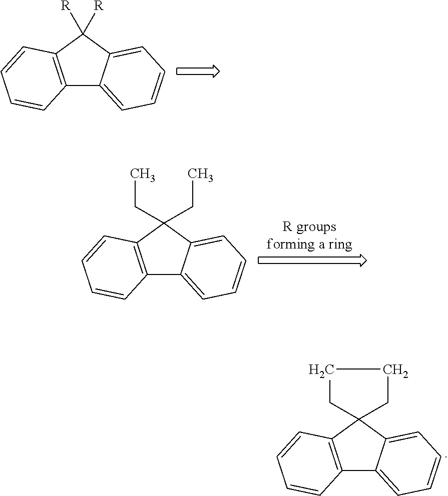

The expression that adjacent substituents can be optionally joined to form a ring is also intended to mean that two substituents bonded to carbon atoms which are directly bonded to each other are joined to each other via a chemical bond to form a ring, which can be exemplified by the following formula:

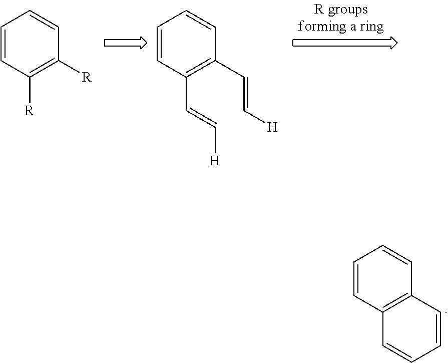

The expression that adjacent substituents can be optionally joined to form a ring is also intended to mean that two substituents bonded to further distant carbon atoms are joined to each other via a chemical bond to form a ring, which can be exemplified by the following formula:

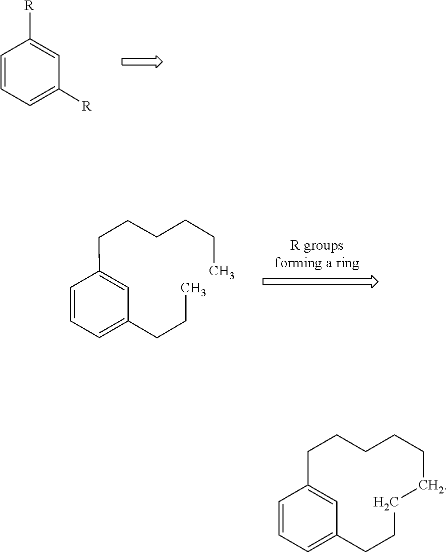

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

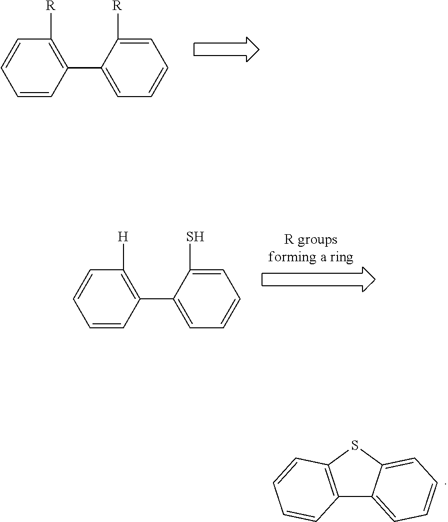

According to an embodiment of the present disclosure, disclosed is a compound having a structure of Formula 1:

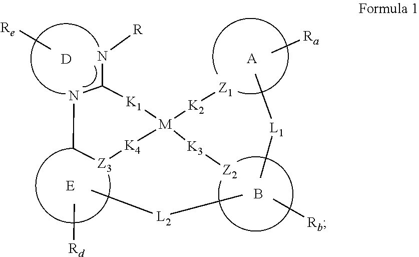

wherein in Formula 1,
the metal M is selected from a metal with a relative atomic mass greater than 40;
the ring A, the ring B and the ring E are, at each occurrence identically or differently, selected from an unsaturated carbocyclic ring having 5 to 30 carbon atoms, an unsaturated heterocyclic ring having 3 to 30 carbon atoms or a combination thereof; and the ring D is selected from an unsaturated heterocyclic ring having 3 to 30 carbon atoms;
L₁ and L₂ are, at each occurrence identically or differently, selected from a single bond, O, S, Se, (CR′R′)_{y}, (SiR′R′)_{y}, PR′, NR′, substituted or unsubstituted arylene having 6 to 30 carbon atoms, substituted or unsubstituted heteroarylene having 3 to 30 carbon atoms or a combination thereof; y is, at each occurrence identically or differently, selected from 0, 1, 2, 3, 4 or 5; and when a plurality of R′ are present at the same time, the plurality of R′ are identical or different;
K₁ to K₄ are, at each occurrence identically or differently, selected from a single bond, O or S;
Z₁ to Z₃ are, at each occurrence identically or differently, selected from C or N;
the substituent R in Formula 1 has a structure represented by Formula 2:

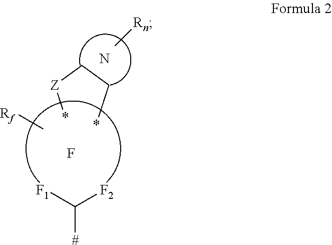

wherein in Formula 2,
“#” represents a position where Formula 2 is joined;
the ring F and the ring N are, at each occurrence identically or differently, selected from an aromatic ring having 6 to 30 carbon atoms, a heteroaromatic ring having 3 to 30 carbon atoms or a combination thereof;
there are two ring atoms that are directly bonded in the ring F, and they are carbon atoms and are connected to two “*”, respectively;
Z is selected from NR_{z}, O, S or Se;
F₁ and F₂ are each independently selected from CR_{f1}, CR_{F} or N, at least one of F₁ and F₂ is selected from CR_{f1}, and R_{f1} is identically or differently selected from the group consisting of: substituted or unsubstituted aryl having 6 to 30 carbon atoms, substituted or unsubstituted heteroaryl having 3 to 30 carbon atoms and combinations thereof;
Rₐ, R_{b}, R_{d}, Rₑ, R_{f} and Rₙ represent, at each occurrence identically or differently, mono-substitution, multiple substitutions or non-substitution;
R′, Rₐ, R_{b}, R_{d}, Rₑ, R_{f}, R_{F}, Rₙ and R_{z} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R′, Rₐ, R_{b}, R_{d}, Rₑ, R_{f}, R_{F}, R_{f1}, Rₙ and R_{z} can be optionally joined to form a ring.

Herein, the expression that adjacent substituents R′, Rₐ, R_{b}, R_{d}, Rₑ, R_{f}, R_{F}, R_{f1}, Rₙ and R_{z} can be optionally joined to form a ring is intended to mean that any one or more of groups of adjacent substituents, such as two substituents R′, two substituents Rₐ, two substituents R_{b}, two substituents R_{d}, two substituents Rₑ, two substituents R_{f}, two substituents Rₙ, substituents R′ and Rₐ, substituents R′ and R_{b}, substituents R′ and R_{d}, substituents R_{z} and R_{f}, and substituents R_{z} and R_{F}, substituents R_{f} and R_{F}, substituents R_{z} and Rₙ, substituents R_{z} and R_{f1}, and substituents R_{f} and R_{f1}, can be joined to form a ring. Obviously, it is possible that none of these adjacent substituents are joined to form a ring.

According to an embodiment of the present disclosure, in Formula 2, the ring fused with the ring F is a heteroaromatic ring (a heteroaromatic group).

According to an embodiment of the present disclosure, in Formula 2, the ring fused with the ring F is a substituted or unsubstituted heteroaromatic ring having 3 to 30 carbon atoms, and the carbon atoms do not include carbon atoms in the ring F that are connected to two “*”.

According to an embodiment of the present disclosure, the compound has a structure represented by a general formula of M(Lₐ)(L_{b}), wherein Lₐ and L_{b} are a first ligand and a second ligand coordinated to the metal M, respectively; Lₐ has a structure represented by Formula A:

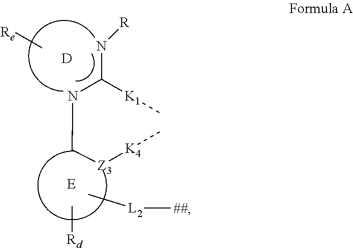

wherein in Formula A, “##” represents a position where L_{b} is joined; and L_{b} has a structure represented by Formula B:

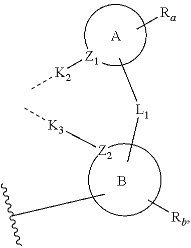

wherein in Formula B “ [symbol] ” represents a position where Lₐ is joined.

According to an embodiment of the present disclosure, the metal M is selected from the group consisting of Cu, Ag, Au, Ru, Rh, Pd, Os, Ir and Pt.

According to an embodiment of the present disclosure, the metal M is selected from Pt or Pd.

According to an embodiment of the present disclosure, the metal M is selected from Pt.

According to an embodiment of the present disclosure, the ring A, the ring B, the ring E, the ring F and the ring N are, at each occurrence identically or differently, selected from a five-membered unsaturated carbocyclic ring, an aromatic ring having 6 to 30 carbon atoms, a heteroaromatic ring having 3 to 30 carbon atoms or a combination thereof; and the ring D is selected from an unsaturated heterocyclic ring having 3 to 24 carbon atoms.

According to an embodiment of the present disclosure, the ring A, the ring B, the ring E, the ring F and the ring N are, at each occurrence identically or differently, selected from a five-membered unsaturated carbocyclic ring, an aromatic ring having 6 to 18 carbon atoms, a heteroaromatic ring having 3 to 18 carbon atoms or a combination thereof; and the ring D is selected from an unsaturated heterocyclic ring having 3 to 18 carbon atoms.

According to an embodiment of the present disclosure, the ring A, the ring B, the ring E, the ring F and the ring N are, at each occurrence identically or differently, selected from a benzene ring, a pyridine ring, an indene ring, a fluorene ring, an indole ring, a carbazole ring, an indolocarbazole ring, a benzofuran ring, a dibenzofuran ring, a benzosilole ring, a dibenzosilole ring, a benzothiophene ring, a dibenzothiophene ring, a dibenzoselenophene ring, a cyclopentadiene ring, a furan ring, a thiophene ring, a silole ring or a combination thereof; and the ring D is selected from an imidazolecarbene ring or a benzimidazolecarbene ring.

According to an embodiment of the present disclosure, the L₁ is selected from a single bond, O, S, (SiR′R′)_{y}, NR′ or a combination thereof; y is 1 or 2; and when a plurality of R′ are present at the same time, the plurality of R′ are identical or different.

According to an embodiment of the present disclosure, the L₁ is selected from a single bond, O or S.

According to an embodiment of the present disclosure, the L₁ is selected from a single bond.

According to an embodiment of the present disclosure, the K₁ to K₄ are selected from a single bond.

According to an embodiment of the present disclosure, the Z₁ is selected from N, and the Z₂ and Z₃ are selected from C.

According to an embodiment of the present disclosure, the compound has a structure represented by one of Formula 1-1 to Formula 1-5:

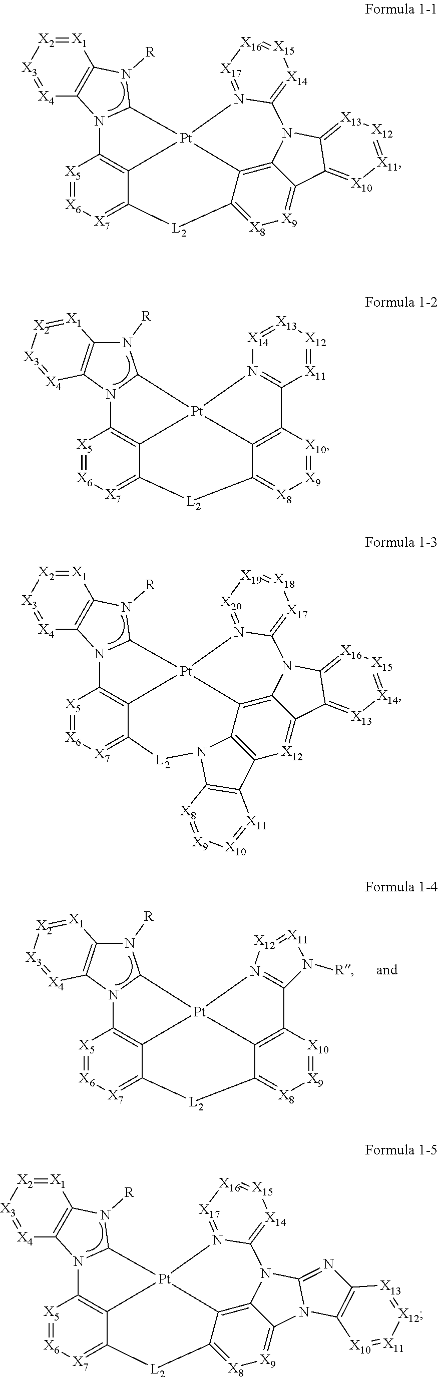

wherein, in Formula 1-1 to Formula 1-5, L₂ is, at each occurrence identically or differently, selected from a single bond, O, S, Se, (CR′R′)_{y}, (SiR′R′)_{y}, PR′, NR′, substituted or unsubstituted arylene having 6 to 30 carbon atoms, substituted or unsubstituted heteroarylene having 3 to 30 carbon atoms or a combination thereof; y is, at each occurrence identically or differently, selected from 0, 1, 2, 3, 4 or 5; when a plurality of R′ are present at the same time, the plurality of R′ are identical or different
X₁ to X₂₀ are, at each occurrence identically or differently, selected from CRₓ or N; the substituent R has a structure represented by Formula 3-1 or Formula 3-2:

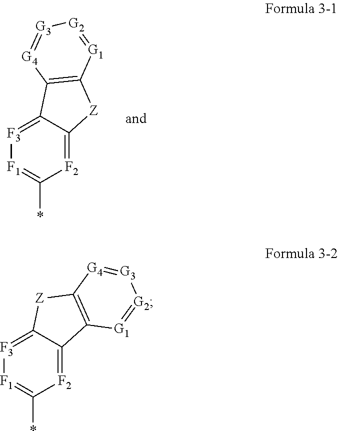

wherein in Formula 3-1 and Formula 3-2, F₁ and F₂ are each independently selected from CR_{f1}, CR_{F} or N, at least one of F₁ and F₂ is selected from CR_{f1}, and R_{f1} is identically or differently selected from the group consisting of: substituted or unsubstituted aryl having 6 to 30 carbon atoms, substituted or unsubstituted heteroaryl having 3 to 30 carbon atoms and combinations thereof;
F₃ is selected from CR_{f} or N;
G₁ to G₄ are each independently selected from CR_{g} or N;
Z is selected from NR_{z}, O, S or Se;
R′, R″, Rₓ, R_{f}, R_{F}, R_{g} and R_{z} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R′, R″, Rₓ, R_{f1}, R_{f}, R_{F}, R_{g} and R_{z} can be optionally joined to form a ring.

In this embodiment, the expression that adjacent substituents R′, R″, Rₓ, R_{f1}, R_{f}, R_{F}, R_{g} and R_{z} can be optionally joined to form a ring is intended to mean that any one or more of groups of adjacent substituents, such as two substituents R′, two substituents Rₓ, two substituents R_{g}, substituents R′ and Rₓ, substituents R″ and Rₓ, substituents R_{f} and R_{f1}, substituents R_{z} and R_{f1}, substituents R_{z} and R_{f}, substituents R_{z} and R_{F}, substituents R_{f} and R_{F}, and substituents R_{z} and R_{g}, can be joined to form a ring. Obviously, it is possible that none of these adjacent substituents are joined to form a ring.

According to an embodiment of the present disclosure, the compound has a structure represented by Formula 1-1.

According to an embodiment of the present disclosure, the compound has a structure represented by Formula 1-1, X₁₄ to X₁₇ in Formula 1-1 are, at each occurrence identically or differently, selected from CRₓ or N, and when adjacent substituents Rₓ are joined to form a ring, the formed ring has at least 6 ring atoms.

According to an embodiment of the present disclosure, the compound has a structure represented by Formula 1-1, X₁₄ to X₁₇ in Formula 1-1 are, at each occurrence identically or differently, selected from CRₓ or N, and the Rₓ cannot be joined to form a ring.

According to an embodiment of the present disclosure, the compound has a structure represented by Formula 1-5, X₁₄ to X₁₇ in Formula 1-5 are, at each occurrence identically or differently, selected from CRₓ or N, and when adjacent substituents Rₓ are joined to form a ring, the formed ring has at least 6 ring atoms.

According to an embodiment of the present disclosure, the compound has a structure represented by Formula 1-5, X₁₄ to X₁₇ in Formula 1-5 are, at each occurrence identically or differently, selected from CRₓ or N, and the Rₓ cannot be joined to form a ring.

According to an embodiment of the present disclosure, the L₂ is, at each occurrence identically or differently, selected from a single bond, O, S, (CR′R′)_{y}, (SiR′R′)_{y}, PR′, NR′ or a combination thereof; y is 1 or 2; and when a plurality of R′ are present at the same time, the plurality of R′ are identical or different.

According to an embodiment of the present disclosure, the L₂ is, at each occurrence identically or differently, selected from a single bond, O or S.

According to an embodiment of the present disclosure, the L₂ is selected from O.

According to an embodiment of the present disclosure, the substituent R has a structure represented by Formula 3-1.

According to an embodiment of the present disclosure, the Z is selected from O, S or Se.

According to an embodiment of the present disclosure, the Z is selected from O or S.

According to an embodiment of the present disclosure, the Z is selected from O.

According to an embodiment of the present disclosure, both F₁ and F₂ are selected from CR_{f1}, and the R_{f1} is identically or differently selected from the group consisting of: substituted or unsubstituted aryl having 6 to 30 carbon atoms, substituted or unsubstituted heteroaryl having 3 to 30 carbon atoms and combinations thereof.

According to an embodiment of the present disclosure, the R_{f1} is identically or differently selected from the group consisting of: substituted or unsubstituted aryl having 6 to 18 carbon atoms, substituted or unsubstituted heteroaryl having 3 to 18 carbon atoms and combinations thereof.

According to an embodiment of the present disclosure, the R_{f1} is identically or differently selected from the group consisting of: substituted or unsubstituted phenyl, substituted or unsubstituted carbazolyl, substituted or unsubstituted indolyl, substituted or unsubstituted benzofuryl, substituted or unsubstituted dibenzofuryl, substituted or unsubstituted benzosilolyl, substituted or unsubstituted dibenzosilolyl, substituted or unsubstituted benzothienyl, substituted or unsubstituted dibenzothienyl, substituted or unsubstituted dibenzoselenophenyl and combinations thereof.

According to an embodiment of the present disclosure, the R_{f1} is selected from substituted or unsubstituted phenyl.

According to an embodiment of the present disclosure, the R_{f1} is selected from deuterated phenyl.

According to an embodiment of the present disclosure, X₁ to X₂₀ are, at each occurrence identically or differently, selected from CRₓ.

According to an embodiment of the present disclosure, the F₃ is selected from CR_{f}.

According to an embodiment of the present disclosure, G₁ to G₄ are each independently selected from CR_{g}.

According to an embodiment of the present disclosure, the R′, R″, Rₓ, R_{f}, R_{F}, R_{g} and R_{z} are, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, the R′, R″, Rₓ, R_{f}, R_{F}, R_{g} and R_{z} are, at each occurrence identically or differently, selected from the group consisting of: hydrogen, deuterium, fluorine, methyl, deuterated methyl, ethyl, n-propyl, isopropyl, cyclopropyl, n-butyl, isobutyl, t-butyl, cyclopentyl, cyclohexyl, phenyl, trimethylsilyl, carbazolyl, indolyl, benzofuranyl, dibenzofuranyl, benzosilolyl, dibenzosilolyl, benzothienyl, dibenzothienyl, dibenzoselenophenyl and combinations thereof.

According to an embodiment of the present disclosure, the substituent R is, at each occurrence identically or differently, selected from the group consisting of An-1 to An-78, wherein the specific structures of An-1 to An-78 are referred to claim 12.

According to an embodiment of the present disclosure, hydrogens in the structures of An-1 to An-78 can be partially or fully substituted with deuterium.

According to an embodiment of the present disclosure, the compound has a structure represented by Pt(Lₐ)(L_{b}), wherein Lₐ and L_{b} are a first ligand and a second ligand coordinated to the metal Pt, respectively, Lₐ is selected from the group consisting of Lₐ1-1 to Lₐ1-16, Lₐ2-1 to Lₐ2-18, Lₐ3-1 to Lₐ3-16 and Lₐ4-1 to Lₐ4-18, and L_{b} is selected from the group consisting of L_{b}1-1 to L_{b}1-22, L_{b}2-1 to L_{b}2-30, L_{b}3-1 to L_{b}3-26, L_{b}4-1 to L_{b}4-25 and L_{b}5-1 to L_{b}5-11, wherein the specific structures of Lₐ1-1 to Lₐ1-16, Lₐ2-1 to Lₐ2-18, Lₐ3-1 to Lₐ3-16, Lₐ4-1 to Lₐ4-18, L_{b}1-1 to L_{b}1-22, L_{b}2-1 to L_{b}2-30, L_{b}3-1 to L_{b}3-26, L_{b}4-1 to L_{b}4-25 and L_{b}5-1 to L_{b}5-11 are referred to claim 13.

According to an embodiment of the present disclosure, the compound is selected from the group consisting of Compound Pt1 to Compound Pt668, wherein the specific structures of Compound Pt1 to Compound Pt668 are referred to claim 13.

According to an embodiment of the present disclosure, hydrogens in the structures of Compound Pt1 to Compound Pt668 can be partially or fully substituted with deuterium.

According to an embodiment of the present disclosure, disclosed is an electroluminescent device, which comprises:
an anode,
a cathode, and
an organic layer disposed between the anode and the cathode, wherein the organic layer comprises a compound having a structure of Formula 1, and the compound having the structure of Formula 1 is as shown in any one of the preceding embodiments.

According to an embodiment of the present disclosure, the organic layer is a light-emitting layer, and the compound is a light-emitting material.

According to an embodiment of the present disclosure, the organic layer may further comprise a second light-emitting material.

According to an embodiment of the present disclosure, the second light-emitting material is a fluorescent light-emitting material.

According to an embodiment of the present disclosure, the second light-emitting material is a delayed fluorescent material.

According to an embodiment of the present disclosure, the second light-emitting material is a boron-containing compound.

According to an embodiment of the present disclosure, the compound is a sensitizer, and the second light-emitting material is a light emitter.

According to an embodiment of the present disclosure, the device emits blue light.

According to an embodiment of the present disclosure, the device emits white light.

According to an embodiment of the present disclosure, the light-emitting layer comprises at least one host material.

According to an embodiment of the present disclosure, the light-emitting layer comprises at least two host materials.

According to an embodiment of the present disclosure, the host material comprises at least one chemical group selected from the group consisting of: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

According to an embodiment of the present disclosure, the light-emitting layer comprises a first host material and a second host material.

According to an embodiment of the present disclosure, the first host material has a structure represented by Formula 4:

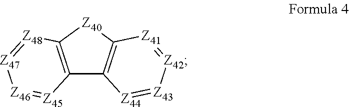

wherein in Formula 4,
Z₄₀ is selected from O or S;
Z₄₁ to Z₄₈ are, at each occurrence identically or differently, selected from CR₅, CR₅′ or N, at least one of Z₄₁ to Z₄₈ is selected from N, and at least one of Z₄₁ to Z₄₈ is selected from CR₅′;
R₅′ is, at each occurrence identically or differently, selected from substituted or unsubstituted aryl having 6 to 30 carbon atoms, substituted or unsubstituted heteroaryl having 3 to 30 carbon atoms or a combination thereof; and
R₅ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

According to an embodiment of the present disclosure, in Formula 4, at least one of Z₄₁ to Z₄₈ is selected from N, and at least two of Z₄₁ to Z₄₈ are selected from CR₅′.

According to an embodiment of the present disclosure, in Formula 4, only one of Z₄₁ to Z₄₈ is selected from N, and only two of Z₄₁ to Z₄₈ are selected from CR₅′.

According to an embodiment of the present disclosure, in Formula 4, Z₄₂ is selected from N, and Z₄₁ and Z₄₆ are selected from CR₅′.

According to an embodiment of the present disclosure, the first host material has a structure represented by Formula 5:

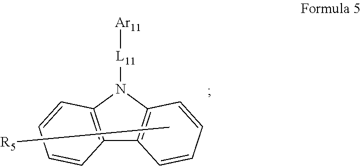

wherein L₁₁ is selected from a single bond, substituted or unsubstituted arylene having 6 to 30 carbon atoms, substituted or unsubstituted heteroarylene having 3 to 30 carbon atoms or a combination thereof;
Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;
R₅ represents, at each occurrence identically or differently, mono-substitution, multiple substitutions or non-substitution;
R₅ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₅ can be optionally joined to form a ring.

Herein, the expression that adjacent substituents R₅ can be optionally joined to form a ring is intended to mean that two substituents R₅ can be joined to form a ring. Obviously, it is also possible that two substituents R₅ are not joined to form a ring.

According to an embodiment of the present disclosure, the first host material has a structure represented by Formula 5-1 or Formula 5-2:

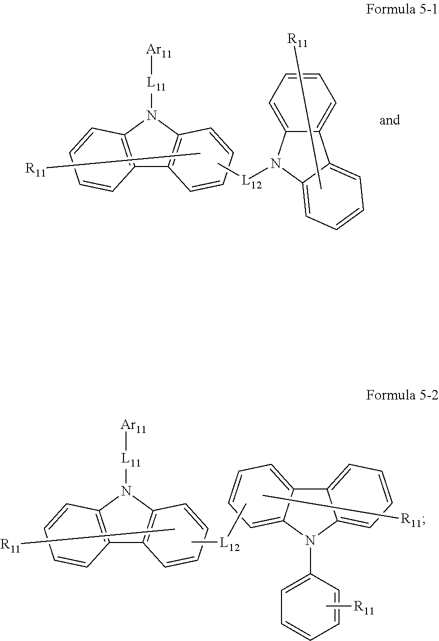

wherein L₁₁ and L₁₂ are selected from a single bond, substituted or unsubstituted arylene having 6 to 30 carbon atoms, substituted or unsubstituted heteroarylene having 3 to 30 carbon atoms or a combination thereof;
Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;
R₁₁ represents, at each occurrence identically or differently, mono-substitution, multiple substitutions or non-substitution;
R₁₁ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₁₁ can be optionally joined to form a ring.

According to an embodiment of the present disclosure, the first host material has a structure represented by Formula 5-3 or Formula 5-4:

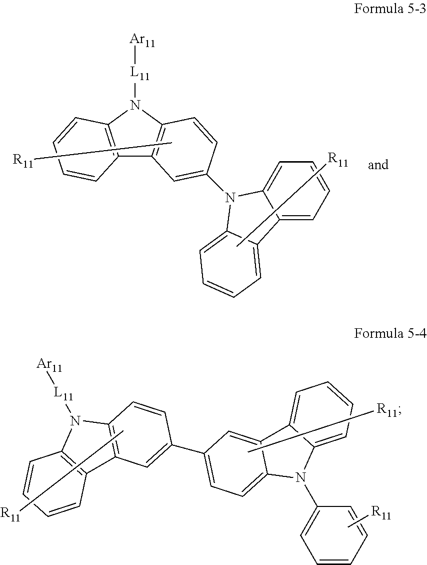

wherein Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;
L₁₁ is selected from a single bond, substituted or unsubstituted arylene having 6 to 30 carbon atoms, substituted or unsubstituted heteroarylene having 3 to 30 carbon atoms or a combination thereof;
R₁₁ represents, at each occurrence identically or differently, mono-substitution, multiple substitutions or non-substitution;
R₁₁ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₁₁ can be optionally joined to form a ring.

According to an embodiment of the present disclosure, R₁₁ is, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, R₁₁ is, at each occurrence identically or differently, selected from the group consisting of: hydrogen, deuterium, halogen, a cyano group, substituted or unsubstituted aryl having 6 to 18 carbon atoms, substituted or unsubstituted heteroaryl having 3 to 18 carbon atoms and combinations thereof.

According to an embodiment of the present disclosure, R₁₁ is, at each occurrence identically or differently, selected from the group consisting of: hydrogen, deuterium, fluorine, cyano, phenyl, biphenyl, triphenylenyl, indenyl, fluorenyl, indolyl, carbazolyl, benzofuranyl, dibenzofuranyl, benzosilolyl, dibenzosilolyl, benzothienyl, dibenzothienyl, dibenzoselenophenyl and combinations thereof.

According to an embodiment of the present disclosure, in Formula 5-1 to Formula 5-4, a plurality of substituents R₁₁ are present, and at least one of the plurality of substituents R₁₁ is carbazolyl. For example, one or two of the plurality of substituents R₁₁ are carbazolyl.

According to an embodiment of the present disclosure, in Formula 5-1 to Formula 5-4, a plurality of substituents R₁₁ are present, and at least one of the plurality of substituents R₁₁ and Ar₁₁ is carbazolyl. For example, one or two of the plurality of substituents R₁₁ and Ar₁₁ are carbazolyl.

According to an embodiment of the present disclosure, the first host material is selected from the group consisting of Compound P-1 to Compound P-31:

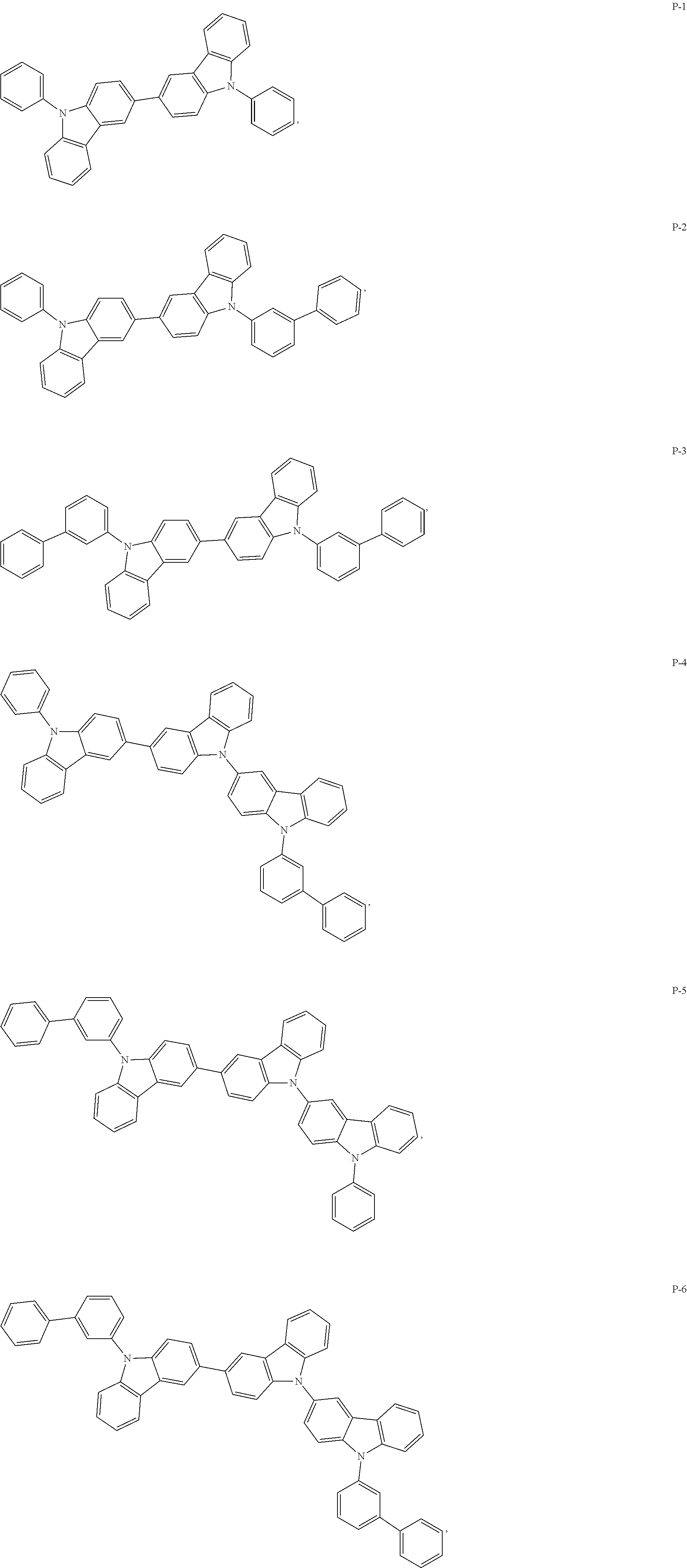

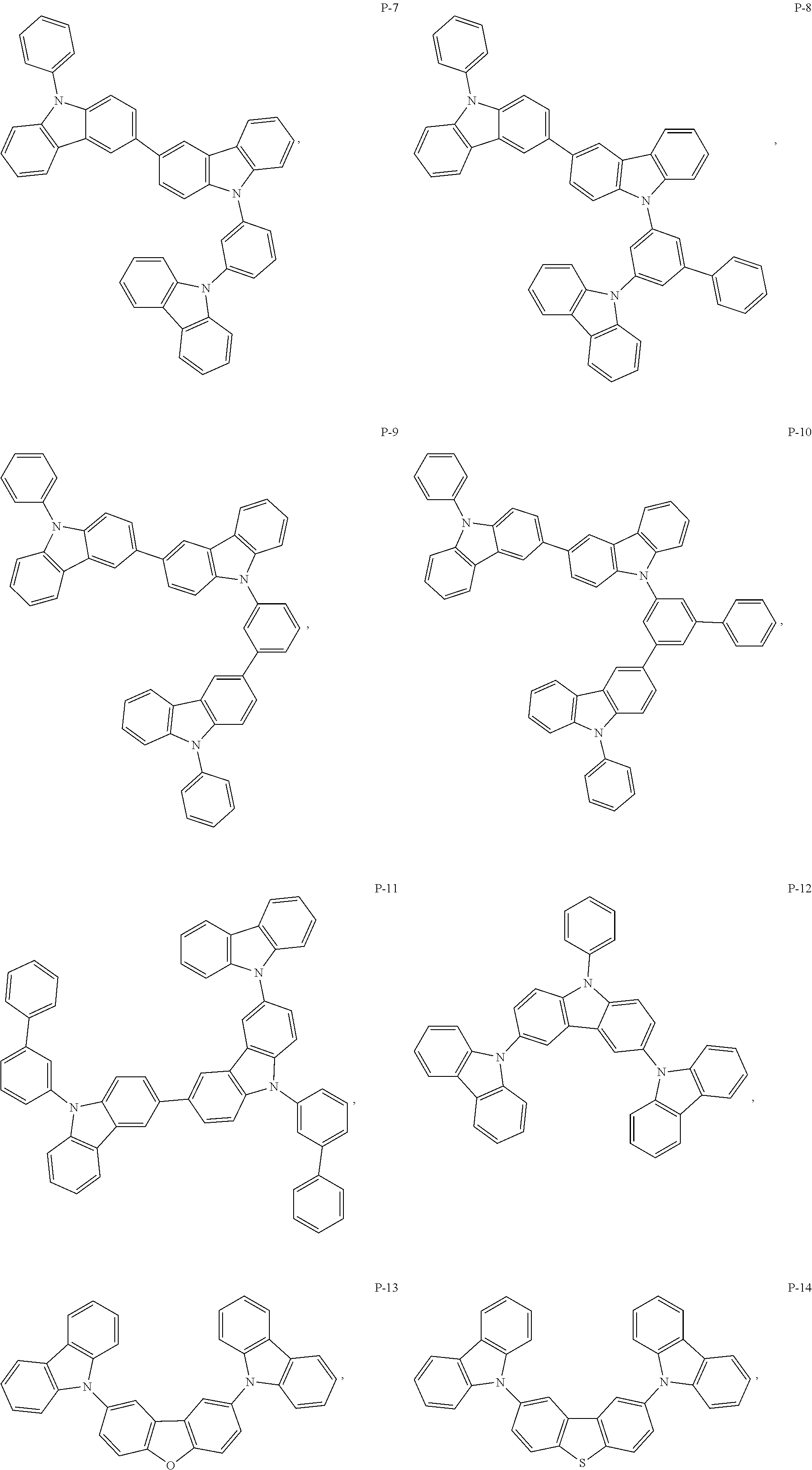

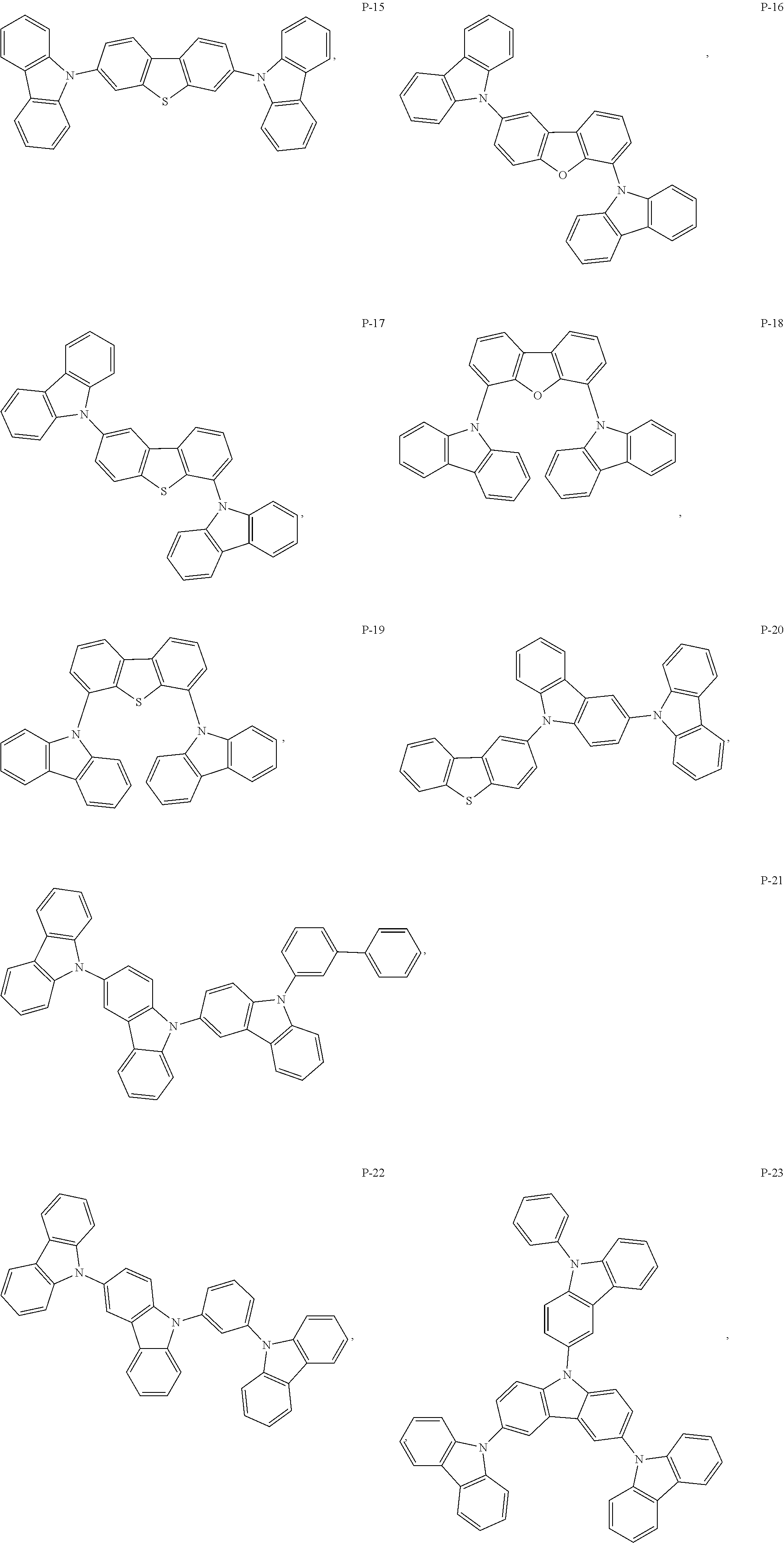

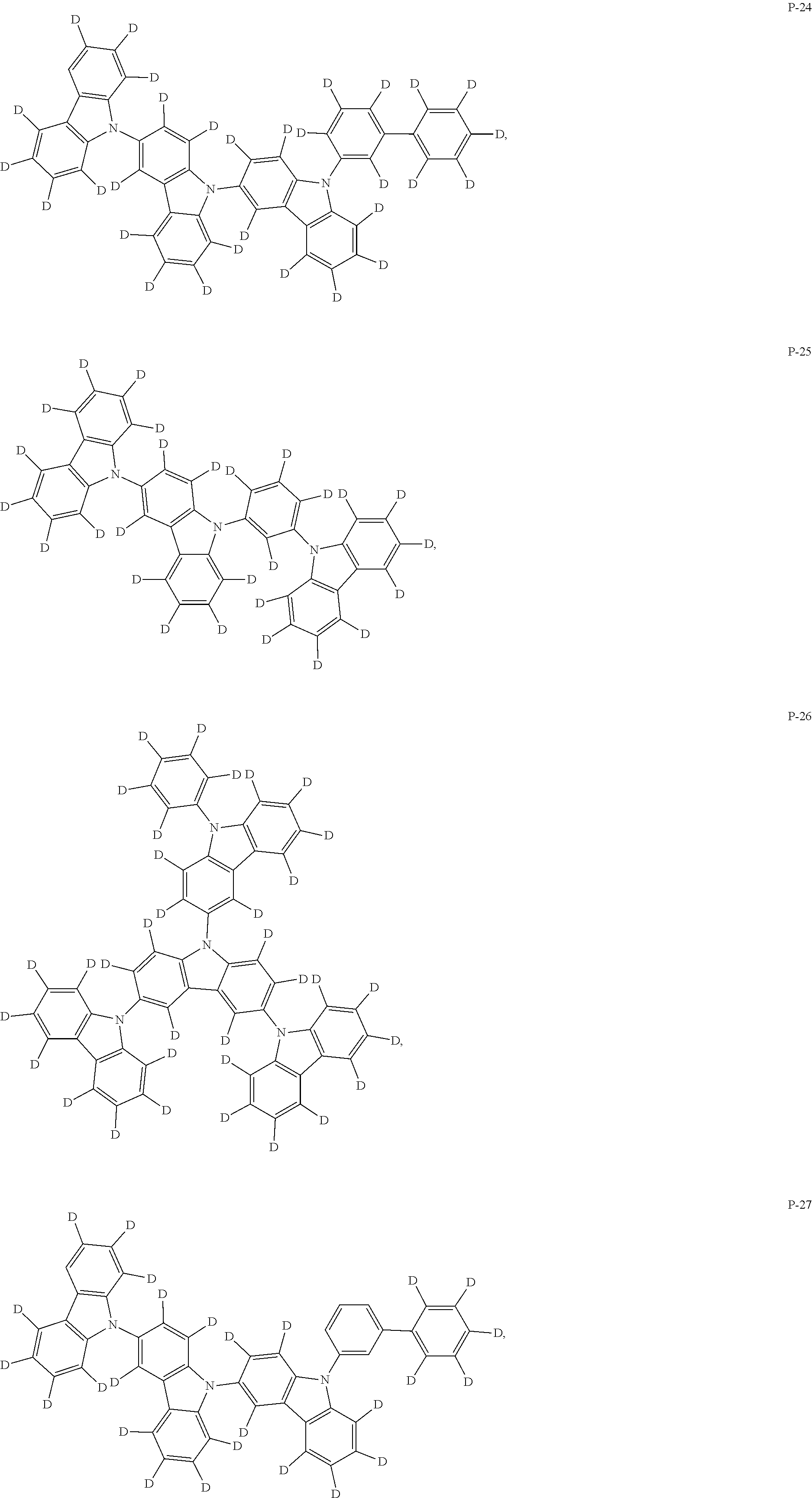

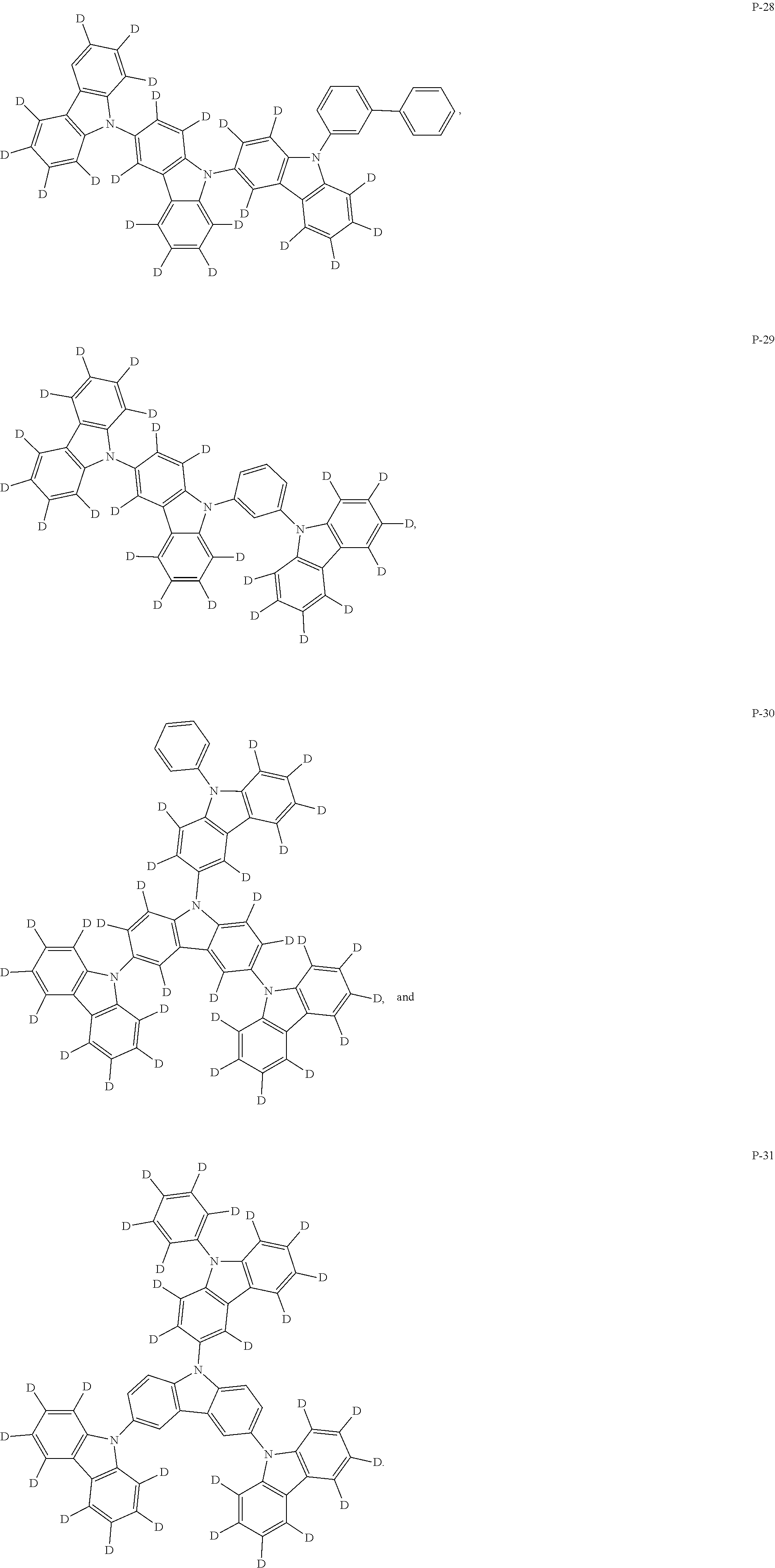

According to an embodiment of the present disclosure, the second host material has a structure represented by Formula 6:

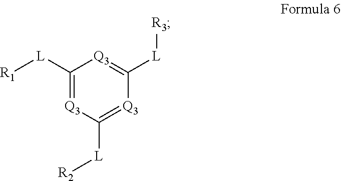

wherein Q₁ to Q₃ are, at each occurrence identically or differently, selected from CR₄ or N, and at least one of Q₁ to Q₃ is N;
L is, at each occurrence identically or differently, selected from the group consisting of: a single bond, substituted or unsubstituted arylene having 6 to 30 carbon atoms, substituted or unsubstituted heteroarylene having 3 to 30 carbon atoms and combinations thereof;
R₁ to R₄ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₄ can be optionally joined to form a ring.

According to an embodiment of the present disclosure, in Formula 6, Q₁ to Q₃ are N.

According to an embodiment of the present disclosure, R₁ to R₄ are, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, the second host material has a structure represented by Formula 6-1:

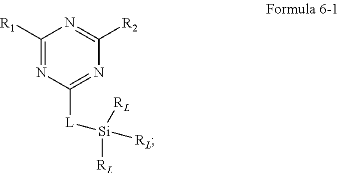

wherein R₁ and R₂ are each independently selected from substituted or unsubstituted heteroaryl having 3 to 30 carbon atoms;
L is selected from a single bond, substituted or unsubstituted arylene having 6 to 30 carbon atoms, substituted or unsubstituted heteroarylene having 3 to 30 carbon atoms or a combination thereof; and
R_{L} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms and combinations thereof.

According to an embodiment of the present disclosure, the R₁ and R₂ are each independently selected from the group consisting of: carbazolyl, indolyl, benzofuranyl, dibenzofuranyl, benzosilolyl, dibenzosilolyl, benzothienyl, dibenzothienyl and combinations thereof.

According to an embodiment of the present disclosure, the L is selected from a single bond, phenylene, biphenylylene, terphenylene or pyridylene.

According to an embodiment of the present disclosure, the R_{L} is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, the R_{L} is, at each occurrence identically or differently, selected from substituted or unsubstituted aryl having 6 to 30 carbon atoms.

According to an embodiment of the present disclosure, the R_{L} is, at each occurrence identically or differently, selected from the group consisting of: phenyl, biphenyl, triphenylenyl, indenyl, fluorenyl, indolyl, carbazolyl, benzofuranyl, dibenzofuranyl, benzosilolyl, dibenzosilolyl, benzothienyl, dibenzothienyl, dibenzoselenophenyl and combinations thereof.

According to an embodiment of the present disclosure, the second host material is selected from the group consisting of Compound N-2-1 to Compound N-2-45:

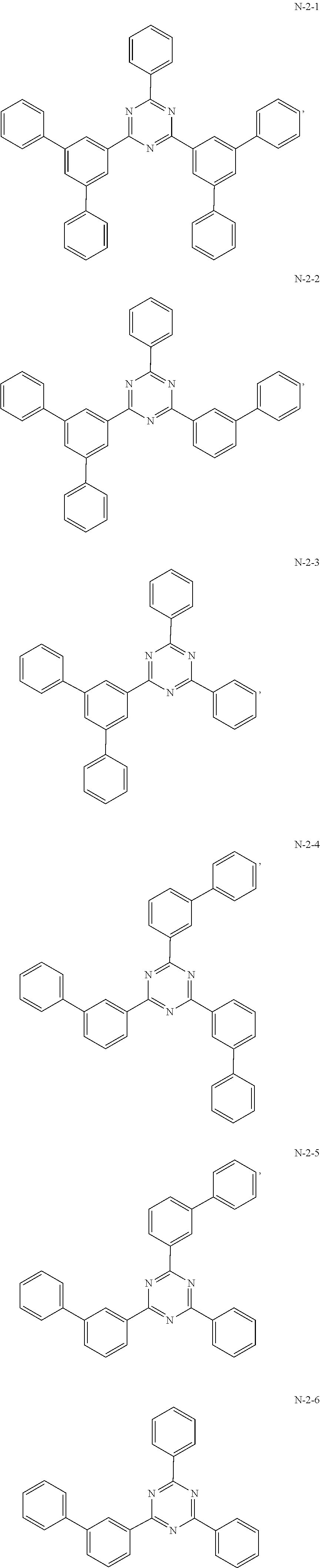 [SMILES: c1ccc(-c2cc(-c3ccccc3)cc(-c3nc(-c4ccccc4)nc(-c4cc(-c5ccccc5)cc(-c5ccccc5)c4)n3)c2)cc1 ; c1ccc(-c2cccc(-c3nc(-c4ccccc4)nc(-c4cc(-c5ccccc5)cc(-c5ccccc5)c4)n3)c2)cc1 ; c1ccc(-c2cc(-c3ccccc3)cc(-c3nc(-c4ccccc4)nc(-c4ccccc4)n3)c2)cc1 ; c1ccc(-c2cccc(-c3nc(-c4cccc(-c5ccccc5)c4)nc(-c4cccc(-c5ccccc5)c4)n3)c2)cc1 ; c1ccc(-c2cccc(-c3nc(-c4ccccc4)nc(-c4cccc(-c5ccccc5)c4)n3)c2)cc1 ; c1ccc(-c2cccc(-c3nc(-c4ccccc4)nc(-c4ccccc4)n3)c2)cc1]

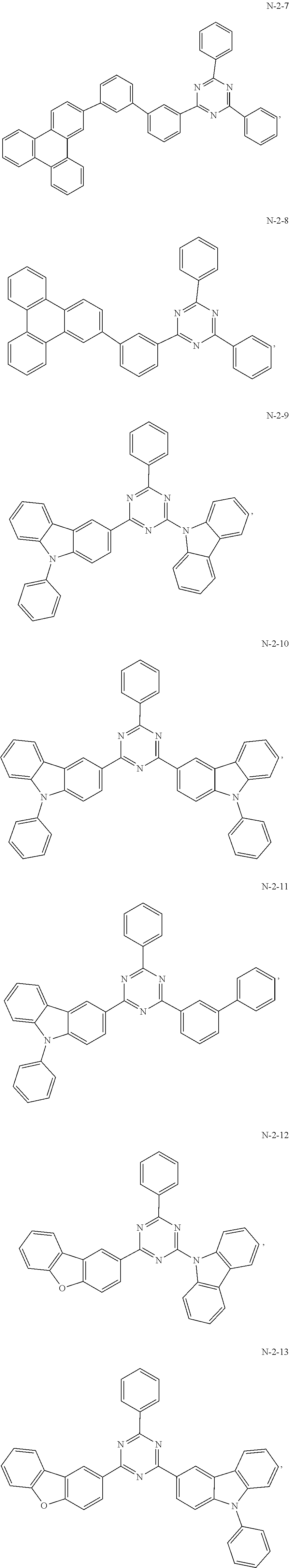

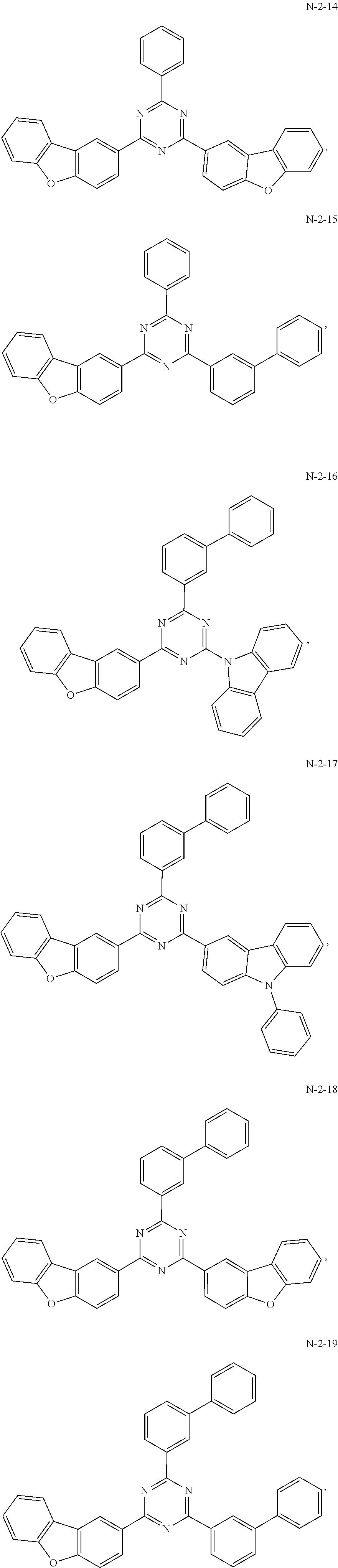 [SMILES: c1ccc(-c2nc(-c3ccc4oc5ccccc5c4c3)nc(-c3ccc4oc5ccccc5c4c3)n2)cc1 ; c1ccc(-c2cccc(-c3nc(-c4ccccc4)nc(-c4ccc5oc6ccccc6c5c4)n3)c2)cc1 ; c1ccc(-c2cccc(-c3nc(-c4ccc5oc6ccccc6c5c4)nc(-n4c5ccccc5c5ccccc54)n3)c2)cc1 ; c1ccc(-c2cccc(-c3nc(-c4ccc5oc6ccccc6c5c4)nc(-c4ccc5c(c4)c4ccccc4n5-c4ccccc4)n3)c2)cc1 ; c1ccc(-c2cccc(-c3nc(-c4ccc5oc6ccccc6c5c4)nc(-c4ccc5oc6ccccc6c5c4)n3)c2)cc1 ; c1ccc(-c2cccc(-c3nc(-c4cccc(-c5ccccc5)c4)nc(-c4ccc5oc6ccccc6c5c4)n3)c2)cc1]

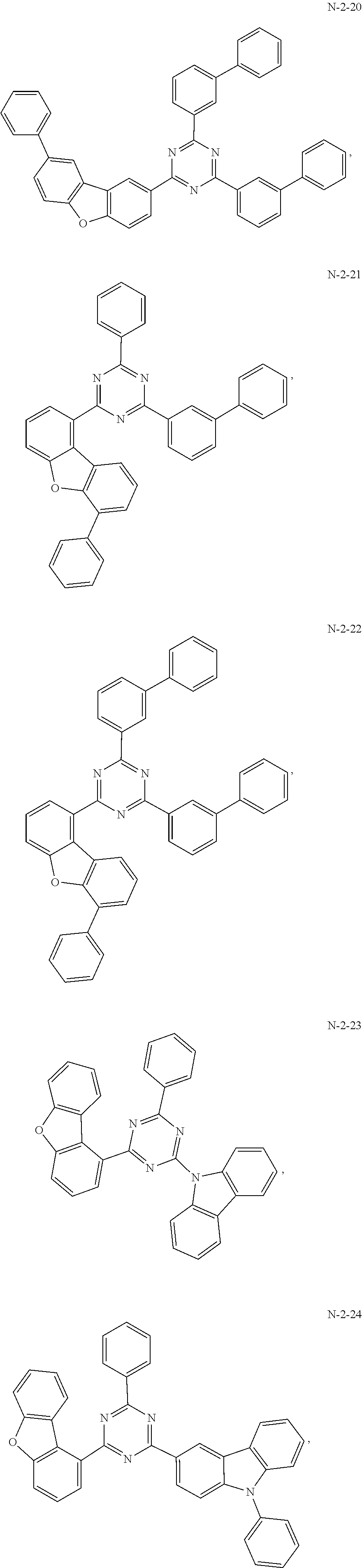 [SMILES: c1ccc(-c2cccc(-c3nc(-c4cccc(-c5ccccc5)c4)nc(-c4ccc5oc6ccc(-c7ccccc7)cc6c5c4)n3)c2)cc1 ; c1ccc(-c2cccc(-c3nc(-c4ccccc4)nc(-c4cccc5oc6c(-c7ccccc7)cccc6c45)n3)c2)cc1 ; c1ccc(-c2cccc(-c3nc(-c4cccc(-c5ccccc5)c4)nc(-c4cccc5oc6c(-c7ccccc7)cccc6c45)n3)c2)cc1 ; c1ccc(-c2nc(-c3cccc4oc5ccccc5c34)nc(-n3c4ccccc4c4ccccc43)n2)cc1 ; c1ccc(-c2nc(-c3ccc4c(c3)c3ccccc3n4-c3ccccc3)nc(-c3cccc4oc5ccccc5c34)n2)cc1]

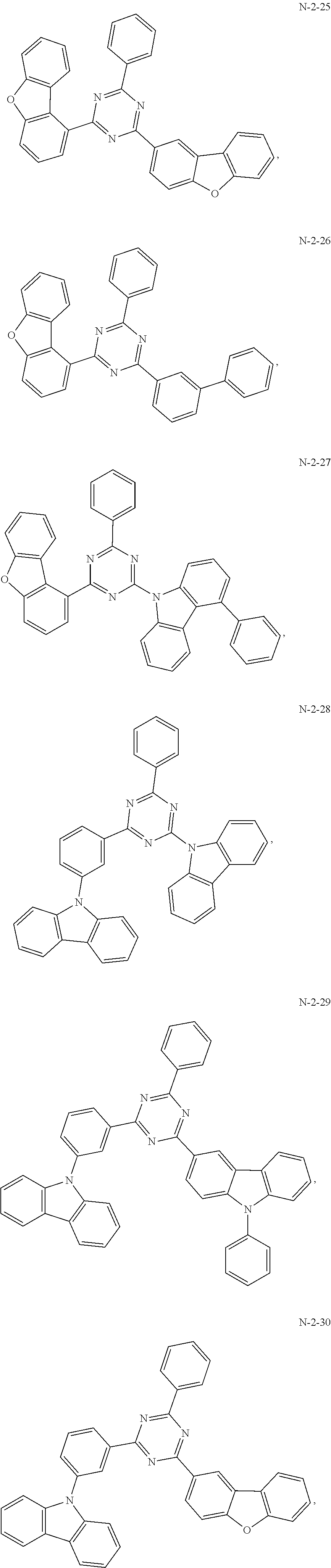 [SMILES: c1ccc(-c2nc(-c3ccc4oc5ccccc5c4c3)nc(-c3cccc4oc5ccccc5c34)n2)cc1 ; c1ccc(-c2cccc(-c3nc(-c4ccccc4)nc(-c4cccc5oc6ccccc6c45)n3)c2)cc1 ; c1ccc(-c2nc(-c3cccc4oc5ccccc5c34)nc(-n3c4ccccc4c4c(-c5ccccc5)cccc43)n2)cc1 ; c1ccc(-c2nc(-c3cccc(-n4c5ccccc5c5ccccc54)c3)nc(-n3c4ccccc4c4ccccc43)n2)cc1 ; c1ccc(-c2nc(-c3cccc(-n4c5ccccc5c5ccccc54)c3)nc(-c3ccc4c(c3)c3ccccc3n4-c3ccccc3)n2)cc1 ; c1ccc(-c2nc(-c3cccc(-n4c5ccccc5c5ccccc54)c3)nc(-c3ccc4oc5ccccc5c4c3)n2)cc1]

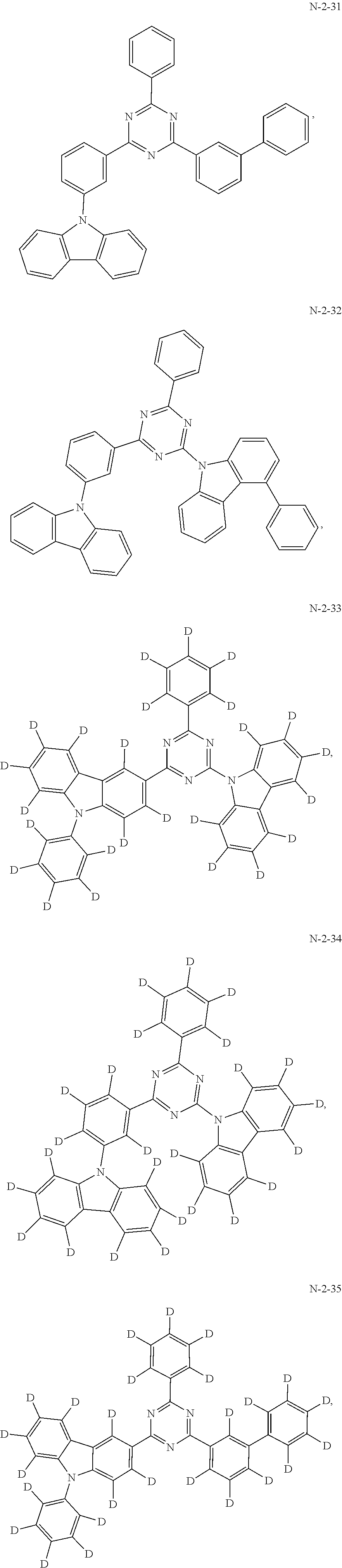

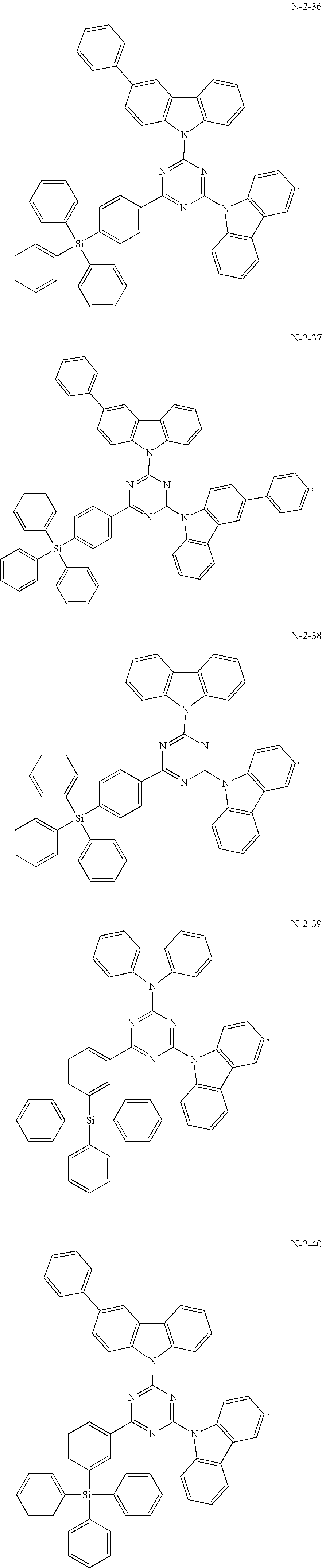

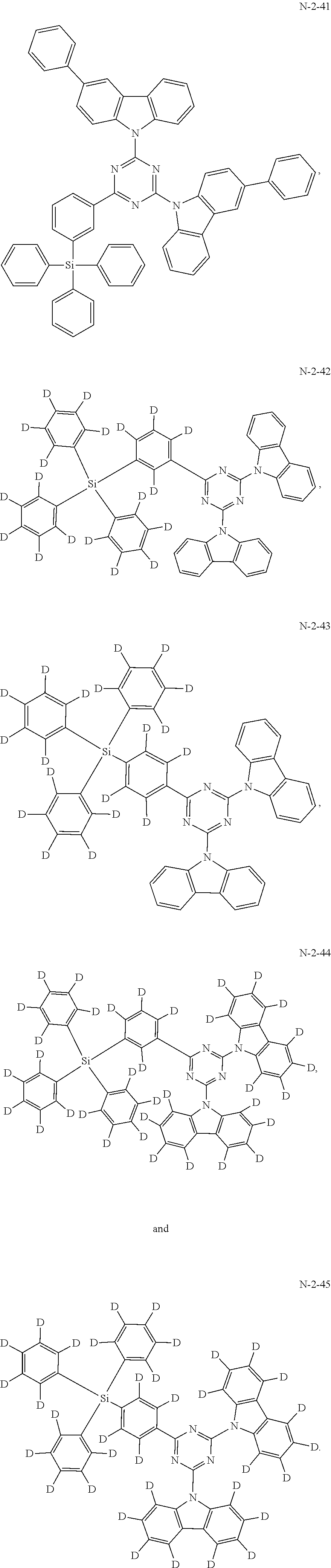

According to another embodiment of the present disclosure, disclosed is a compound composition, which comprises a compound having a structure of Formula 1, wherein the compound having the structure of Formula 1 is as shown in any one of the preceding embodiments.

Combination with Other Materials

The materials described in the present disclosure for a particular layer in an organic light emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, compounds disclosed herein may be used in combination with a wide variety of light-emitting dopants, hosts, transporting layers, blocking layers, injection layers, electrodes, and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

### Material Synthesis Example

The method for preparing the compound of the present disclosure is not limited herein. Typically, the following compound is used as examples without limitation, and the synthesis route and preparation method thereof are described below.

### Synthesis Example 1: Synthesis of Compound Pt119

### Step 1: Synthesis of Intermediate 1

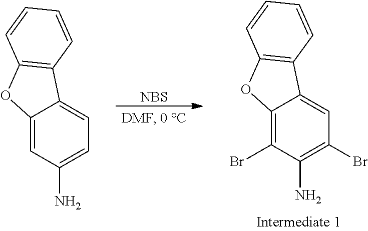

3-aminodibenzofuran (20.8 g, 114 mmol) was dissolved in 160 mL of dry DMF and cooled to 0° C. Separately, N-bromosuccinimide (NBS) (44.5 g, 250 mmol) was dissolved in 200 mL of dry DMF and added dropwise to the above solution. The resulting mixture was stirred for 1 h. After the reaction was confirmed complete by TLC, the reaction was quenched with water, and the resulting product was extracted with dichloromethane. The organic layer was washed with an aqueous sodium chloride solution, dried over anhydrous magnesium sulfate, concentrated under reduced pressure, and purified by column chromatography to obtain Intermediate 1 (19.4 g, 57 mmol).

### Step 2: Synthesis of Intermediate 2

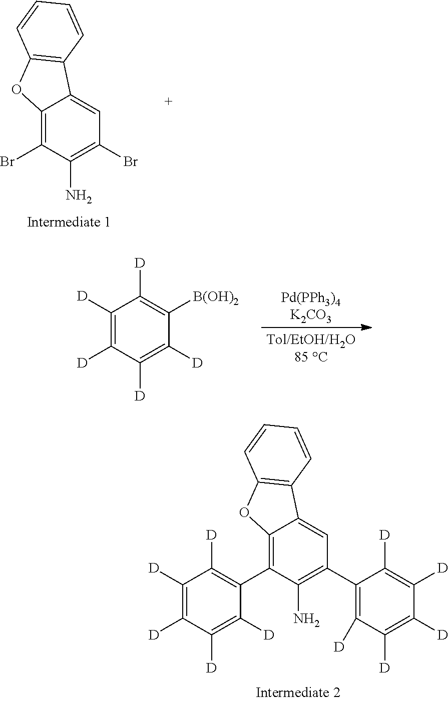 [SMILES: Nc1c(Br)cc2c(oc3ccccc32)c1Br ; [2H]c1c([2H])c([2H])c(B(O)O)c([2H])c1[2H] ; [2H]c1c([2H])c([2H])c(-c2cc3c(oc4ccccc43)c(-c3c([2H])c([2H])c([2H])c([2H])c3[2H])c2N)c([2H])c1[2H]]

Under a nitrogen condition, Intermediate 1 (5.6 g, 16.4 mmol), penta-deuterophenylboronic acid (5.2 g, 42.6 mmol), tetrakis(triphenylphosphine)palladium (0.948 g, 0.82 mmol), and potassium carbonate (9.0 g, 65.6 mmol) were dissolved in a mixed solvent of toluene/ethanol/water (4:1:1, 82 mL in total). The mixture was stirred at 110° C. overnight. After the reaction was completed, the resulting product was purified by column chromatography to obtain Intermediate 2 (4.1 g, 11.88 mmol).

### Step 3: Synthesis of Intermediate 3

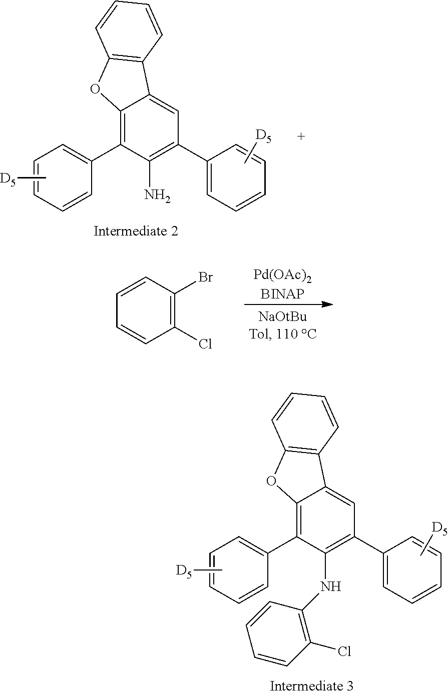

Under a nitrogen condition, Intermediate 2 (4.1 g, 11.88 mmol), o-chlorobromobenzene (3.4 g, 17.8 mmol), palladium acetate (133 mg, 0.594 mmol), BINAP (739 mg, 1.19 mmol), and sodium tert-butoxide (2.3 g, 23.76 mmol) were added to a flask, and 118 mL of toluene was added. The mixture was stirred at 110° C. overnight. After the reaction was completed, the resulting product was purified by column chromatography to obtain Intermediate 3 (5.46 g, 12 mmol).

### Step 4: Synthesis of Intermediate 5

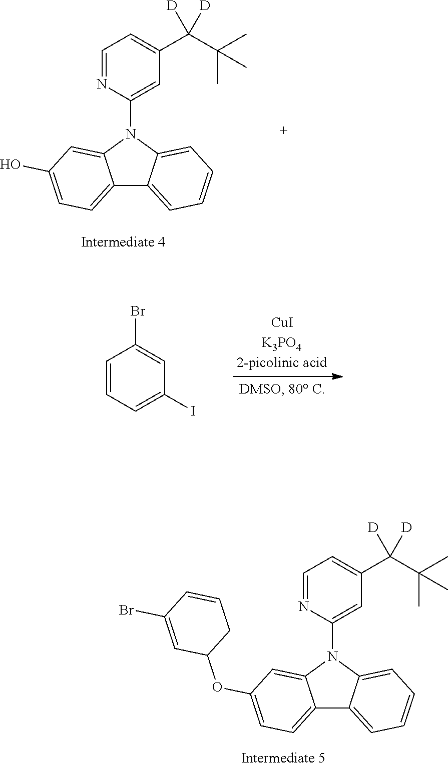 [SMILES: [2H]C([2H])(c1ccnc(-n2c3ccccc3c3ccc(O)cc32)c1)C(C)(C)C ; Brc1cccc(I)c1 ; [2H]C([2H])(c1ccnc(-n2c3ccccc3c3ccc(OC4C=C(Br)C=CC4)cc32)c1)C(C)(C)C]

Under a nitrogen condition, Intermediate 4 (15.0 g, 45 mmol), m-bromoiodobenzene (19 g, 67.5 mmol), cuprous iodide (854 mg, 4.5 mmol), 2-picolinic acid (771 mg, 6.27 mmol), and potassium phosphate (19.1 g, 90 mmol) were added to a 500 mL flask, and dimethyl sulfoxide (150 mL) was added. The reaction was heated to 80° C. and stirred overnight. After the reaction was completed, the reaction was cooled to room temperature and quenched with water, and the resulting product was extracted with dichloromethane. The organic layer was washed with an aqueous sodium chloride solution, dried over anhydrous magnesium sulfate, concentrated under reduced pressure, and purified by column chromatography to obtain Intermediate 5 (17.5 g, 36 mmol).

### Step 5: Synthesis of Intermediate 6

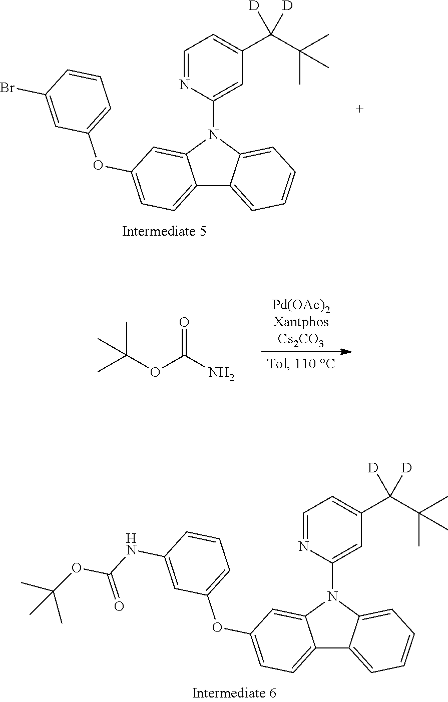

Under a nitrogen condition, Intermediate 5 (17.5 g, 36 mmol), tert-butyl carbamate (5.5 g, 46.8 mmol), Pd(OAc)₂ (403 mg, 1.8 mmol), XantPhos (2.1 g, 3.6 mmol), Cs₂CO₃ (23.4 g, 72 mmol), and toluene (144 mL) were added to a flask. The reaction was warmed to 110° C. and stirred overnight. The reaction was cooled to room temperature, and the resulting product was concentrated under reduced pressure and purified by column chromatography to obtain Intermediate 6 (18 g, 34.2 mmol).

### Step 6: Synthesis of Intermediate 7

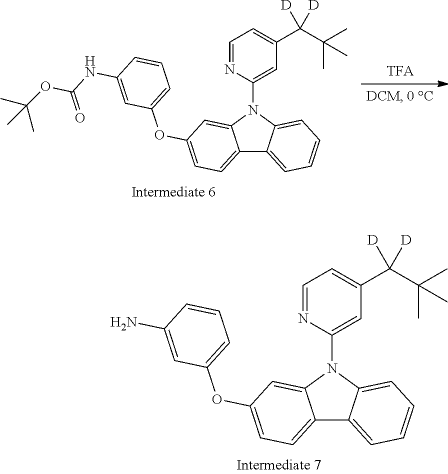 [SMILES: [2H]C([2H])(c1ccnc(-n2c3ccccc3c3ccc(Oc4cccc(NC(=O)OC(C)(C)C)c4)cc32)c1)C(C)(C)C ; [2H]C([2H])(c1ccnc(-n2c3ccccc3c3ccc(Oc4cccc(N)c4)cc32)c1)C(C)(C)C]

Intermediate 6 (18 g, 34.2 mmol) was dissolved in dichloromethane (300 mL). trifluoroacetic acid (150 mL) was added at 0° C. The mixture was warmed to room temperature and stirred for 2 h. The pH of the reaction solution was adjusted to neutral with an aqueous sodium hydroxide solution. The resulting product was extracted, dried, concentrated, and purified by column chromatography to obtain Intermediate 7 (14 g, 33 mmol).

### Step 7: Synthesis of Intermediate 8

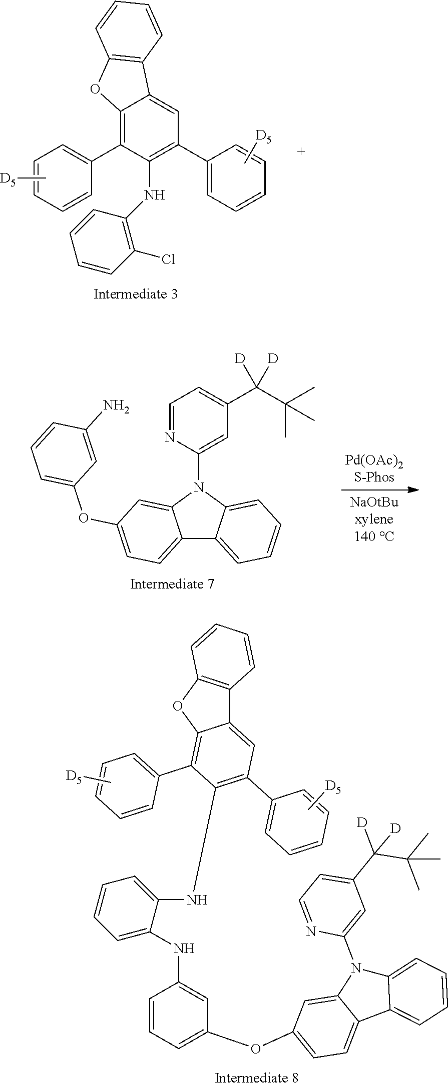

Under a nitrogen condition, Intermediate 3 (5.46 g, 12 mmol), Intermediate 7 (4.23 g, 10 mmol), palladium acetate (18 mg, 0.08 mmol), S-Phos (656 mg, 1.6 mmol), sodium tert-butoxide (1.9 g, 20.0 mmol), and xylene (100 mL) were added to a flask. The reaction was warmed to 140° C. and stirred overnight. After the reaction was completed, the reaction was cooled to room temperature, and the resulting product was filtered through Celite, concentrated under reduced pressure, and purified by column chromatography to obtain Intermediate 8 (3.5 g, 4.15 mmol).

### Step 8: Synthesis of Intermediate 9

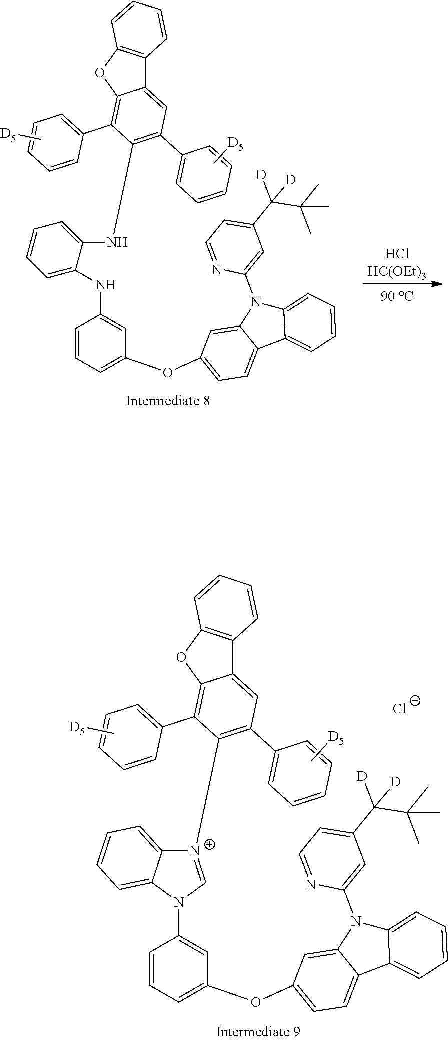

Under a nitrogen condition, Intermediate 8 (3.5 g, 4.15 mmol), triethyl orthoformate (22.8 g, 153.7 mmol), and concentrated hydrochloric acid (1.1 mL) were added to a flask. The reaction was warmed to 100° C. and stirred overnight. After the reaction was confirmed complete by TLC, the reaction was cooled to room temperature, and the resulting product was concentrated under reduced pressure and purified by column chromatography to obtain Intermediate 9 (3.0 g, 3.36 mmol).

### Step 9: Synthesis of Intermediate 10

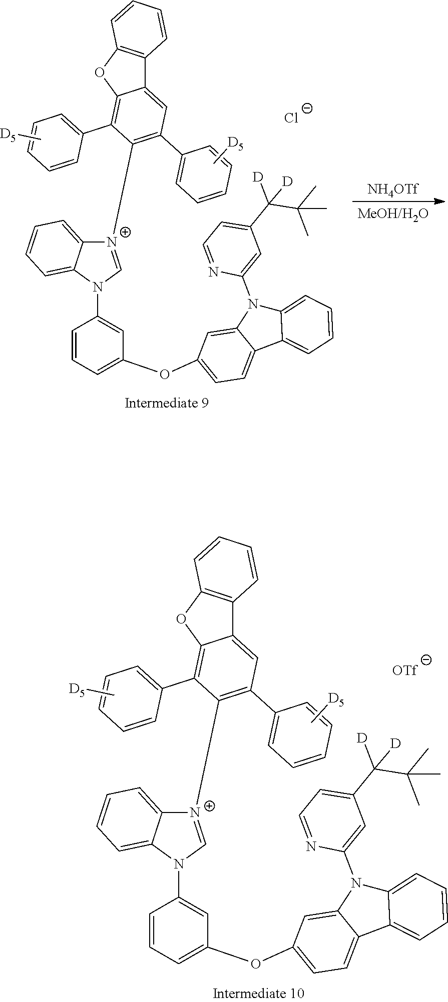

Intermediate 9 (3.0 g, 3.36 mmol) was dissolved in 90 mL of methanol. Separately, ammonium trifluoromethanesulfonate (1.69 g, 10.1 mmol) was dissolved in 30 mL of water. The resulting aqueous solutions were slowly added dropwise to the flask. The mixture was stirred at room temperature for 24 h. After the reaction was completed, the resulting product was purified by column chromatography to obtain Intermediate 10 (3.3 g, 3.27 mmol).

### Step 10: Synthesis of Compound Pt119

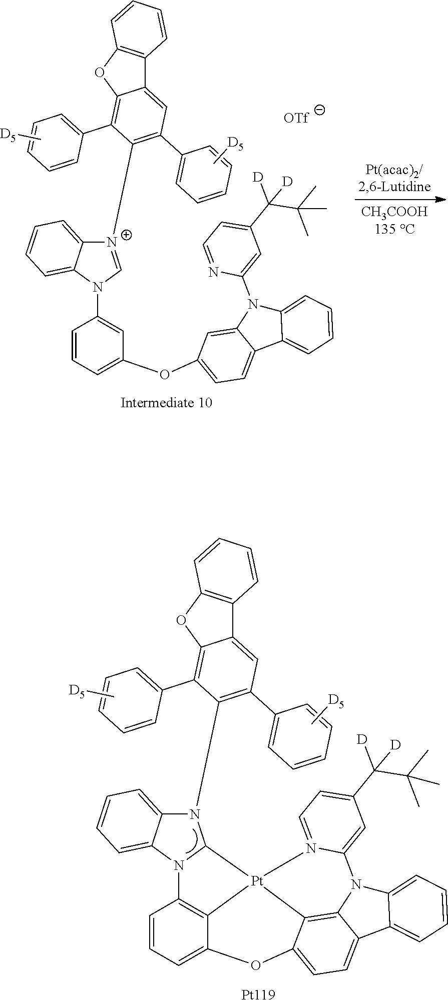

Under a nitrogen condition, Intermediate 10 (3.3 g, 3.27 mmol), platinum(II) bis(acetylacetonate) (1.42 g, 3.6 mmol), 2,6-lutidine (420 mg, 3.9 mmol), and acetic acid (33 mL) were added to a flask. The reaction was warmed to 135° C. and stirred for 24 h. The reaction was cooled to room temperature, and the resulting product was extracted with dichloromethane. The combined organic layers were purified by column chromatography to obtain Compound Pt119 (2.2 g, 2.13 mmol). The product was confirmed as the target product with a molecular weight of 1045.4.

Those skilled in the art will appreciate that the above preparation method is merely exemplary. Those skilled in the art can obtain other compound structures of the present disclosure through the modifications of the preparation method.

The method for preparing an electroluminescent device is not limited herein. The preparation methods in the following examples are merely examples and are not to be construed as limiting. Based on the existing art, those skilled in the art can make reasonable improvements to the preparation methods in the following examples. For example, the ratio of various materials in the light-emitting layer is not particularly limited, and those skilled in the art can reasonably select the ratio of materials within a certain range based on the existing art. For instance, based on the total weight of the light-emitting layer materials, the host material may account for 80% to 99%, and the light-emitting material may account for 1% to 20%; or, the host material may account for 85% to 99%, and the light-emitting material may account for 1% to 15%. Furthermore, the host material may include one or two materials. When two host materials are used, the ratio of the two host materials may range from 99:1 to 1:99; or the ratio can range from 80:20 to 20:80.

### Device Example 1

First, a glass substrate with pre-patterned 80 nm thick indium tin oxide (ITO) serving as the anode was cleaned. The substrate was washed with deionized water and a detergent, and then the ITO surface was treated with oxygen plasma and UV ozone. After the treatment, the substrate was dried in a glovebox to remove moisture. Then, the substrate was mounted on a substrate holder and placed in a vacuum chamber. Organic layers specified below were sequentially deposited through vacuum thermal evaporation on the ITO anode at a rate of 0.2 to 2 Angstroms (Å) per second at a vacuum degree of about 10⁻⁷ torr. Compound HT and Compound HI were co-deposited (at a weight ratio of 97:3) as a hole injection layer (HIL) with a thickness of 100 Å. Compound HT was deposited as a hole transport layer (HTL) with a thickness of 250 Å. Compound EB was deposited as an electron blocking layer (EBL) with a thickness of 50 Å. Compound P-25 serving as a first host, Compound N-2-39 serving as a second host and Compound Pt119 of the present disclosure serving as a dopant were co-deposited (at a weight ratio of 52.9:35.1:12) as a light-emitting layer (EML) with a thickness of 350 Å. Compound N-2-39 was deposited as a hole blocking layer (HBL) with a thickness of 50 Å. On the hole blocking layer, Compound ET and 8-hydroxyquinolinolato-lithium (Liq) were co-deposited (at a weight ratio of 50:50) as an electron transport layer (ETL) with a thickness of 310 Å. Finally, LiF with a thickness of 15 Å was deposited as an electron injection layer, and Al with a thickness of 1200 Å was evaporated as a cathode. The device was transferred back to the glovebox and encapsulated with a glass lid and a desiccant to complete the device.

### Device Comparative Example 1

The preparation method in Device Comparative Example 1 is the same as the preparation method in Device Example 1, except that Compound Pt119 was replaced with Compound Pt-A in the light-emitting layer (EML).

TABLE 1
Part of device structures in device examples and device comparative examples

| Device ID | HIL | HTL | EBL | EML | HBL | ETL |
|---|---|---|---|---|---|---|
| Example 1 | Compound | Compound | Compound | Compound | Compound | Compound |
| | HT:Compound | HT | EB | P-25:Compound | N-2-39 | ET:Liq |
| | HI | (250 Å) | (50 Å) | N-2-39:Compound | (50 Å) | (50:50) |
| | (97:3) (100 Å) | | | Pt119 | | (310 Å) |
| | | | | (52.9:35.1:12) | | |
| | | | | (350 Å) | | |
| Comparative | Compound | Compound | Compound | Compound | Compound | Compound |
| Example 1 | HT:Compound | HT | EB | P-25:Compound | N-2-39 | ET:Liq |
| | HI | (250 Å) | (50 Å) | N-2-39:Compound | (50 Å) | (50:50) |
| | (97:3) (100 Å) | | | Pt-A | | (310 Å) |
| | | | | (52.9:35.1:12) | | |
| | | | | (350 Å) | | |

The structures of the materials used in the devices are as follows:

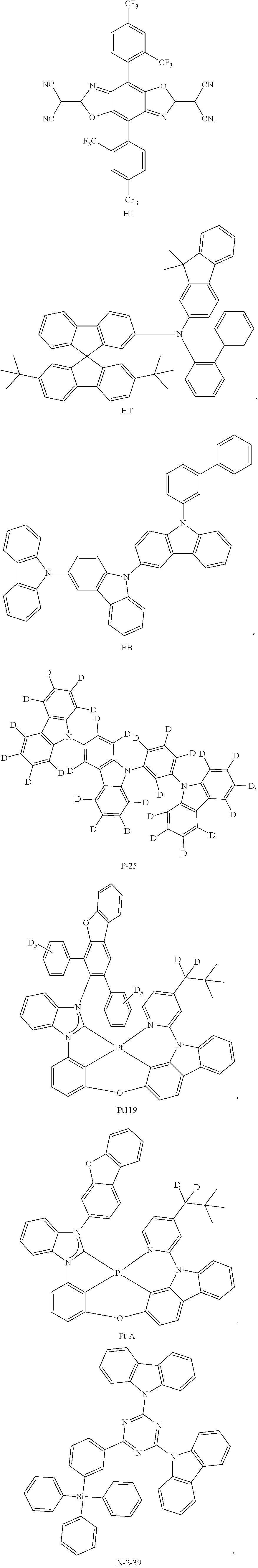

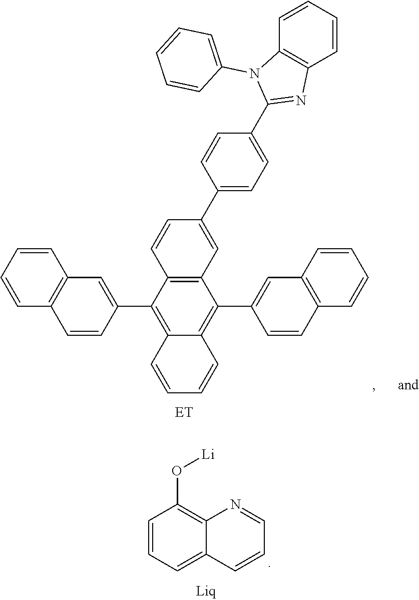

The CIE values, maximum emission wavelengths (λₘₐₓ), power efficiency (PE) and current efficiency (CE) of Example 1 and Comparative Example 1 were measured at 10 mA/cm². The related data are shown in Table 2.

TABLE 2
Device data

| Device No. | CIE (x, y) | λₘₐₓ (nm) | PE (lm/W) | CE (cd/A) |
|---|---|---|---|---|
| Example 1 | 0.135, 0.182 | 466 | 17.88 | 23.8 |
| Comparative | 0.152, 0.244 | 467 | 10.79 | 14.58 |
| Example 1 | | | | |

### DISCUSSION

As can be seen from the data in Table 2, both Example 1 and Comparative Example 1 achieve deep blue phosphorescence emission. The difference between the compound in Example 1 and the compound in Comparative Example 1 lies only in whether the ring F in the substituent R comprises the specific substituent R_{f} of the present disclosure. However, the difference in device performance between the two is very significant. Compared with Comparative Example 1, the power efficiency (PE) and current efficiency (CE) of Example 1 are unexpectedly improved by 65.7% and 63.2%, respectively. Such an improvement is very rare in blue phosphorescent devices.

The above data demonstrate the importance of the compound of the present disclosure having a specific substituent R and the ring F in the substituent R having a specific substituent R_{f1} and proves that when the compound having a specific structure of Formula 1 of the present disclosure is used as a light-emitting material in blue phosphorescent devices, the compound can further significantly enhance PE and CE, thereby improving the overall performance of the device. It fully demonstrates the unique advantages and broad application prospects of the compound having a specific structure of Formula 1 of the present disclosure.

It should be understood that various embodiments described herein are merely embodiments and not intended to limit the scope of the present disclosure. Therefore, it is apparent to those skilled in the art that the present disclosure as claimed may include variations of specific embodiments and preferred embodiments described herein. Many of the materials and structures described herein may be replaced with other materials and structures without departing from the spirit of the present disclosure. It should be understood that various theories as to why the present disclosure works are not intended to be limitative.

What is claimed is:

1. A compound having a structure of Formula 1: 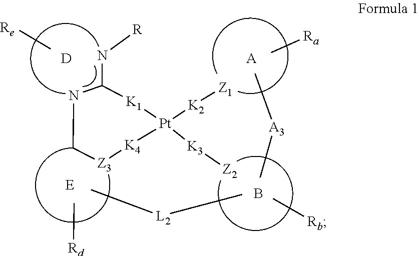
wherein in Formula 1,
the metal M is selected from a metal with a relative atomic mass greater than 40;
the ring A, the ring B and the ring E are, at each occurrence identically or differently, selected from an unsaturated carbocyclic ring having 5 to 30 carbon atoms, an unsaturated heterocyclic ring having 3 to 30 carbon atoms or a combination thereof; and the ring D is selected from an unsaturated heterocyclic ring having 3 to 30 carbon atoms;
L₁ and L₂ are, at each occurrence identically or differently, selected from a single bond, O, S, Se, (CR′R′)_{y}, (SiR′R′)_{y}, PR′, NR′, substituted or unsubstituted arylene having 6 to 30 carbon atoms, substituted or unsubstituted heteroarylene having 3 to 30 carbon atoms or a combination thereof; y is, at each occurrence identically or differently, selected from 0, 1, 2, 3, 4 or 5; and when a plurality of R′ are present at the same time, the plurality of R′ are identical or different;
K₁ to K₄ are, at each occurrence identically or differently, selected from a single bond, O or S; and
Z₁ to Z₃ are, at each occurrence identically or differently, selected from C or N;
the substituent R in Formula 1 has a structure represented by Formula 2: 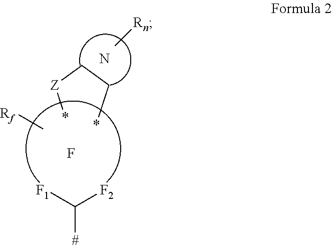
wherein in Formula 2,
“#” represents a position where Formula 2 is joined;
the ring F and the ring N are, at each occurrence identically or differently, selected from an aromatic ring having 6 to 30 carbon atoms, a heteroaromatic ring having 3 to 30 carbon atoms or a combination thereof;
there are two ring atoms that are directly bonded in the ring F, and they are carbon atoms and are connected to two “*”, respectively;
Z is selected from NR_{z}, O, S or Se;
F₁ and F₂ are each independently selected from CR_{f1}, CR_{F} or N, at least one of F₁ and F₂ is selected from CR_{f1}, and the R_{f1} is identically or differently selected from the group consisting of: substituted or unsubstituted aryl having 6 to 30 carbon atoms, substituted or unsubstituted heteroaryl having 3 to 30 carbon atoms and combinations thereof;
Rₐ, R_{b}, R_{d}, Rₑ, R_{f} and Rₙ represent, at each occurrence identically or differently, mono-substitution, multiple substitutions or non-substitution;
R′, Rₐ, R_{b}, R_{d}, Rₑ, R_{f}, R_{F}, Rₙ and R_{z} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R′, Rₐ, R_{b}, R_{d}, Rₑ, R_{f}, R_{F}, R_{f1}, Rₙ and R_{z} can be optionally joined to form a ring.

2. The compound of claim 1, wherein the metal M is selected from the group consisting of Cu, Ag, Au, Ru, Rh, Pd, Os, Ir and Pt; preferably, the metal M is selected from Pt or Pd; and more preferably, the metal M is selected from Pt.

3. The compound of claim 1, wherein the ring A, the ring B, the ring E, the ring F and the ring N are, at each occurrence identically or differently, selected from a five-membered unsaturated carbocyclic ring, an aromatic ring having 6 to 30 carbon atoms, a heteroaromatic ring having 3 to 30 carbon atoms or a combination thereof; and the ring D is selected from an unsaturated heterocyclic ring having 3 to 24 carbon atoms;
preferably, the ring A, the ring B, the ring E, the ring F and the ring N are, at each occurrence identically or differently, selected from a five-membered unsaturated carbocyclic ring, an aromatic ring having 6 to 18 carbon atoms, a heteroaromatic ring having 3 to 18 carbon atoms or a combination thereof; and the ring D is selected from an unsaturated heterocyclic ring having 3 to 18 carbon atoms; and
more preferably, the ring A, the ring B, the ring E, the ring F and the ring N are, at each occurrence identically or differently, selected from a benzene ring, a pyridine ring, an indene ring, a fluorene ring, an indole ring, a carbazole ring, an indolocarbazole ring, a benzofuran ring, a dibenzofuran ring, a benzosilole ring, a dibenzosilole ring, a benzothiophene ring, a dibenzothiophene ring, a dibenzoselenophene ring, a cyclopentadiene ring, a furan ring, a thiophene ring, a silole ring or a combination thereof; and the ring D is selected from an imidazolecarbene ring or a benzimidazolecarbene ring.

4. The compound of claim 1, wherein the L₁ is selected from a single bond, O, S, (SiR′R′)_{y}, NR′ or a combination thereof; y is 1 or 2; and when a plurality of R′ are present at the same time, the plurality of R′ are identical or different;
preferably, the L₁ is selected from a single bond, O or S; and
more preferably, the L₁ is selected from a single bond.

5. The compound of claim 1, wherein the K₁ to K₄ are selected from a single bond.

6. The compound of claim 1, wherein the Z₁ is selected from N, and the Z₂ and Z₃ are selected from C.

7. The compound of claim 1, wherein the compound has a structure represented by one of Formula 1-1 to Formula 1-5: 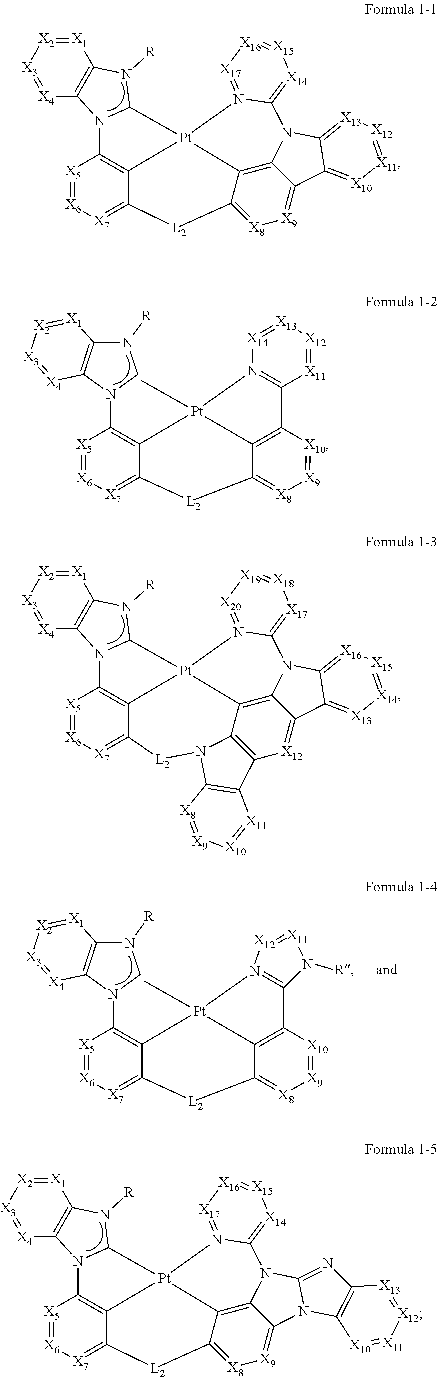
wherein in Formula 1-1 to Formula 1-5,
L₂ is, at each occurrence identically or differently, selected from a single bond, O, S, Se, (CR′R′)_{y}, (SiR′R′)_{y}, PR′, NR′, substituted or unsubstituted arylene having 6 to 30 carbon atoms, substituted or unsubstituted heteroarylene having 3 to 30 carbon atoms or a combination thereof; y is, at each occurrence identically or differently, selected from 0, 1, 2, 3, 4 or 5; when a plurality of R′ are present at the same time, the plurality of R′ are identical or different;
X₁ to X₂₀ are, at each occurrence identically or differently, selected from CRₓ or N;
the substituent R has a structure represented by Formula 3-1 or Formula 3-2: 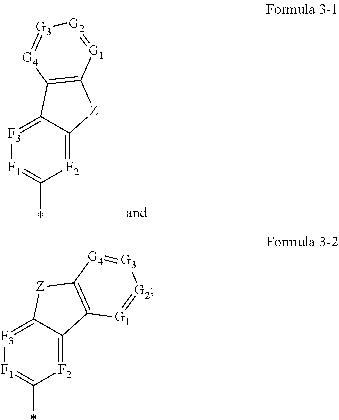
wherein in Formula 3-1 and Formula 3-2, F₁ and F₂ are each independently selected from CR_{f1}, CR_{F} or N, at least one of F₁ and F₂ is selected from CR_{f1}, and R_{f1} is identically or differently selected from the group consisting of: substituted or unsubstituted aryl having 6 to 30 carbon atoms, substituted or unsubstituted heteroaryl having 3 to 30 carbon atoms and combinations thereof;
F₃ is selected from CR_{f} or N;
G₁ to G₄ are each independently selected from CR_{g} or N;
Z is selected from NR_{z}, O, S or Se;
R′, R″, Rₓ, R_{f}, R_{F}, R_{g} and R_{z} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R′, R″, Rₓ, R_{f1}, R_{f}, R_{F}, R_{g} and R_{z} can be optionally joined to form a ring; and
preferably, the compound has a structure represented by Formula 1-1.

8. The compound of claim 7, wherein the L₂ is, at each occurrence identically or differently, selected from a single bond, O, S, (CR′R′)_{y}, (SiR′R′)_{y}, PR′, NR′ or a combination thereof; y is 1 or 2; and when a plurality of R′ are present at the same time, the plurality of R′ are identical or different;
preferably, the L₂ is, at each occurrence identically or differently, selected from a single bond, O or S; and
more preferably, the L₂ is selected from O.

9. The compound of claim 7, wherein both F₁ and F₂ are selected from CR_{f1}, and the R_{f1} is identically or differently selected from the group consisting of: substituted or unsubstituted aryl having 6 to 30 carbon atoms, substituted or unsubstituted heteroaryl having 3 to 30 carbon atoms and combinations thereof;
preferably, the R_{f1} is identically or differently selected from the group consisting of: substituted or unsubstituted aryl having 6 to 18 carbon atoms, substituted or unsubstituted heteroaryl having 3 to 18 carbon atoms and combinations thereof; and
more preferably, the R_{f1} is identically or differently selected from the group consisting of: substituted or unsubstituted phenyl, substituted or unsubstituted carbazolyl, substituted or unsubstituted indolyl, substituted or unsubstituted benzofuryl, substituted or unsubstituted dibenzofuryl, substituted or unsubstituted benzosilolyl, substituted or unsubstituted dibenzosilolyl, substituted or unsubstituted benzothienyl, substituted or unsubstituted dibenzothienyl, substituted or unsubstituted dibenzoselenophenyl and combinations thereof.

10. The compound of claim 7, wherein X₁ to X₂₀ are, at each occurrence identically or differently, selected from CRₓ; and/or F₃ is selected from CR_{f}; and/or G₁ to G₄ are each independently selected from CR_{g}.

11. The compound of claim 7, wherein the R′, R″, Rₓ, R_{f}, R_{F}, R_{g} and R_{z} are, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof; and
preferably, the R′, R″, Rₓ, R_{f}, R_{F}, R_{g} and R_{z} are, at each occurrence identically or differently, selected from the group consisting of: hydrogen, deuterium, fluorine, methyl, deuterated methyl, ethyl, n-propyl, isopropyl, cyclopropyl, n-butyl, isobutyl, t-butyl, cyclopentyl, cyclohexyl, phenyl, trimethylsilyl, carbazolyl, indolyl, benzofuranyl, dibenzofuranyl, benzosilolyl, dibenzosilolyl, benzothienyl, dibenzothienyl, dibenzoselenophenyl and combinations thereof.

12. The compound of claim 1, wherein the substituent R is, at each occurrence identically or differently, selected from the group consisting of An-1 to An-78: 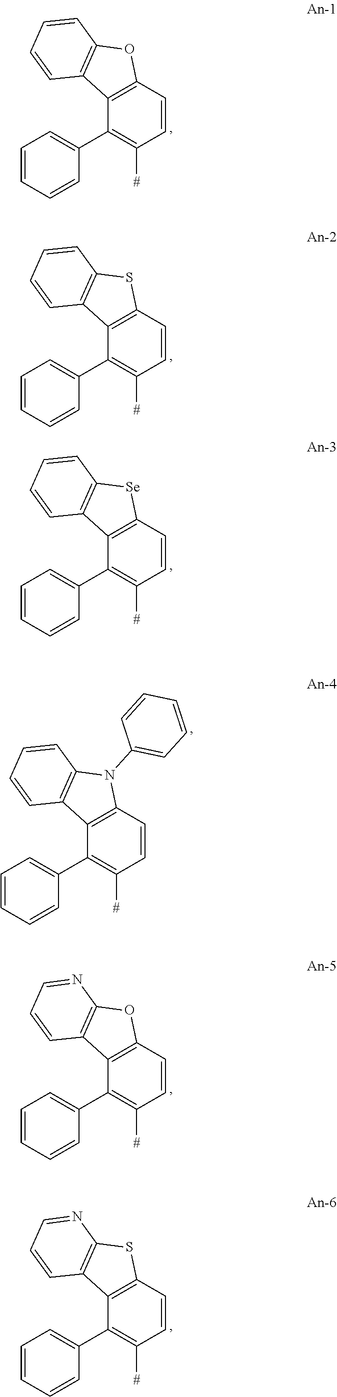 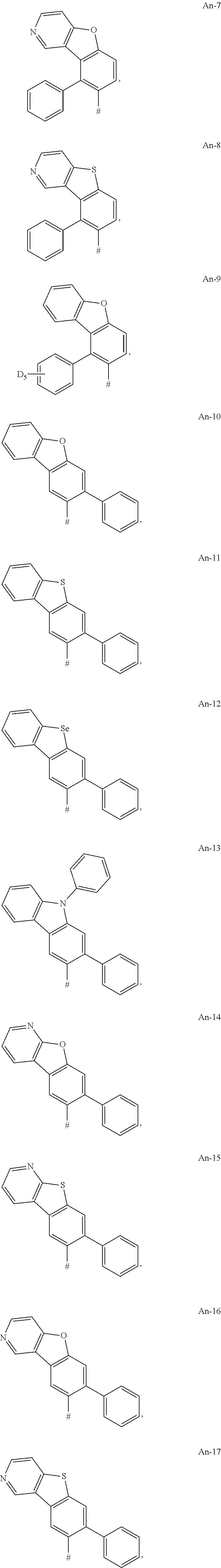 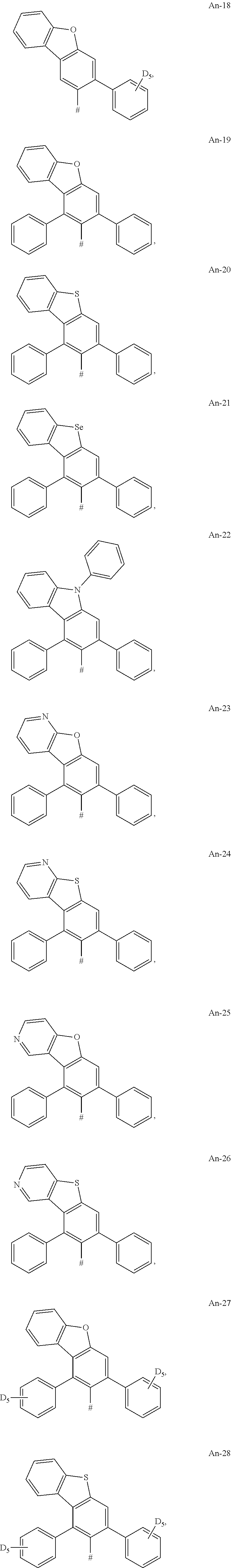 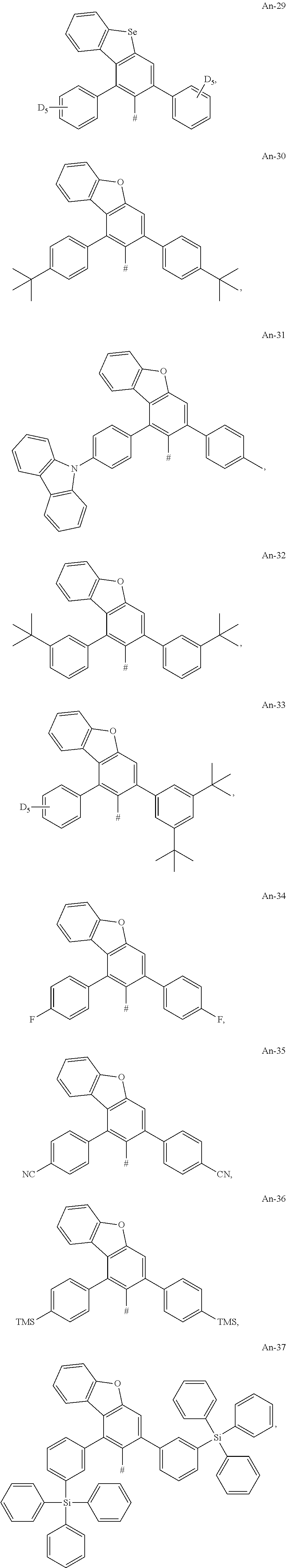 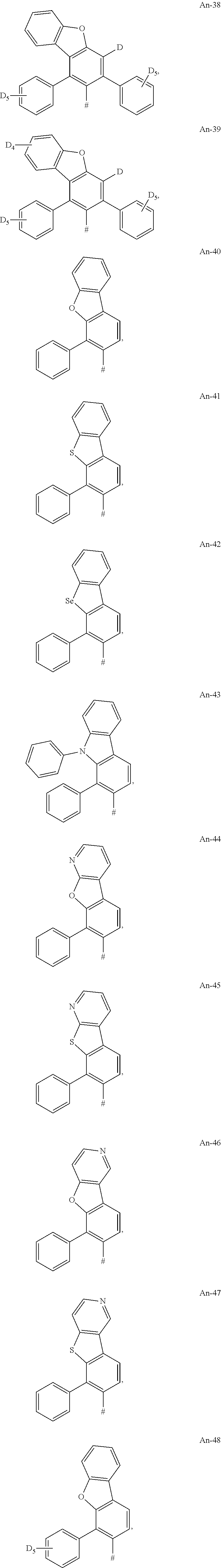 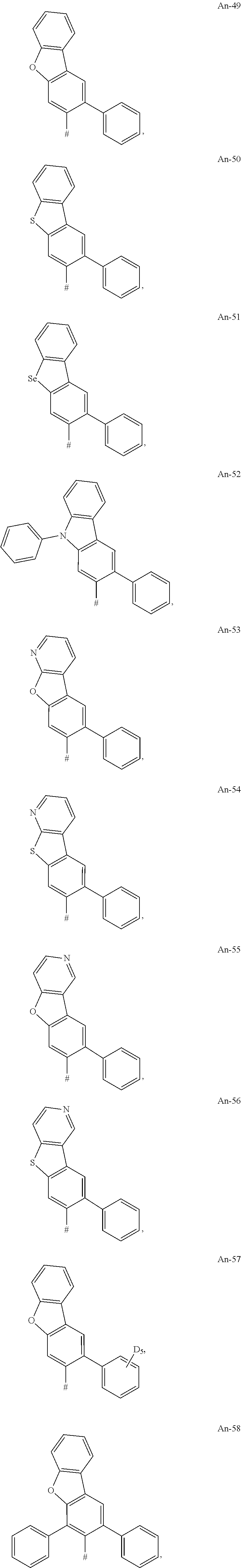 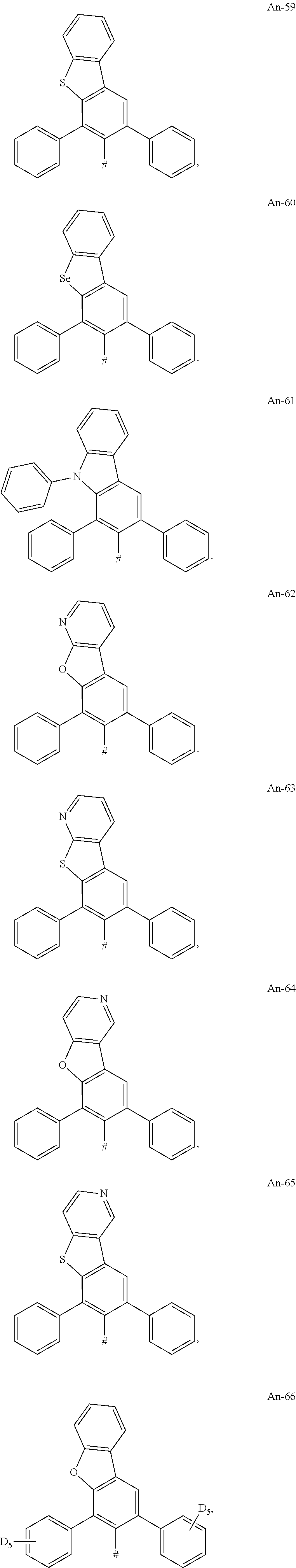 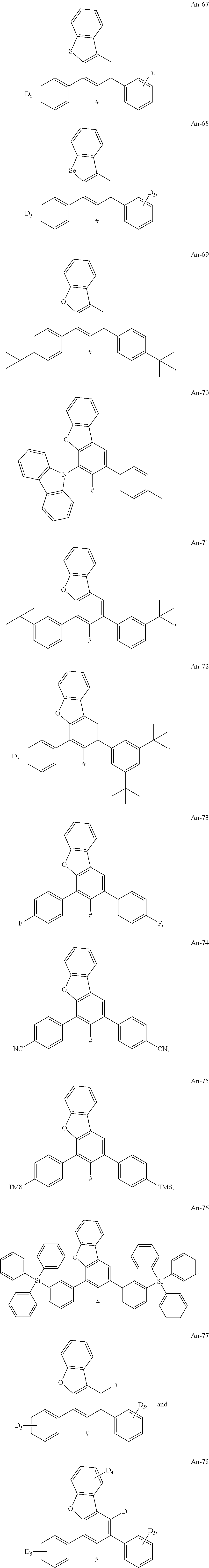
wherein optionally, hydrogens in An-1 to An-78 can be partially or fully substituted with deuterium.

13. The compound of claim 1, wherein the compound has a structure represented by Pt(Lₐ)(L_{b}), wherein Lₐ and L_{b} are a first ligand and a second ligand coordinated to the metal Pt, respectively, and Lₐ is selected from the group consisting of Lₐ1-1 to Lₐ1-16, Lₐ2-1 to Lₐ2-18, Lₐ3-1 to Lₐ3-16 and Lₐ4-1 to Lₐ4-18: 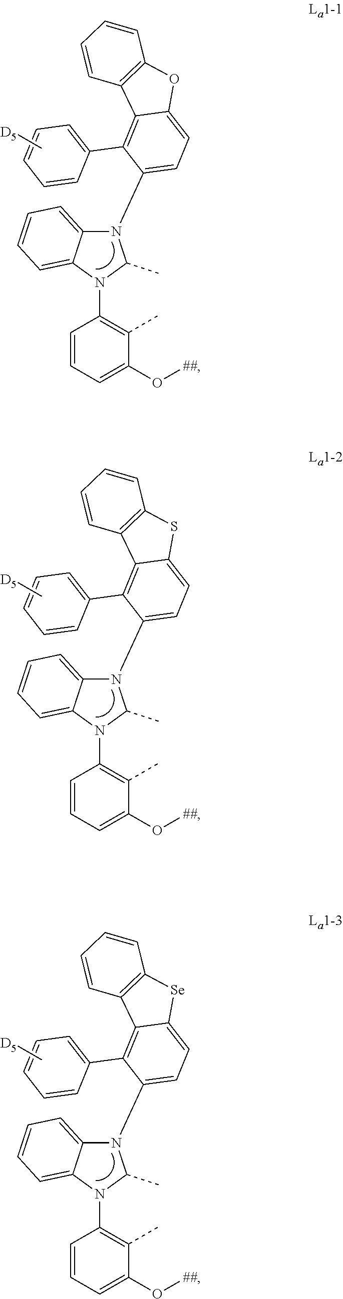 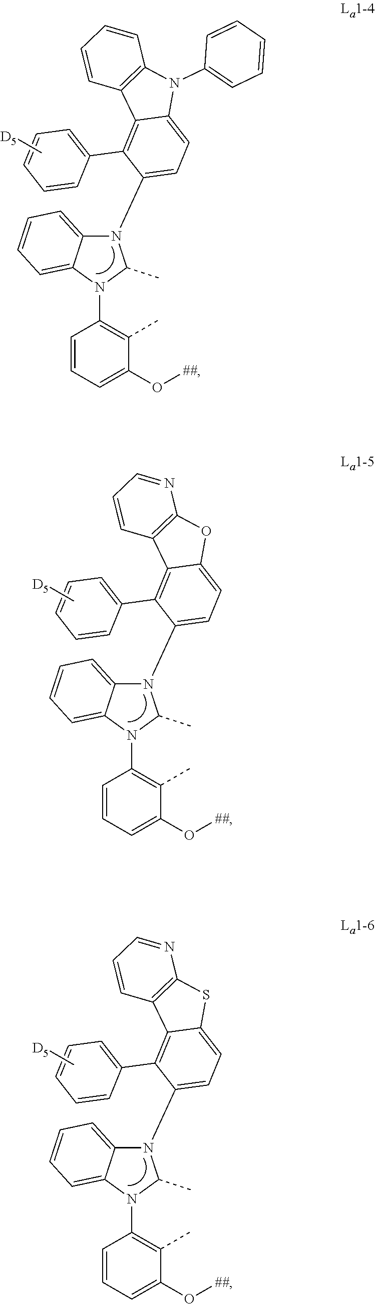 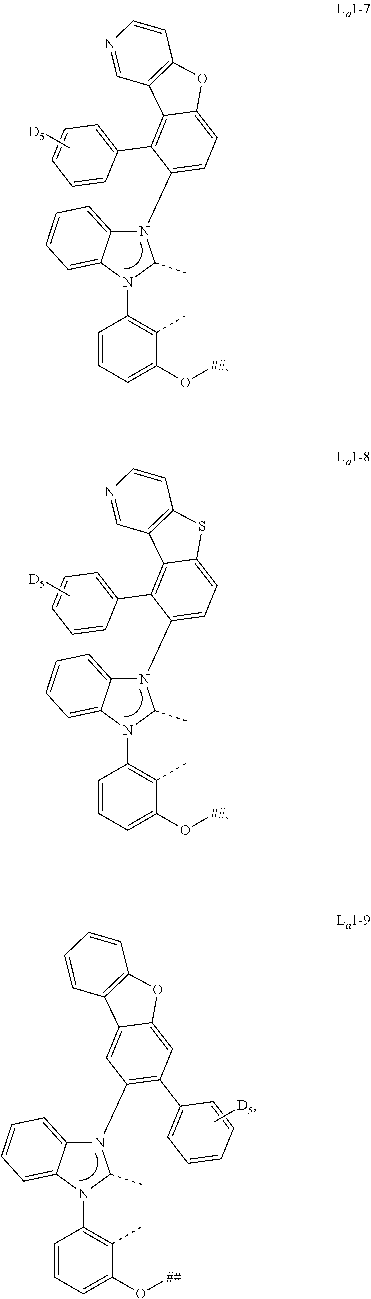 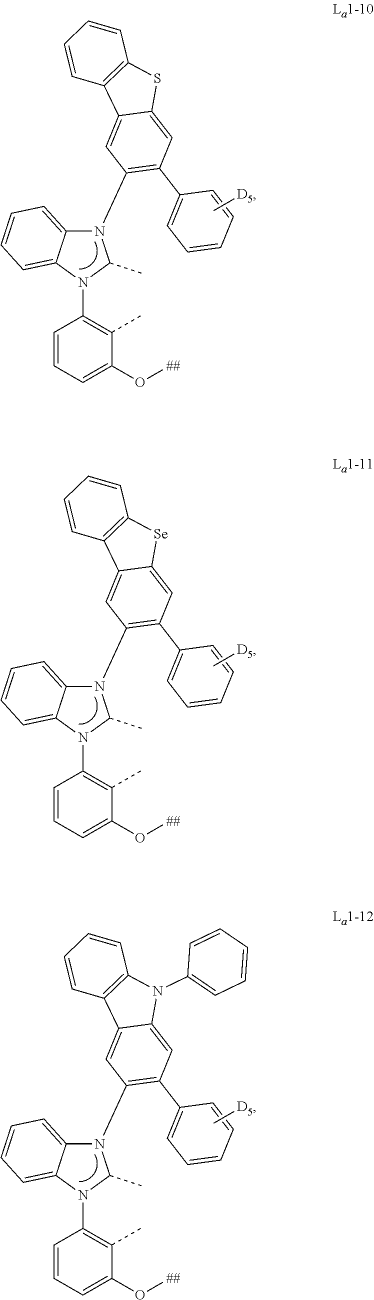 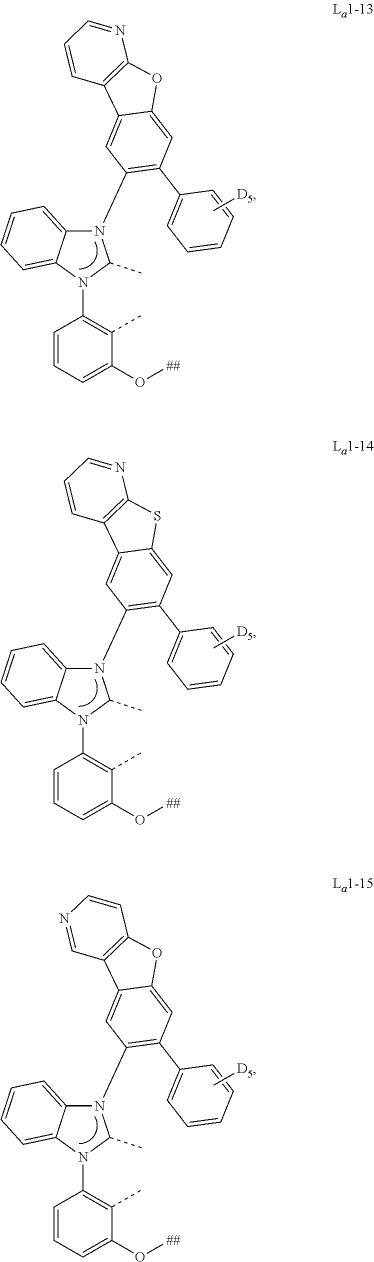 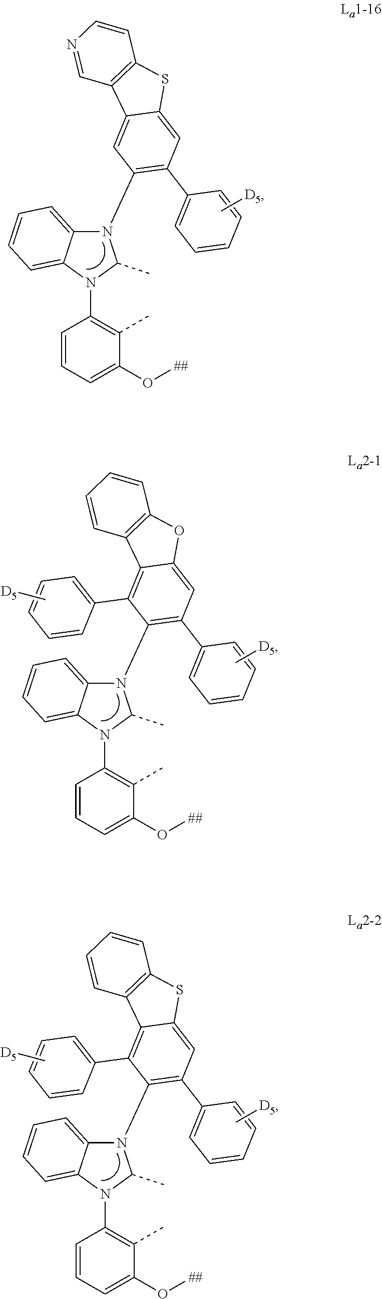 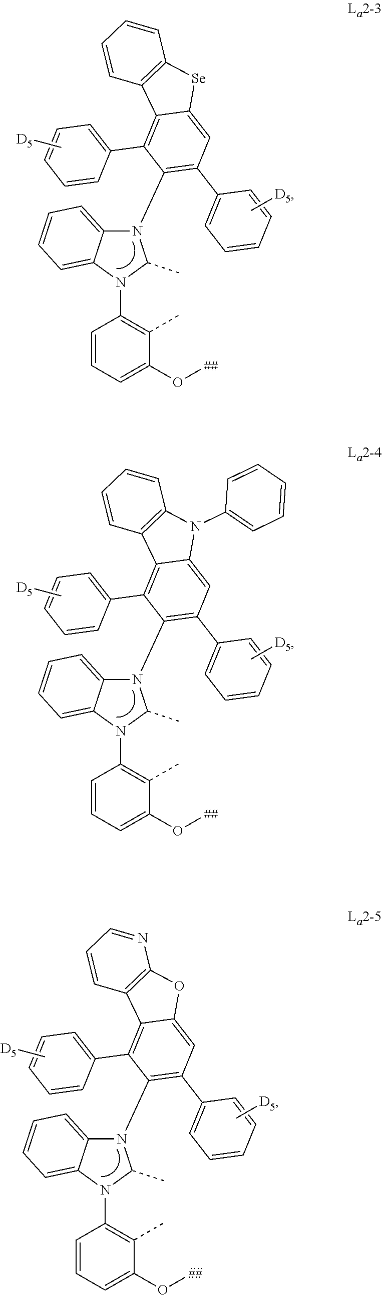 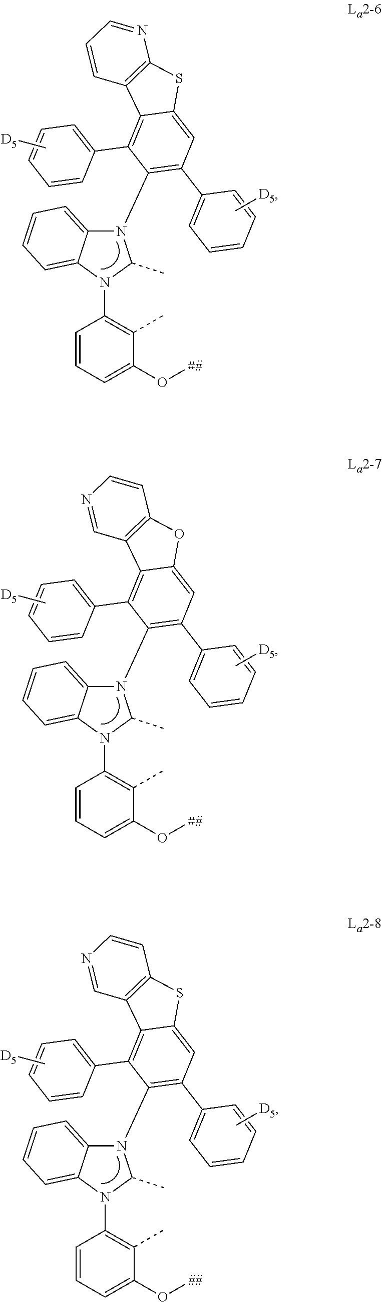 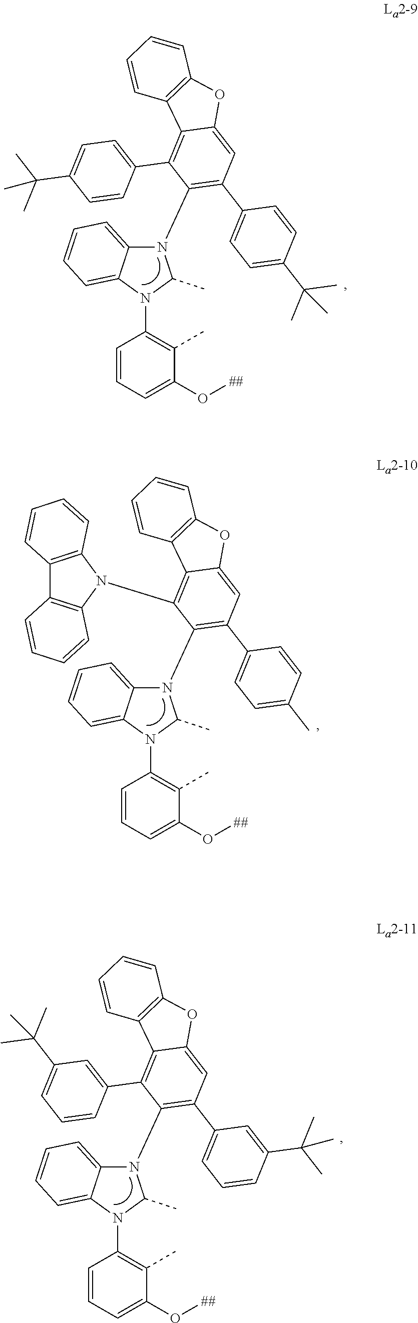 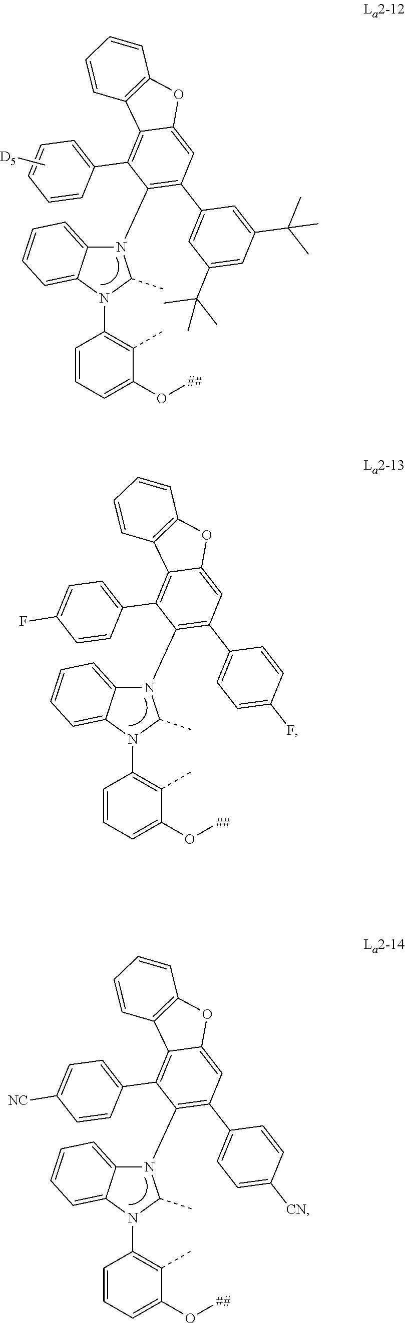 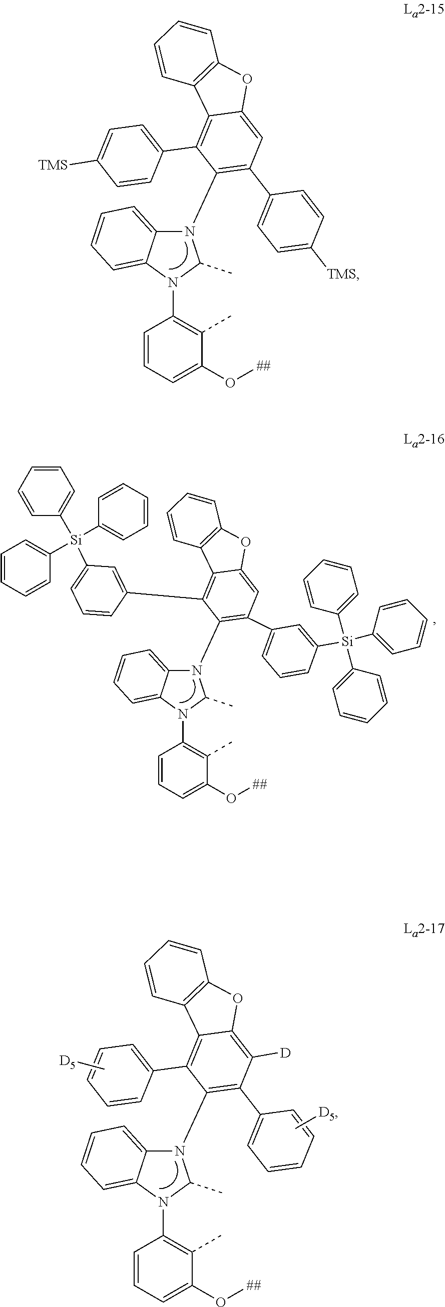 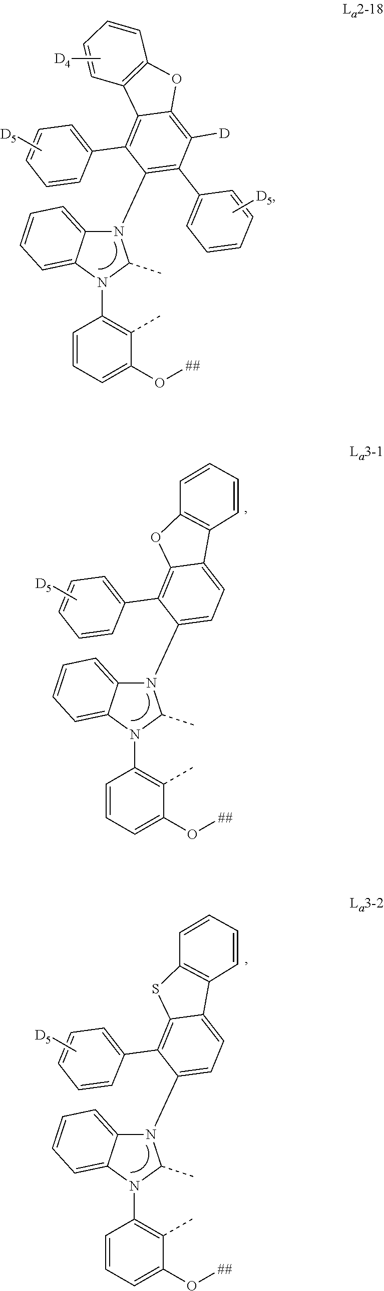 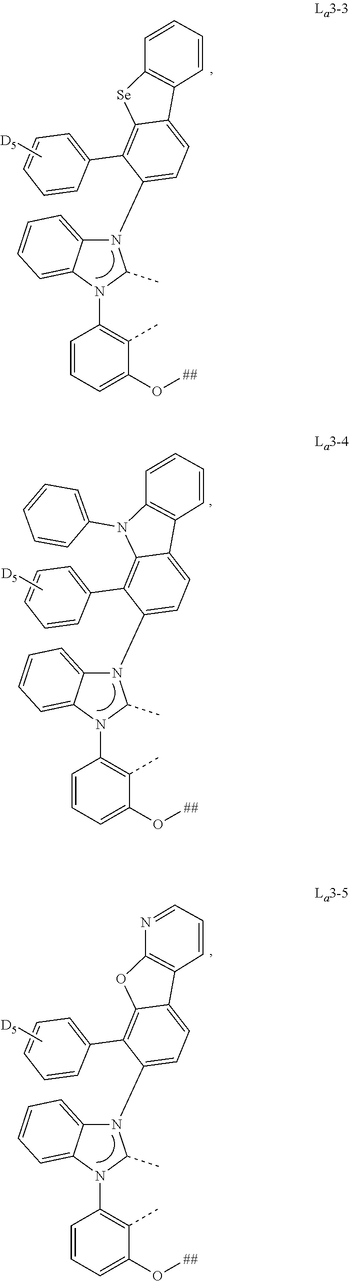 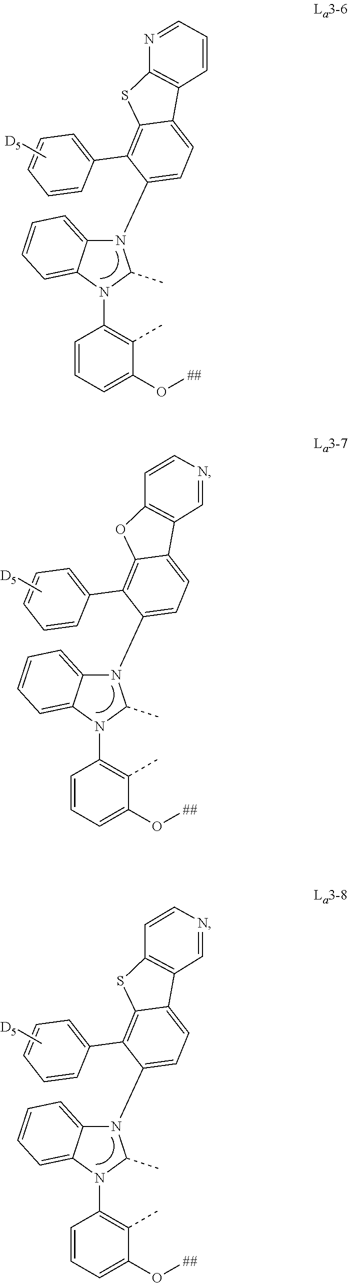 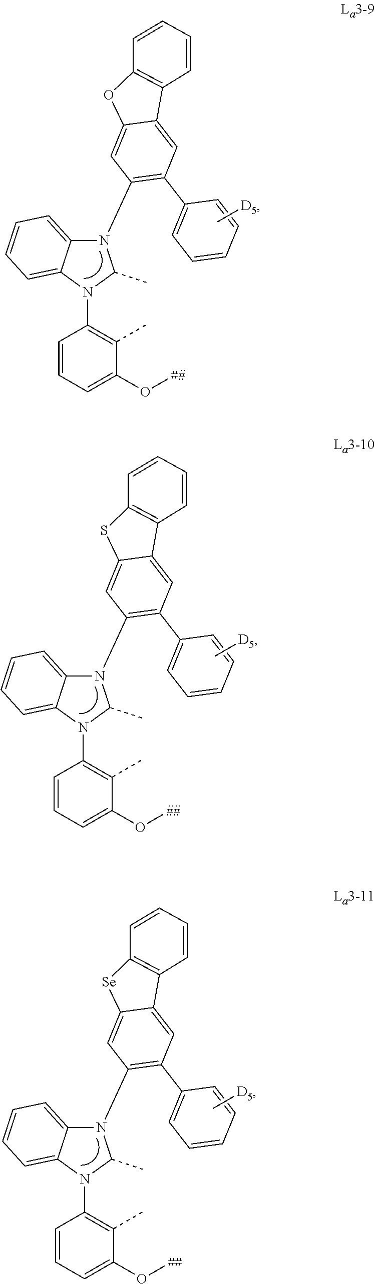 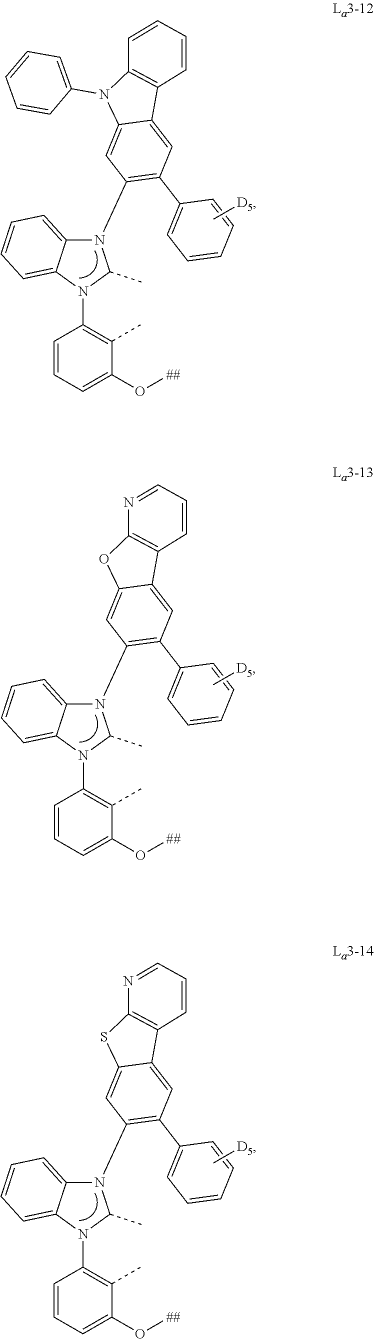 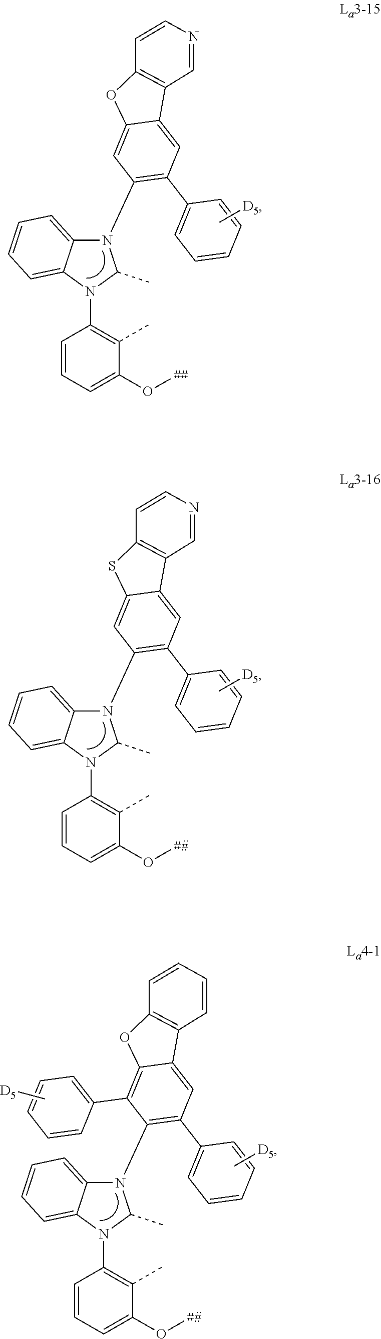 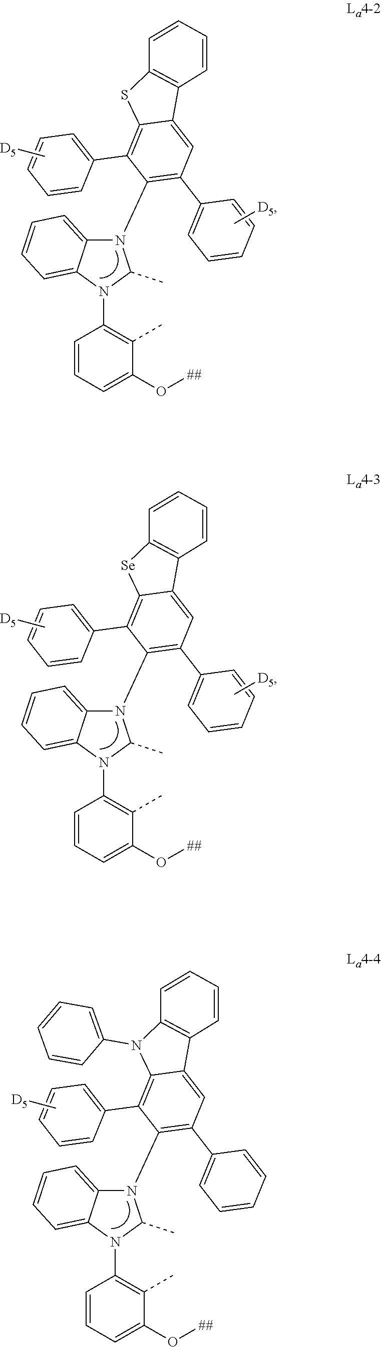 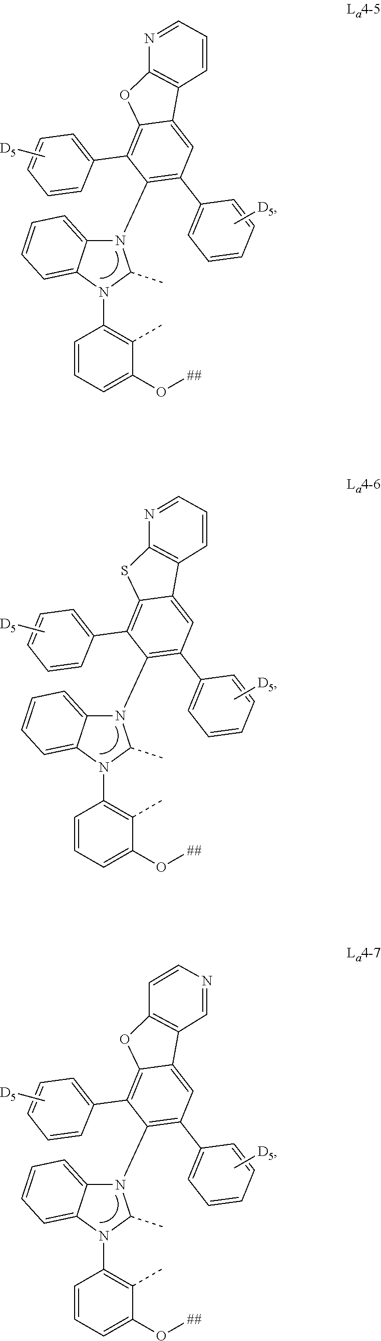 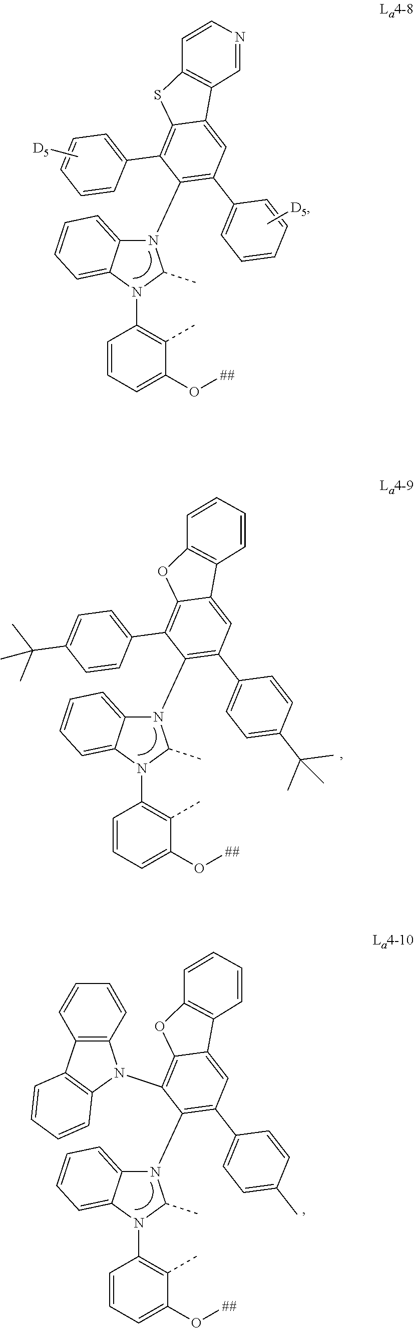 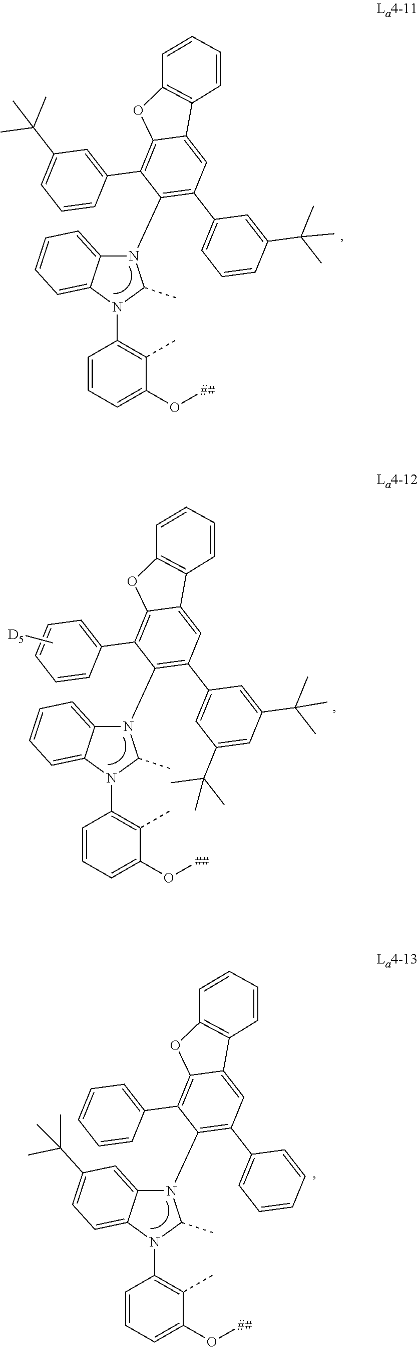 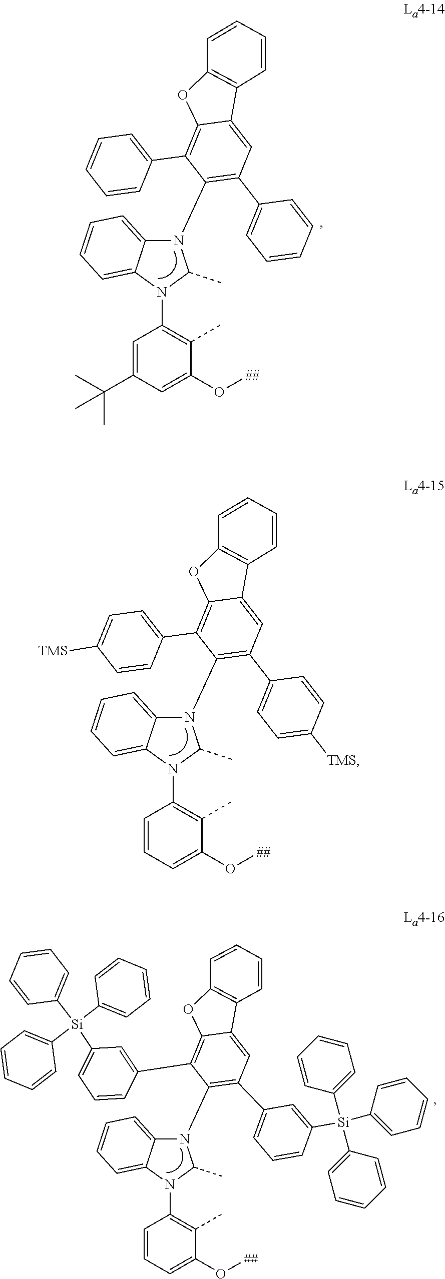 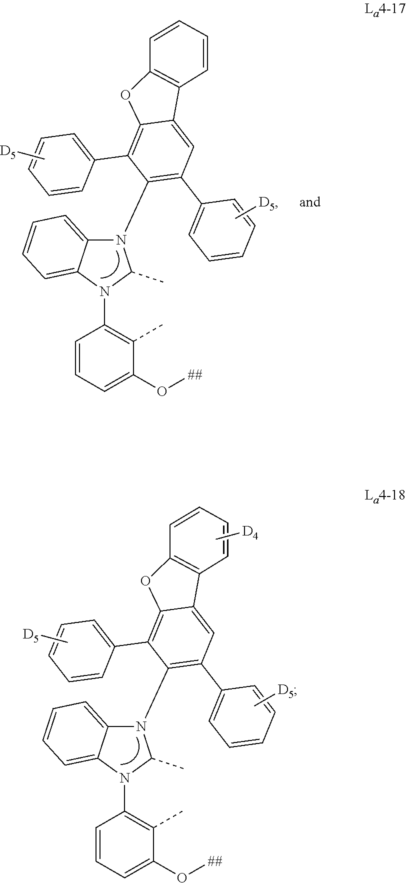
wherein “##” in the structure of Lₐ represents a position where the structure is joined to L_{b};
L_{b} is selected from the group consisting of L_{b}1-1 to L_{b}1-22, L_{b}2-1 to L_{b}2-30, L_{b}3-1 to L_{b}3-26, L_{b}4-1 to L_{b}4-25 and L_{b}5-1 to L_{b}5-11: 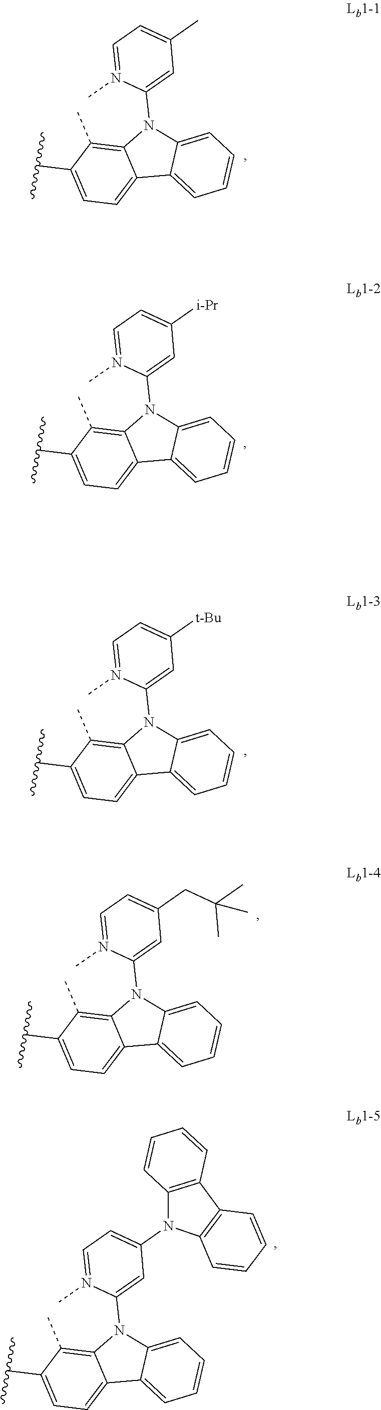 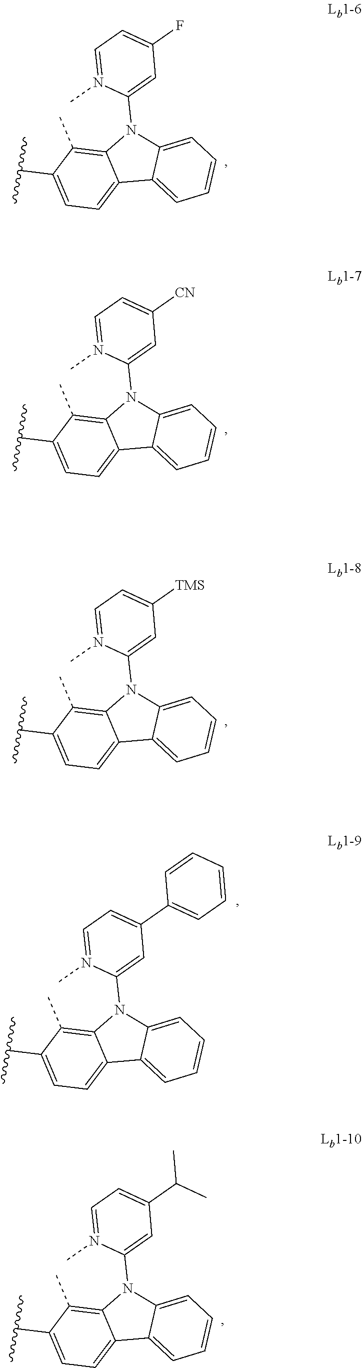 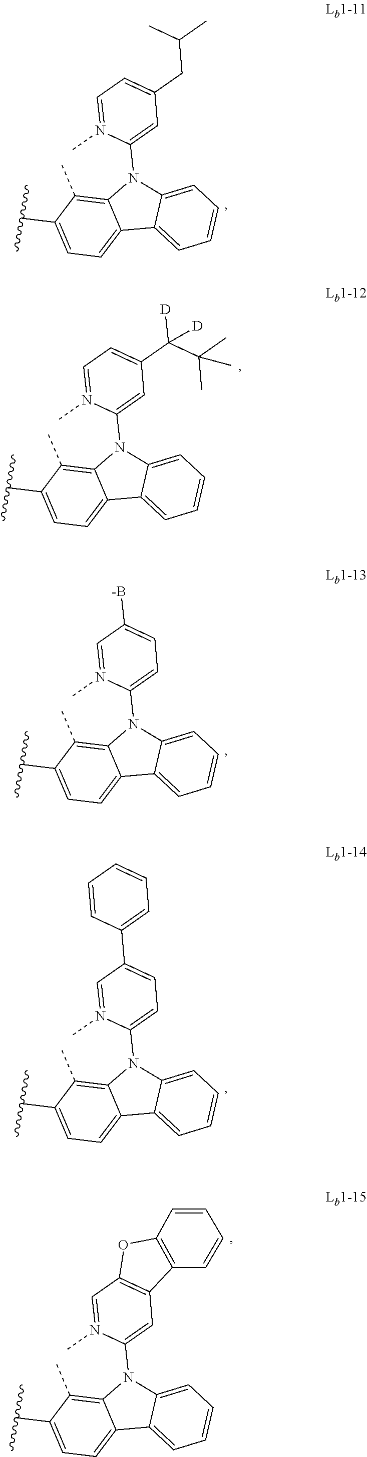 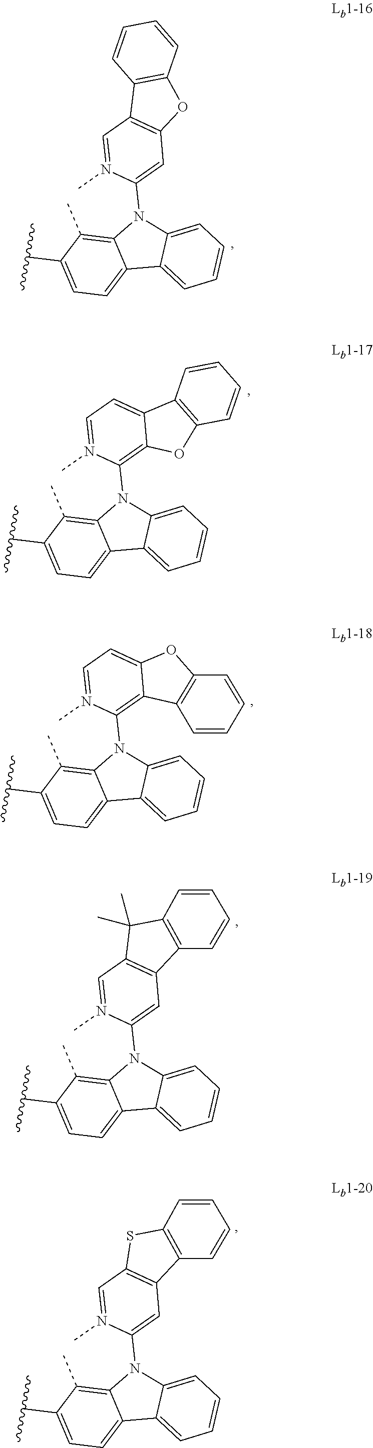 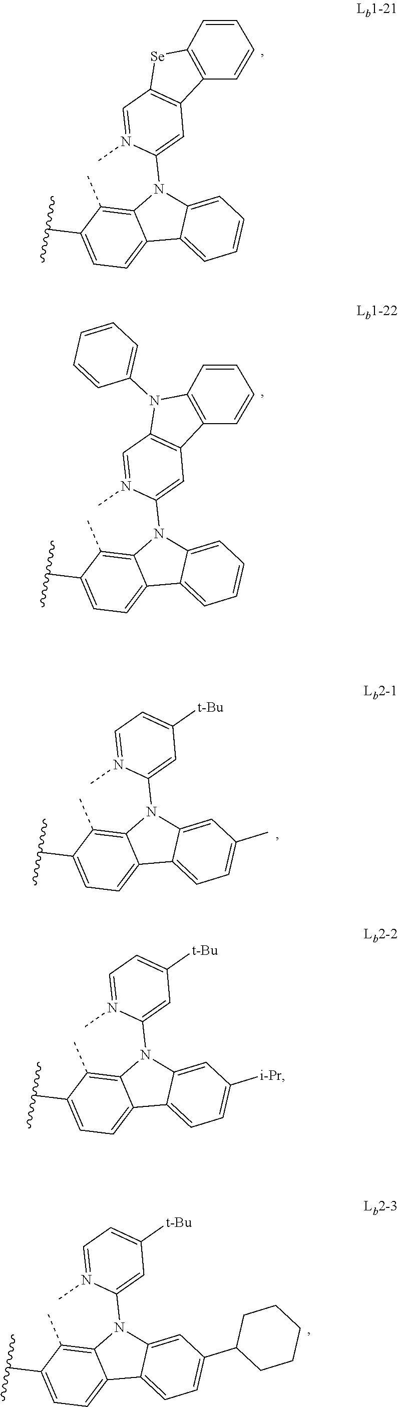 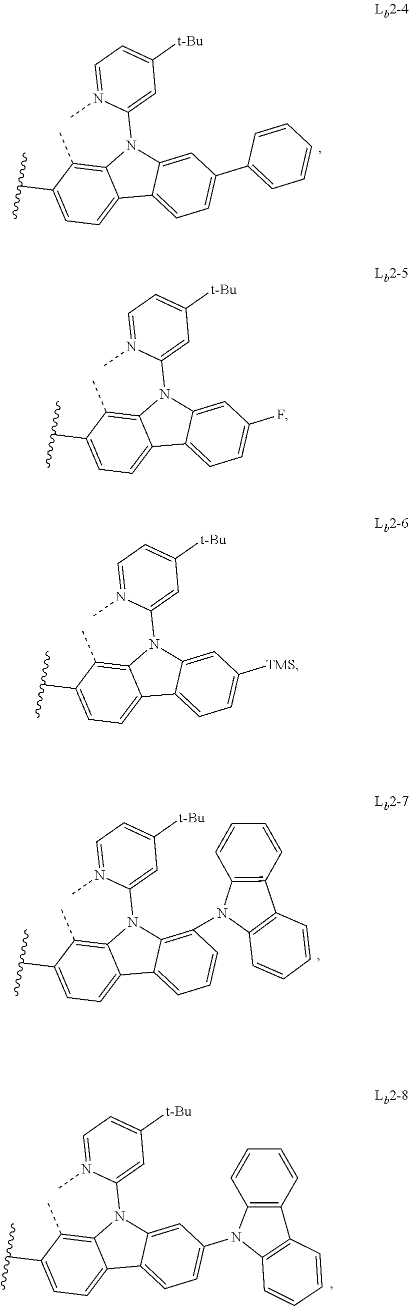 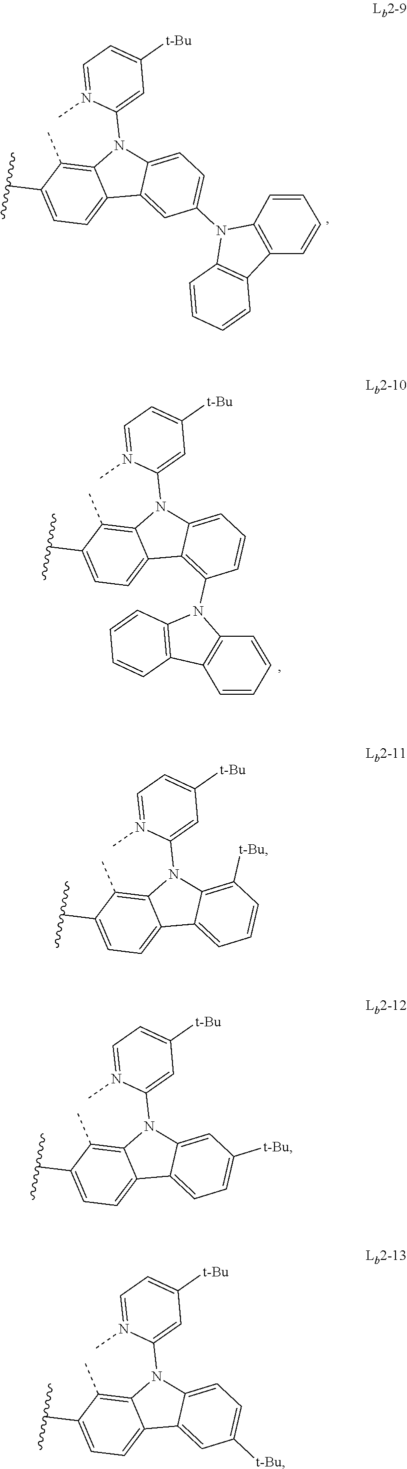 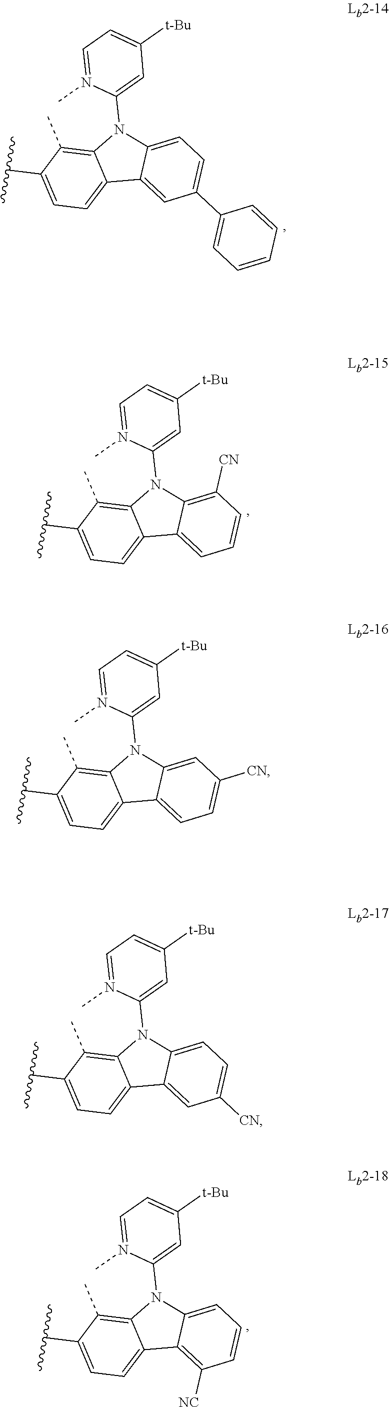 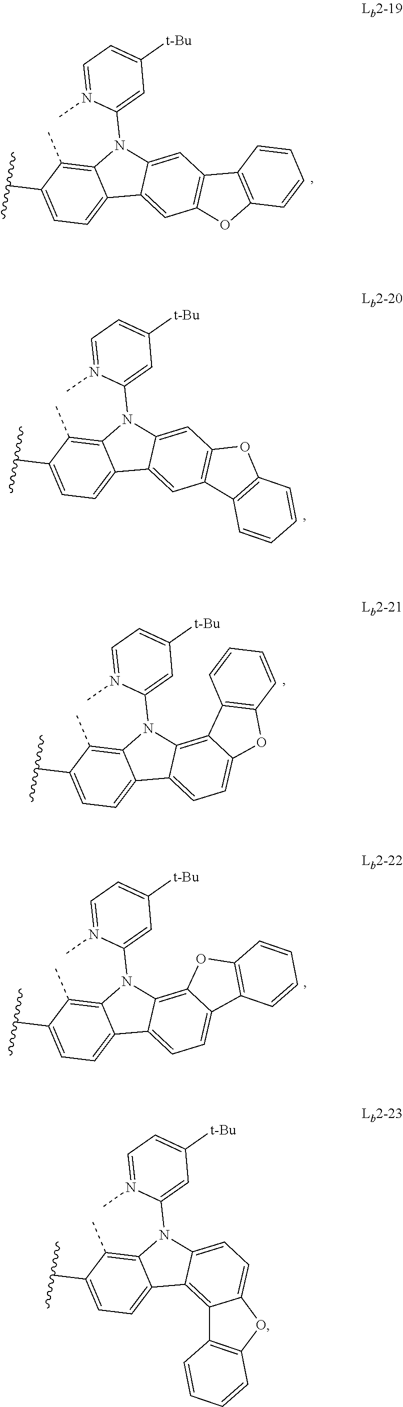 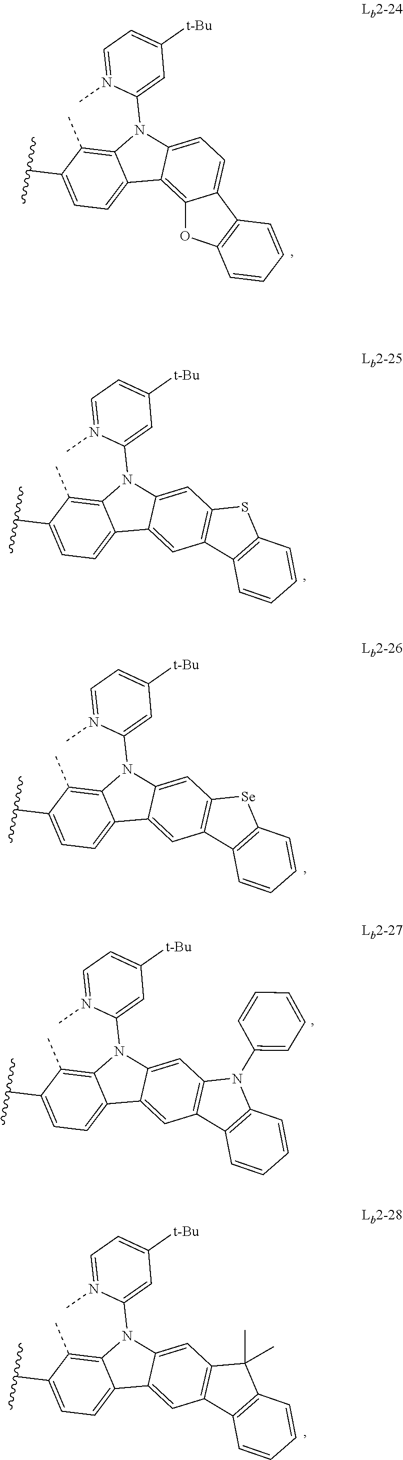 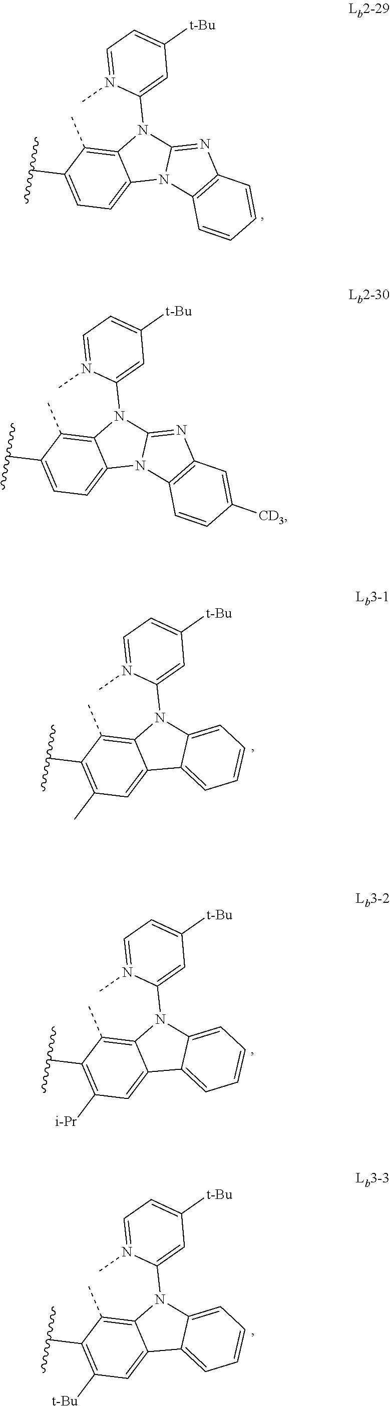 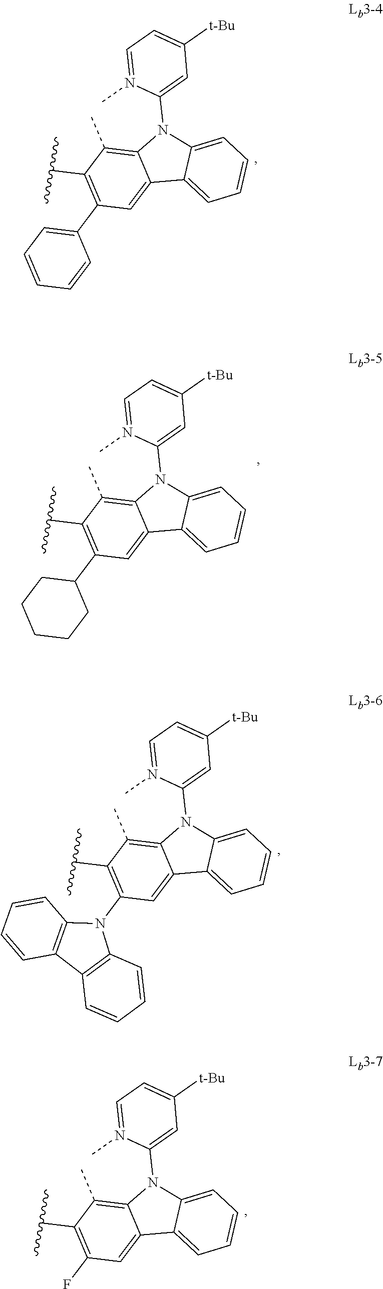 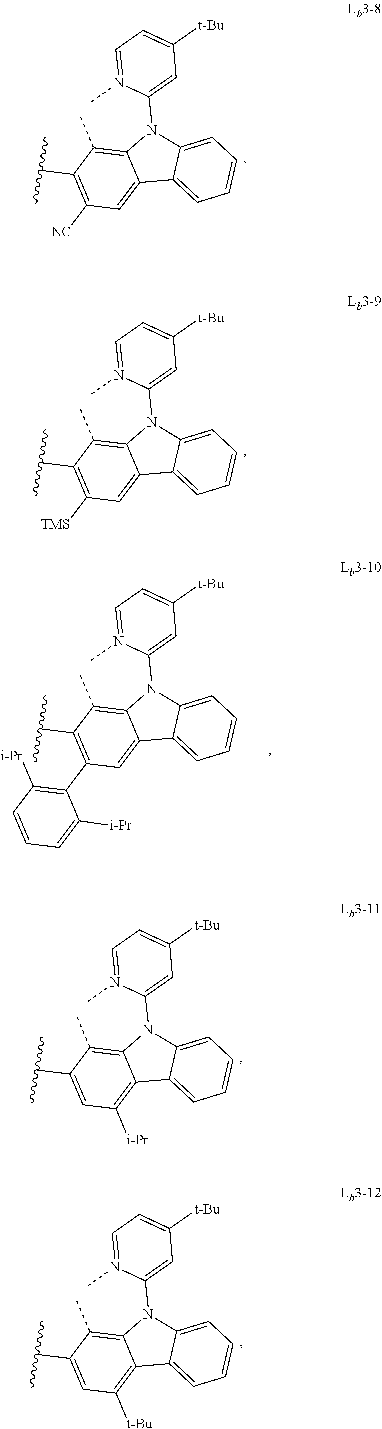 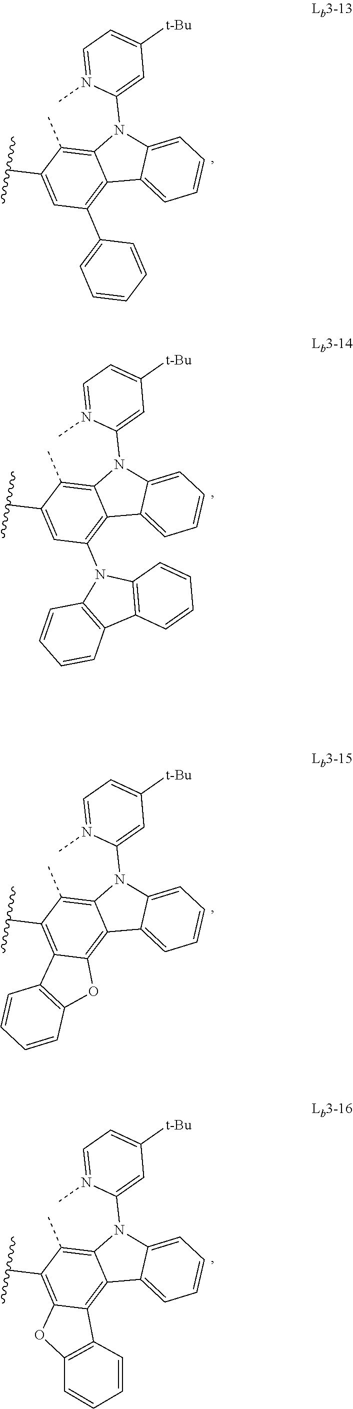 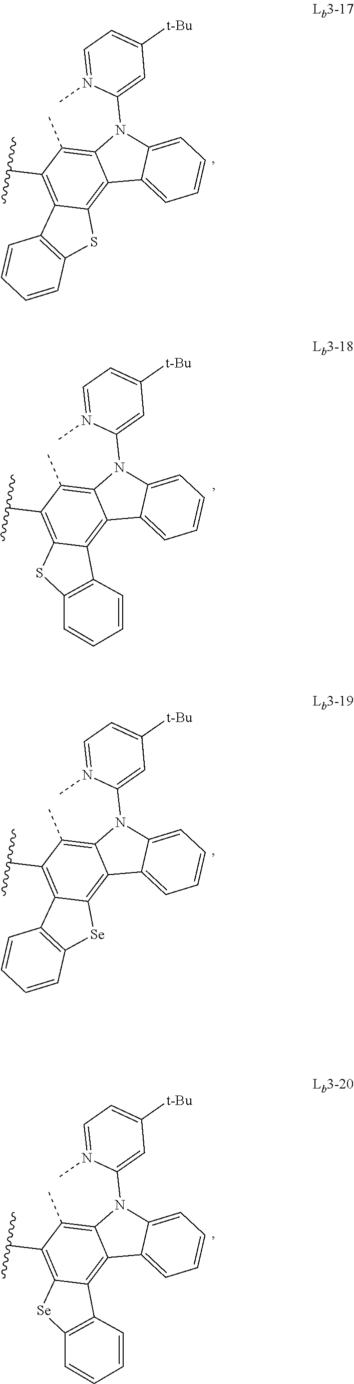 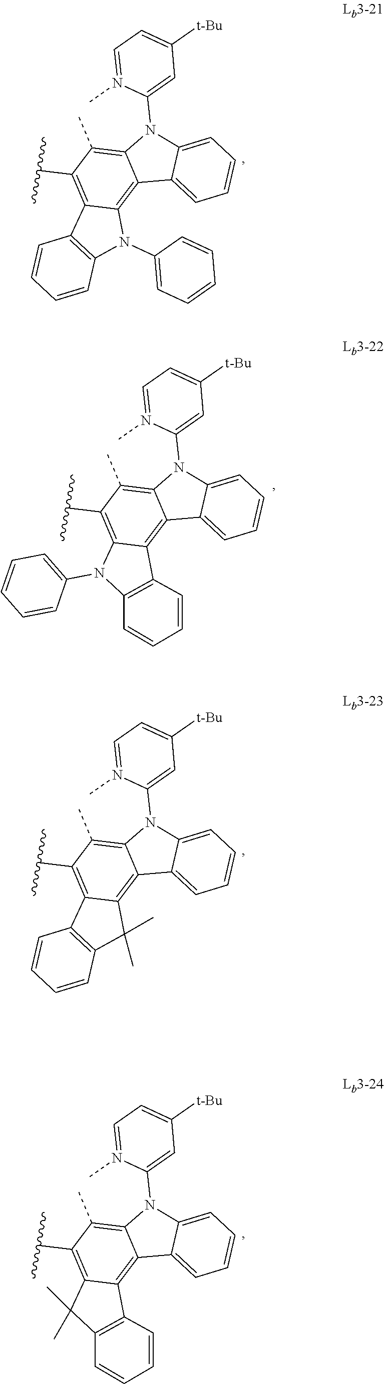 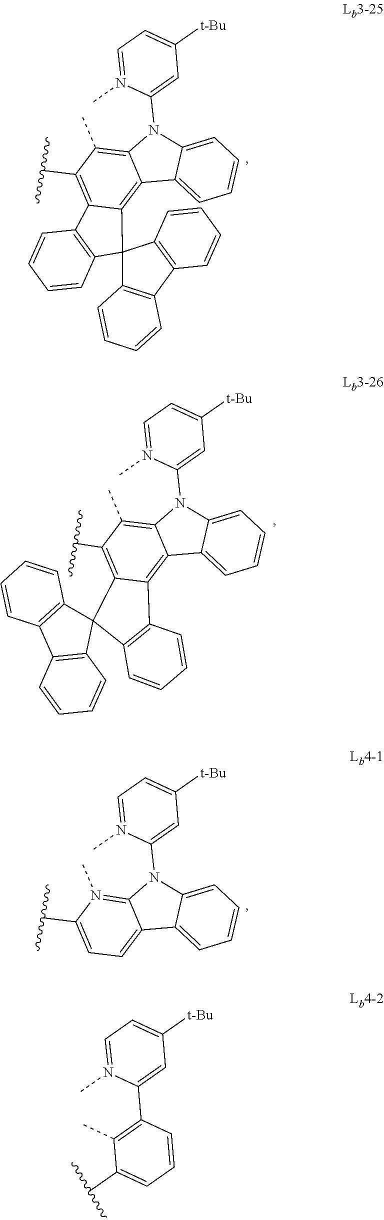 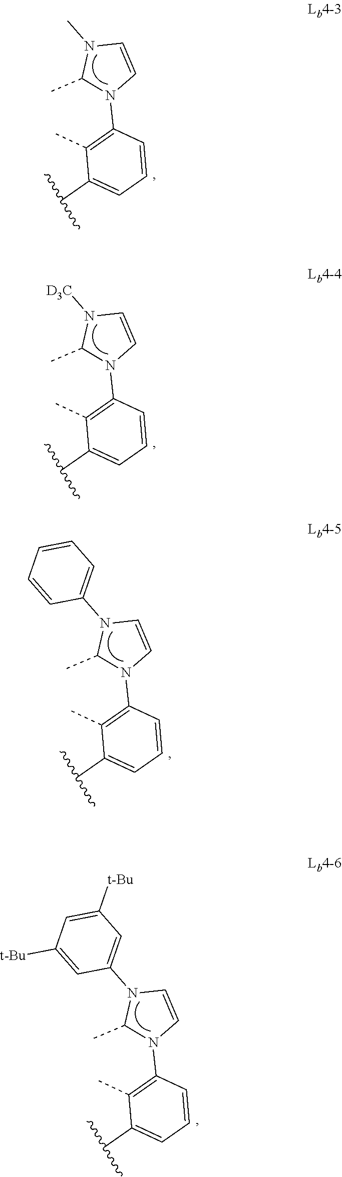 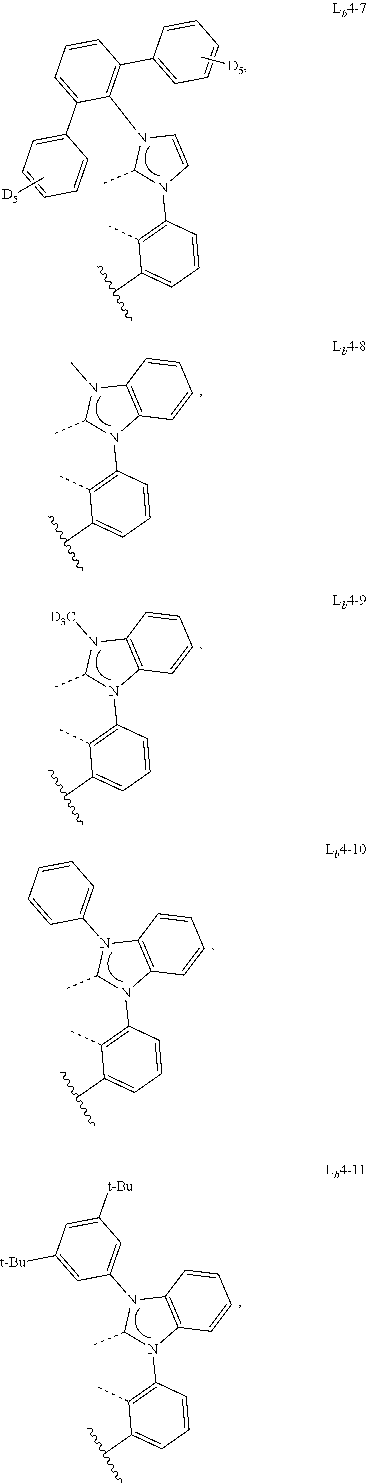 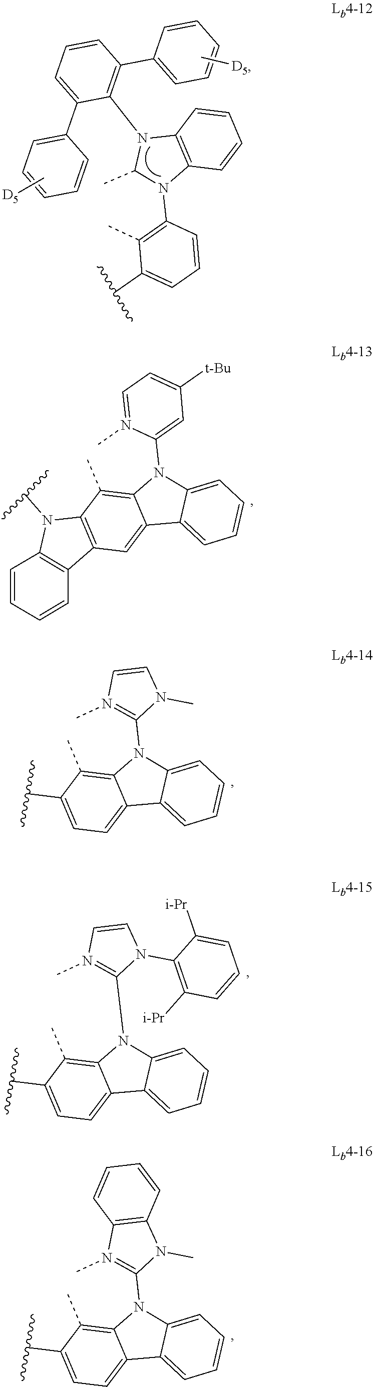 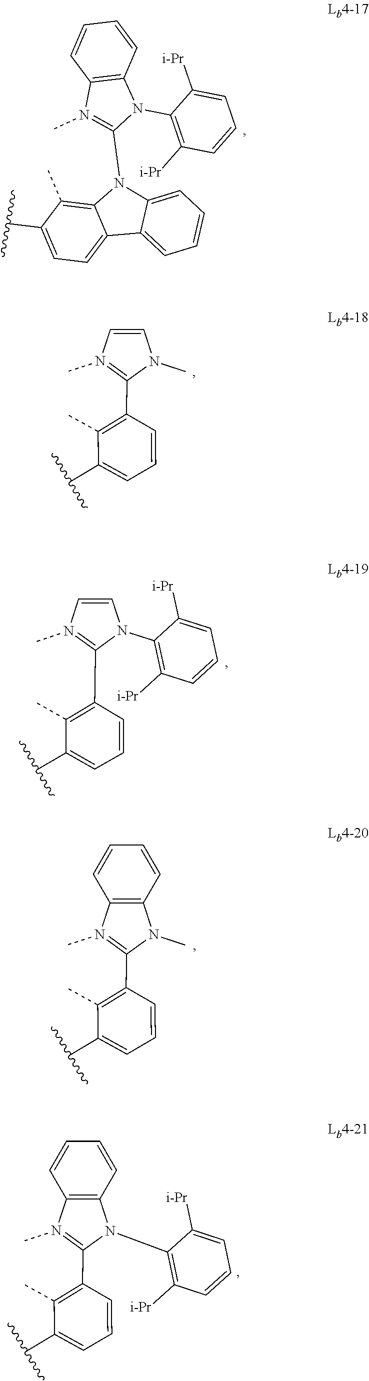 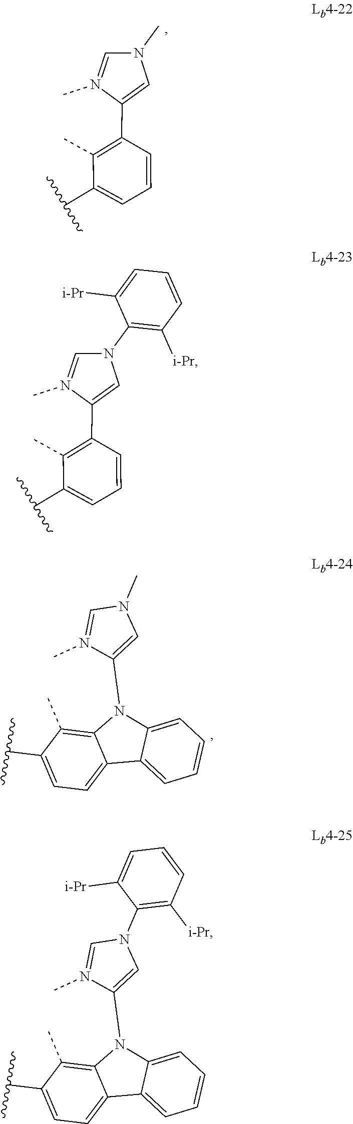 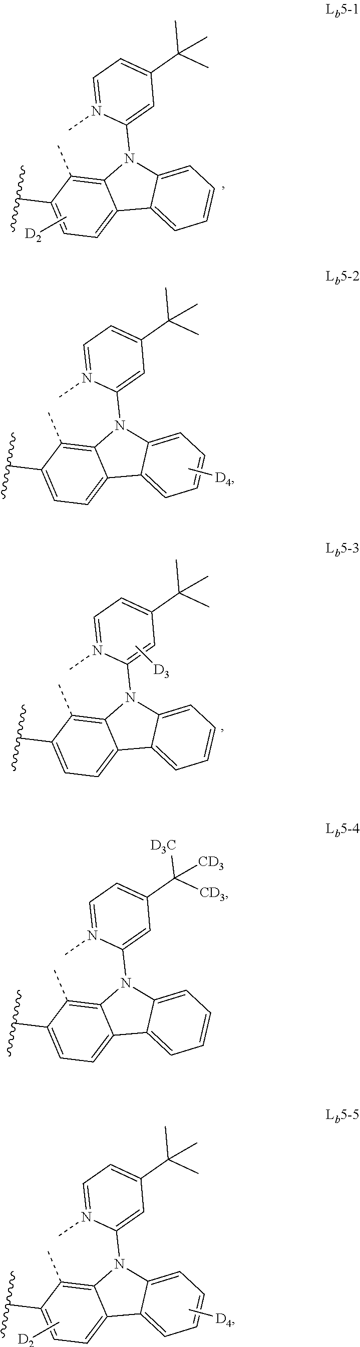 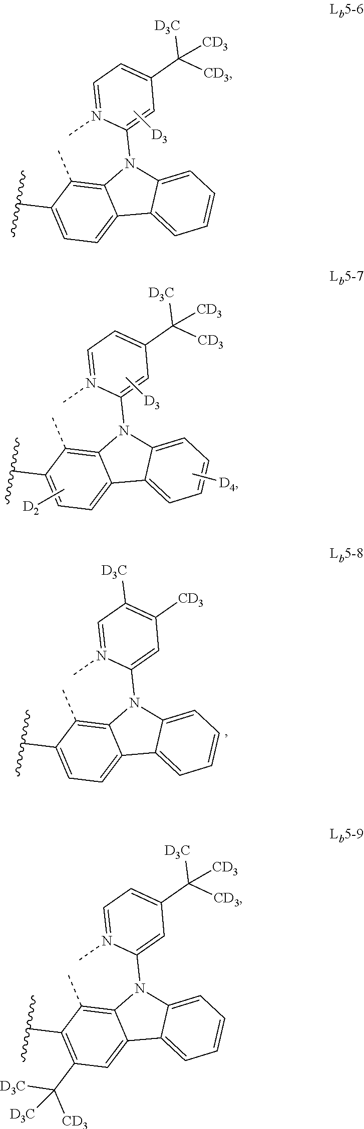 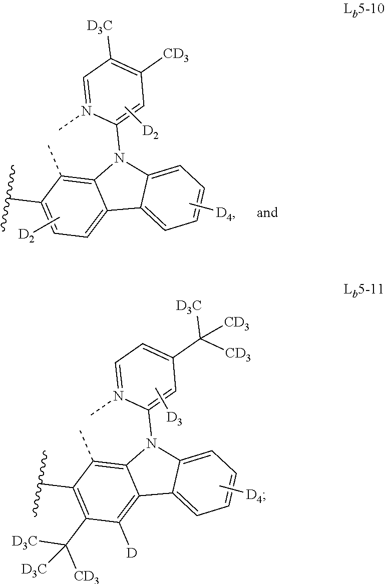
wherein “ [symbol] ” in the structure of L_{b} represents a position where the structure is joined to “##” in Lₐ;
in the structures of Lₐ and L_{b}, “t-Bu” represents t-butyl, “i-Pr” represents isopropyl, and “TMS” represents trimethylsilyl;
preferably, the compound is selected from the group consisting of Compound Pt1 to Compound Pt668:

| Compound | | | Compound | | |
|---|---|---|---|---|---|
| No | Lₐ | L_{b} | No. | Lₐ | L_{b} |
| Pt1 | La1-1 | Lb1-3 | Pt2 | La1-2 | Lb1-3 |
| Pt3 | La1-3 | Lb1-3 | Pt4 | La1-4 | Lb1-3 |
| Pt5 | La1-5 | Lb1-3 | Pt6 | La1-6 | Lb1-3 |
| Pt7 | La1-7 | Lb1-3 | Pt8 | La1-8 | Lb1-3 |
| Pt9 | La1-9 | Lb1-3 | Pt10 | La1-10 | Lb1-3 |
| Pt11 | La1-11 | Lb1-3 | Pt12 | La1-12 | Lb1-3 |
| Pt13 | La1-13 | Lb1-3 | Pt14 | La1-14 | Lb1-3 |
| Pt15 | La1-15 | Lb1-3 | Pt16 | La1-16 | Lb1-3 |
| Pt17 | La2-1 | Lb1-3 | Pt18 | La2-2 | Lb1-3 |
| Pt19 | La2-3 | Lb1-3 | Pt20 | La2-4 | Lb1-3 |
| Pt21 | La2-5 | Lb1-3 | Pt22 | La2-6 | Lb1-3 |
| Pt23 | La2-7 | Lb1-3 | Pt24 | La2-8 | Lb1-3 |
| Pt25 | La2-9 | Lb1-3 | Pt26 | La2-10 | Lb1-3 |
| Pt27 | La2-11 | Lb1-3 | Pt28 | La2-12 | Lb1-3 |
| Pt29 | La2-13 | Lb1-3 | Pt30 | La2-14 | Lb1-3 |
| Pt31 | La2-15 | Lb1-3 | Pt32 | La2-16 | Lb1-3 |
| Pt33 | La2-17 | Lb1-3 | Pt34 | La2-18 | Lb1-3 |
| Pt35 | La3-1 | Lb1-3 | Pt36 | La3-2 | Lb1-3 |
| Pt37 | La3-3 | Lb1-3 | Pt38 | La3-4 | Lb1-3 |
| Pt39 | La3-5 | Lb1-3 | Pt40 | La3-6 | Lb1-3 |
| Pt41 | La3-7 | Lb1-3 | Pt42 | La3-8 | Lb1-3 |
| Pt43 | La3-9 | Lb1-3 | Pt44 | La3-10 | Lb1-3 |
| Pt45 | La3-11 | Lb1-3 | Pt46 | La3-12 | Lb1-3 |
| Pt47 | La3-13 | Lb1-3 | Pt48 | La3-14 | Lb1-3 |
| Pt49 | La3-15 | Lb1-3 | Pt50 | La3-16 | Lb1-3 |
| Pt51 | La4-1 | Lb1-3 | Pt52 | La4-2 | Lb1-3 |
| Pt53 | La4-3 | Lb1-3 | Pt54 | La4-4 | Lb1-3 |
| Pt55 | La4-5 | Lb1-3 | Pt56 | La4-6 | Lb1-3 |
| Pt57 | La4-7 | Lb1-3 | Pt58 | La4-8 | Lb1-3 |
| Pt59 | La4-9 | Lb1-3 | Pt60 | La4-10 | Lb1-3 |
| Pt61 | La4-11 | Lb1-3 | Pt62 | La4-12 | Lb1-3 |
| Pt63 | La4-13 | Lb1-3 | Pt64 | La4-14 | Lb1-3 |
| Pt65 | La4-15 | Lb1-3 | Pt66 | La4-16 | Lb1-3 |
| Pt67 | La4-17 | Lb1-3 | Pt68 | La4-18 | Lb1-3 |
| Pt69 | La1-1 | Lb1-12 | Pt70 | La1-2 | Lb1-12 |
| Pt71 | La1-3 | Lb1-12 | Pt72 | La1-4 | Lb1-12 |
| Pt73 | La1-5 | Lb1-12 | Pt74 | La1-6 | Lb1-12 |
| Pt75 | La1-7 | Lb1-12 | Pt76 | La1-8 | Lb1-12 |
| Pt77 | La1-9 | Lb1-12 | Pt78 | La1-10 | Lb1-12 |
| Pt79 | La1-11 | Lb1-12 | Pt80 | La1-12 | Lb1-12 |
| Pt81 | La1-13 | Lb1-12 | Pt82 | La1-14 | Lb1-12 |
| Pt83 | La1-15 | Lb1-12 | Pt84 | La1-16 | Lb1-12 |
| Pt85 | La2-1 | Lb1-12 | Pt86 | La2-2 | Lb1-12 |
| Pt87 | La2-3 | Lb1-12 | Pt88 | La2-4 | Lb1-12 |
| Pt89 | La2-5 | Lb1-12 | Pt90 | La2-6 | Lb1-12 |
| Pt91 | La2-7 | Lb1-12 | Pt92 | La2-8 | Lb1-12 |
| Pt93 | La2-9 | Lb1-12 | Pt94 | La2-10 | Lb1-12 |
| Pt95 | La2-11 | Lb1-12 | Pt96 | La2-12 | Lb1-12 |
| Pt97 | La2-13 | Lb1-12 | Pt98 | La2-14 | Lb1-12 |
| Pt99 | La2-15 | Lb1-12 | Pt100 | La2-16 | Lb1-12 |
| Pt101 | La2-17 | Lb1-12 | Pt102 | La2-18 | Lb1-12 |
| Pt103 | La3-1 | Lb1-12 | Pt104 | La3-2 | Lb1-12 |
| Pt105 | La3-3 | Lb1-12 | Pt106 | La3-4 | Lb1-12 |
| Pt107 | La3-5 | Lb1-12 | Pt108 | La3-6 | Lb1-12 |
| Pt109 | La3-7 | Lp1-12 | Pt110 | L23-8 | Lb1-12 |
| Pt111 | La3-9 | Lb1-12 | Pt112 | La3-10 | Lb1-12 |
| Pt113 | La3-11 | Lb1-12 | Pt114 | La3-12 | Lb1-12 |
| Pt115 | La3-13 | Lb1-12 | Pt116 | La3-14 | Lb1-12 |
| Pt117 | La3-15 | Lb1-12 | Pt118 | La3-16 | Lb1-12 |
| Pt119 | La4-1 | Lb1-12 | Pt120 | La4-2 | Lb1-12 |
| Pt121 | La4-3 | Lb1-12 | Pt122 | La4-4 | Lb1-12 |
| Pt123 | La4-5 | Lb1-12 | Pt124 | La4-6 | Lb1-12 |
| Pt125 | La4-7 | Lb1-12 | Pt126 | La4-8 | Lb1-12 |
| Pt127 | La4-9 | Lb1-12 | Pt128 | La4-10 | Lb1-12 |
| Pt129 | La4-11 | Lb1-12 | Pt130 | La4-12 | Lb1-12 |
| Pt131 | La4-13 | Lb1-12 | Pt132 | La4-14 | Lb1-12 |
| Pt133 | La4-15 | Lb1-12 | Pt134 | La4-16 | Lb1-12 |
| Pt135 | La4-17 | Lb1-12 | Pt136 | La4-18 | Lb1-12 |
| Pt137 | La1-1 | Lb1-1 | Pt138 | La1-1 | Lb1-2 |
| Pt139 | La1-1 | Lb1-4 | Pt140 | La1-1 | Lb1-5 |
| Pt141 | La1-1 | Lb1-6 | Pt142 | La1-1 | Lb1-7 |
| Pt143 | La1-1 | Lb1-8 | Pt144 | La1-1 | Lb1-9 |
| Pt145 | La1-1 | Lb1-10 | Pt146 | La1-1 | Lb1-11 |
| Pt147 | La1-1 | Lb1-13 | Pt148 | La1-1 | Lb1-14 |
| Pt149 | La1-1 | Lb1-15 | Pt150 | La1-1 | Lb1-16 |
| Pt151 | La1-1 | Lb1-17 | Pt152 | La1-1 | Lb1-18 |
| Pt153 | La1-1 | Lb1-19 | Pt154 | La1-1 | Lb1-20 |
| Pt155 | La1-1 | Lb1-21 | Pt156 | La1-1 | Lb1-22 |
| Pt157 | La1-1 | Lb2-1 | Pt158 | La1-1 | Lb2-2 |
| Pt159 | La1-1 | Lb2-3 | Pt160 | La1-1 | Lb2-4 |
| Pt161 | La1-1 | Lb2-5 | Pt162 | La1-1 | Lb2-6 |
| Pt163 | La1-1 | Lb2-7 | Pt164 | La1-1 | Lb2-8 |
| Pt165 | La1-1 | Lb2-9 | Pt166 | La1-1 | Lb2-10 |
| Pt167 | La1-1 | Lb2-11 | Pt168 | La1-1 | Lb2-12 |
| Pt169 | La1-1 | Lb2-13 | Pt170 | La1-1 | Lb2-14 |
| Pt171 | La1-1 | Lb2-15 | Pt172 | La1-1 | Lb2-16 |
| Pt173 | La1-1 | Lb2-17 | Pt174 | La1-1 | Lb2-18 |
| Pt175 | La1-1 | Lb2-19 | Pt176 | La1-1 | Lb2-20 |
| Pt177 | La1-1 | Lb2-21 | Pt178 | La1-1 | Lb2-22 |
| Pt179 | La1-1 | Lb2-23 | Pt180 | La1-1 | Lb2-24 |
| Pt181 | La1-1 | Lb2-25 | Pt182 | La1-1 | Lb2-26 |
| Pt183 | La1-1 | Lb2-27 | Pt184 | La1-1 | Lb2-28 |
| Pt185 | La1-1 | Lb2-29 | Pt186 | La1-1 | Lb2-30 |
| Pt187 | La1-1 | Lb3-1 | Pt188 | La1-1 | Lb3-2 |
| Pt189 | La1-1 | Lb3-3 | Pt190 | La1-1 | Lb3-4 |
| Pt191 | La1-1 | Lb3-5 | Pt192 | La1-1 | Lb3-6 |
| Pt193 | La1-1 | Lb3-7 | Pt194 | La1-1 | Lb3-8 |
| Pt195 | La1-1 | Lb3-9 | Pt196 | La1-1 | Lb3-10 |
| Pt197 | La1-1 | Lb3-11 | Pt198 | La1-1 | Lb3-12 |
| Pt199 | La1-1 | Lb3-13 | Pt200 | La1-1 | Lb3-14 |
| Pt201 | La1-1 | Lb3-15 | Pt202 | La1-1 | Lb3-16 |
| Pt203 | La1-1 | Lb3-17 | Pt204 | La1-1 | Lb3-18 |
| Pt205 | La1-1 | Lb3-19 | Pt206 | La1-1 | Lb3-20 |
| Pt207 | La1-1 | Lb3-21 | Pt208 | La1-1 | Lb3-22 |
| Pt209 | La1-1 | Lb3-23 | Pt210 | La1-1 | Lb3-24 |
| Pt211 | La1-1 | Lb3-25 | Pt212 | La1-1 | Lb3-26 |
| Pt213 | La1-9 | Lb1-1 | Pt214 | La1-9 | Lb1-2 |
| Pt215 | La1-9 | Lb1-4 | Pt216 | La1-9 | Lb1-5 |
| Pt217 | La1-9 | Lb1-6 | Pt218 | La1-9 | Lb1-7 |
| Pt219 | La1-9 | Lb1-8 | Pt220 | La1-9 | Lb1-9 |
| Pt221 | La1-9 | Lb1-10 | Pt222 | La1-9 | Lb1-11 |
| Pt223 | La1-9 | Lb1-13 | Pt224 | La1-9 | Lb1-14 |
| Pt225 | La1-9 | Lb1-15 | Pt226 | La1-9 | Lb1-16 |
| Pt227 | La1-9 | Lb1-17 | Pt228 | La1-9 | Lb1-18 |
| Pt229 | La1-9 | Lb1-19 | Pt230 | La1-9 | Lb1-20 |
| Pt231 | La1-9 | Lb1-21 | Pt232 | La1-9 | Lb1-22 |
| Pt233 | La1-9 | Lb2-1 | Pt234 | La1-9 | Lb2-2 |
| Pt235 | La1-9 | Lb2-3 | Pt236 | La1-9 | Lb2-4 |
| Pt237 | La1-9 | Lb2-5 | Pt238 | La1-9 | Lb2-6 |
| Pt239 | La1-9 | Lb2-7 | Pt240 | La1-9 | Lb2-8 |
| Pt241 | La1-9 | Lb2-9 | Pt242 | La1-9 | Lb2-10 |
| Pt243 | La1-9 | Lb2-11 | Pt244 | La1-9 | Lb2-12 |
| Pt245 | La1-9 | Lb2-13 | Pt246 | La1-9 | Lb2-14 |
| Pt247 | La1-9 | Lb2-15 | Pt248 | La1-9 | Lb2-16 |
| Pt249 | La1-9 | Lb2-17 | Pt250 | La1-9 | Lb2-18 |
| Pt251 | La1-9 | Lb2-19 | Pt252 | La1-9 | Lb2-20 |
| Pt253 | La1-9 | Lb2-21 | Pt254 | La1-9 | Lb2-22 |
| Pt255 | La1-9 | Lb2-23 | Pt256 | La1-9 | Lb2-24 |
| Pt257 | La1-9 | Lb2-25 | Pt258 | La1-9 | Lb2-26 |
| Pt259 | La1-9 | Lb2-27 | Pt260 | La1-9 | Lb2-28 |
| Pt261 | La1-9 | Lb2-29 | Pt262 | La1-9 | Lb2-30 |
| Pt263 | La1-9 | Lb3-1 | Pt264 | La1-9 | Lb3-2 |
| Pt265 | La1-9 | Lb3-3 | Pt266 | La1-9 | Lb3-4 |
| Pt267 | La1-9 | Lb3-5 | Pt268 | La1-9 | Lb3-6 |
| Pt269 | La1-9 | Lb3-7 | Pt270 | La1-9 | Lb3-8 |
| Pt271 | La1-9 | Lb3-9 | Pt272 | La1-9 | Lb3-10 |
| Pt273 | La1-9 | Lb3-11 | Pt274 | La1-9 | Lb3-12 |
| Pt275 | La1-9 | Lb3-13 | Pt276 | La1-9 | Lb3-14 |
| Pt277 | La1-9 | Lb3-15 | Pt278 | La1-9 | Lb3-16 |
| Pt279 | La1-9 | Lb3-17 | Pt280 | La1-9 | Lb3-18 |
| Pt281 | La1-9 | Lb3-19 | Pt282 | La1-9 | Lb3-20 |
| Pt283 | La1-9 | Lb3-21 | Pt284 | La1-9 | Lb3-22 |
| Pt285 | La1-9 | Lb3-23 | Pt286 | La1-9 | Lb3-24 |
| Pt287 | La1-9 | Lb3-25 | Pt288 | La1-9 | Lb3-26 |
| Pt289 | La2-1 | Lb1-1 | Pt290 | La2-1 | Lb1-2 |
| Pt291 | La2-1 | Lb1-4 | Pt292 | La2-1 | Lb1-5 |
| Pt293 | La2-1 | Lb1-6 | Pt294 | La2-1 | Lb1-7 |
| Pt295 | La2-1 | Lb1-8 | Pt296 | La2-1 | Lb1-9 |
| Pt297 | La2-1 | Lb1-10 | Pt298 | La2-1 | Lb1-11 |
| Pt299 | La2-1 | Lb1-13 | Pt300 | La2-1 | Lb1-14 |
| Pt301 | La2-1 | Lb1-15 | Pt302 | La2-1 | Lb1-16 |
| Pt303 | La2-1 | Lb1-17 | Pt304 | La2-1 | Lb1-18 |
| Pt305 | La2-1 | Lb1-19 | Pt306 | La2-1 | Lb1-20 |
| Pt307 | La2-1 | Lb1-21 | Pt308 | La2-1 | Lb1-22 |
| Pt309 | La2-1 | Lb2-1 | Pt310 | La2-1 | Lb2-2 |
| Pt311 | La2-1 | Lb2-3 | Pt3 12 | La2-1 | Lb2-4 |
| Pt313 | La2-1 | Lb2-5 | Pt3 14 | La2-1 | Lb2-6 |
| Pt315 | La2-1 | Lb2-7 | Pt316 | La2-1 | Lb2-8 |
| Pt317 | La2-1 | Lb2-9 | Pt318 | La2-1 | Lb2-10 |
| Pt3 19 | La2-1 | Lb2-11 | Pt320 | La2-1 | Lb2-12 |
| Pt321 | La2-1 | Lb2-13 | Pt322 | La2-1 | Lb2-14 |
| Pt323 | La2-1 | Lb2-15 | Pt324 | La2-1 | Lb2-16 |
| Pt325 | La2-1 | Lb2-17 | Pt326 | La2-1 | Lb2-18 |
| Pt327 | La2-1 | Lb2-19 | Pt328 | La2-1 | Lb2-20 |
| Pt329 | La2-1 | Lb2-21 | Pt330 | La2-1 | Lb2-22 |
| Pt331 | La2-1 | Lb2-23 | Pt332 | La2-1 | Lb2-24 |
| Pt333 | La2-1 | Lb2-25 | Pt334 | La2-1 | Lb2-26 |
| Pt335 | La2-1 | Lb2-27 | Pt336 | La2-1 | Lb2-28 |
| Pt337 | La2-1 | Lb2-29 | Pt338 | La2-1 | Lb2-30 |
| Pt339 | La2-1 | Lb3-1 | Pt340 | La2-1 | Lb3-2 |
| Pt341 | La2-1 | Lb3-3 | Pt342 | La2-1 | Lb3-4 |
| Pt343 | La2-1 | Lb3-5 | Pt344 | La2-1 | Lb3-6 |
| Pt345 | La2-1 | Lb3-7 | Pt346 | La2-1 | Lb3-8 |
| Pt347 | La2-1 | Lb3-9 | Pt348 | La2-1 | Lb3-10 |
| Pt349 | La2-1 | Lb3-11 | Pt350 | La2-1 | Lb3-12 |
| Pt351 | La2-1 | Lb3-13 | Pt352 | La2-1 | Lb3-14 |
| Pt353 | La2-1 | Lb3-15 | Pt354 | La2-1 | Lb3-16 |
| Pt355 | La2-1 | Lb3-17 | Pt356 | La2-1 | Lb3-18 |
| Pt357 | La2-1 | Lb3-19 | Pt358 | La2-1 | Lb3-20 |
| Pt359 | La2-1 | Lb3-21 | Pt360 | La2-1 | Lb3-22 |
| Pt361 | La2-1 | Lb3-23 | Pt362 | La2-1 | Lb3-24 |
| Pt363 | La2-1 | Lb3-25 | Pt364 | La2-1 | Lb3-26 |
| Pt365 | La2-2 | Lb1-1 | Pt366 | La2-2 | Lb1-2 |
| Pt367 | La2-2 | Lb1-4 | Pt368 | La2-2 | Lb1-5 |
| Pt369 | La2-2 | Lb1-6 | Pt370 | La2-2 | Lb1-7 |
| Pt371 | La2-2 | Lb1-8 | Pt372 | La2-2 | Lb1-9 |
| Pt373 | La2-2 | Lb1-10 | Pt374 | La2-2 | Lb1-11 |
| Pt375 | La2-2 | Lb1-13 | Pt376 | La2-2 | Lb1-14 |
| Pt377 | La2-2 | Lb1-15 | Pt378 | La2-2 | Lb1-16 |
| Pt379 | La2-2 | Lb1-17 | Pt380 | La2-2 | Lb1-18 |
| Pt381 | La2-2 | Lb1-19 | Pt382 | La2-2 | Lb1-20 |
| Pt383 | La2-2 | Lb1-21 | Pt384 | La2-2 | Lb1-22 |
| Pt385 | La2-2 | Lb2-1 | Pt386 | La2-2 | Lb2-2 |
| Pt387 | La2-2 | Lb2-3 | Pt388 | La2-2 | Lb2-4 |
| Pt389 | La2-2 | Lb2-5 | Pt390 | La2-2 | Lb2-6 |
| Pt391 | La2-2 | Lb2-7 | Pt392 | La2-2 | Lb2-8 |
| Pt393 | La2-2 | Lb2-9 | Pt394 | La2-2 | Lb2-10 |
| Pt395 | La2-2 | Lb2-11 | Pt396 | La2-2 | Lb2-12 |
| Pt397 | La2-2 | Lb2-13 | Pt398 | La2-2 | Lb2-14 |
| Pt399 | La2-2 | Lb2-15 | Pt400 | La2-2 | Lb2-16 |
| Pt401 | La2-2 | L62-17 | Pt402 | La2-2 | Lb2-18 |
| Pt403 | La2-2 | Lb2-19 | Pt404 | La2-2 | Lb2-20 |
| Pt405 | La2-2 | Lb2-21 | Pt406 | La2-2 | Lb2-22 |
| Pt407 | La2-2 | Lb2-23 | Pt408 | La2-2 | Lb2-24 |
| Pt409 | La2-2 | Lb2-25 | Pt410 | La2-2 | Lb2-26 |
| Pt411 | La2-2 | Lb2-27 | Pt412 | La2-2 | Lb2-28 |
| Pt413 | La2-2 | Lb2-29 | Pt414 | La2-2 | Lb2-30 |
| Pt415 | La2-2 | Lb3-1 | Pt416 | La2-2 | Lb3-2 |
| Pt417 | La2-2 | Lb3-3 | Pt418 | La2-2 | Lb3-4 |
| Pt419 | La2-2 | Lb3-5 | Pt420 | La2-2 | Lb3-6 |
| Pt421 | La2-2 | Lb3-7 | Pt422 | La2-2 | Lb3-8 |
| Pt423 | La2-2 | Lb3-9 | Pt424 | La2-2 | Lb3-10 |
| Pt425 | La2-2 | Lb3-11 | Pt426 | La2-2 | Lb3-12 |
| Pt427 | La2-2 | Lb3-13 | Pt428 | La2-2 | Lb3-14 |
| Pt429 | La2-2 | Lb3-15 | Pt430 | La2-2 | Lb3-16 |
| Pt431 | La2-2 | Lb3-17 | Pt432 | La2-2 | Lb3-18 |
| Pt433 | La2-2 | Lb3-19 | Pt434 | La2-2 | Lb3-20 |
| Pt435 | La2-2 | Lb3-21 | Pt436 | La2-2 | Lb3-22 |
| Pt437 | La2-2 | Lb3-23 | Pt438 | La2-2 | Lb3-24 |
| Pt439 | La2-2 | Lb3-25 | Pt440 | La2-2 | Lb3-26 |
| Pt441 | La3-1 | Lb1-1 | Pt442 | La3-1 | Lb1-2 |
| Pt443 | La3-1 | Lb1-4 | Pt444 | La3-1 | Lb1-5 |
| Pt445 | La3-1 | Lb1-6 | Pt446 | La3-1 | Lb1-7 |
| Pt447 | La3-1 | Lb1-8 | Pt448 | La3-1 | Lb1-9 |
| Pt449 | La3-1 | Lb1-10 | Pt450 | La3-1 | Lb1-11 |
| Pt451 | La3-1 | Lb1-13 | Pt452 | La3-1 | Lb1-14 |
| Pt453 | La3-1 | Lb1-15 | Pt454 | La3-1 | Lb1-16 |
| Pt455 | La3-1 | Lb1-17 | Pt456 | La3-1 | Lb1-18 |
| Pt457 | La3-1 | Lb1-19 | Pt458 | La3-1 | Lb1-20 |
| Pt459 | La3-1 | Lb1-21 | Pt460 | La3-1 | Lb1-22 |
| Pt461 | La3-1 | Lb2-1 | Pt462 | La3-1 | Lb2-2 |
| Pt463 | La3-1 | Lb2-3 | Pt464 | La3-1 | Lb2-4 |
| Pt465 | La3-1 | Lb2-5 | Pt466 | La3-1 | Lb2-6 |
| Pt467 | La3-1 | Lb2-7 | Pt468 | La3-1 | Lb2-8 |
| Pt469 | La3-1 | Lb2-9 | Pt470 | La3-1 | Lb2-10 |
| Pt471 | La3-1 | L62-11 | Pt472 | La3-1 | Lb2-12 |
| Pt473 | La3-1 | Lb2-13 | Pt474 | La3-1 | Lb2-14 |
| Pt475 | La3-1 | Lb2-15 | Pt476 | La3-1 | Lb2-16 |
| Pt477 | La3-1 | Lb2-17 | Pt478 | La3-1 | Lb2-18 |
| Pt479 | La3-1 | Lb2-19 | Pt480 | La3-1 | Lb2-20 |
| Pt481 | La3-1 | Lb2-21 | Pt482 | La3-1 | Lb2-22 |
| Pt483 | La3-1 | Lb2-23 | Pt484 | La3-1 | Lb2-24 |
| Pt485 | La3-1 | Lb2-25 | Pt486 | La3-1 | Lb2-26 |
| Pt487 | La3-1 | Lb2-27 | Pt488 | La3-1 | Lb2-28 |
| Pt489 | La3-1 | Lb2-29 | Pt490 | La3-1 | Lb2-30 |
| Pt491 | La3-1 | Lb3-1 | Pt492 | La3-1 | Lb3-2 |
| Pt493 | La3-1 | Lb3-3 | Pt494 | La3-1 | Lb3-4 |
| Pt495 | La3-1 | Lb3-5 | Pt496 | La3-1 | Lb3-6 |
| Pt497 | La3-1 | Lb3-7 | Pt498 | La3-1 | Lb3-8 |
| Pt499 | La3-1 | Lb3-9 | Pt500 | L23-1 | Lb3-10 |
| Pt501 | La3-1 | Lb3-11 | Pt502 | La3-1 | Lb3-12 |
| Pt503 | La3-1 | Lb3-13 | Pt504 | La3-1 | Lb3-14 |
| Pt505 | La3-1 | Lb3-15 | Pt506 | La3-1 | Lb3-16 |
| Pt507 | La3-1 | Lb3-17 | Pt508 | La3-1 | Lb3-18 |
| Pt509 | La3-1 | Lb3-19 | Pt510 | La3-1 | Lb3-20 |
| Pt511 | La3-1 | Lb3-21 | Pt512 | La3-1 | Lb3-22 |
| Pt513 | La3-1 | Lb3-23 | Pt514 | La3-1 | Lb3-24 |
| Pt515 | La3-1 | Lb3-25 | Pt516 | La3-1 | Lb3-26 |
| Pt517 | La3-9 | Lb1-1 | Pt518 | La3-9 | Lb1-2 |
| Pt519 | La3-9 | Lb1-4 | Pt520 | La3-9 | Lb1-5 |
| Pt521 | La3-9 | Lb1-6 | Pt522 | La3-9 | Lb1-7 |
| Pt523 | La3-9 | Lb1-8 | Pt524 | La3-9 | Lb1-9 |
| Pt525 | La3-9 | Lb1-10 | Pt526 | La3-9 | Lb1-11 |
| Pt527 | La3-9 | Lb1-13 | Pt528 | La3-9 | Lb1-14 |
| Pt529 | La3-9 | Lp1-15 | Pt530 | La3-9 | Lb1-16 |
| Pt531 | La3-9 | Lb1-17 | Pt532 | La3-9 | Lb1-18 |
| Pt533 | La3-9 | Lb1-19 | Pt534 | La3-9 | Lb1-20 |
| Pt535 | La3-9 | Lb1-21 | Pt536 | La3-9 | Lb1-22 |
| Pt537 | La3-9 | Lb2-1 | Pt538 | La3-9 | Lb2-2 |
| Pt539 | La3-9 | Lb2-3 | Pt540 | La3-9 | Lb2-4 |
| Pt541 | La3-9 | Lb2-5 | Pt542 | La3-9 | Lb2-6 |
| Pt543 | La3-9 | Lb2-7 | Pt544 | La3-9 | Lb2-8 |
| Pt545 | La3-9 | Lb2-9 | Pt546 | La3-9 | Lb2-10 |
| Pt547 | La3-9 | Lb2-11 | Pt548 | La3-9 | Lb2-12 |
| Pt549 | La3-9 | Lb2-13 | Pt550 | La3-9 | Lb2-14 |
| Pt551 | La3-9 | Lb2-15 | Pt552 | La3-9 | Lb2-16 |
| Pt553 | La3-9 | Lb2-17 | Pt554 | La3-9 | Lb2-18 |
| Pt555 | La3-9 | Lb2-19 | Pt556 | La3-9 | Lb2-20 |
| Pt557 | La3-9 | Lb2-21 | Pt558 | La3-9 | Lb2-22 |
| Pt559 | La3-9 | Lb2-23 | Pt560 | La3-9 | Lb2-24 |
| Pt561 | La3-9 | Lb2-25 | Pt562 | La3-9 | Lb2-26 |
| Pt563 | La3-9 | Lb2-27 | Pt564 | La3-9 | Lb2-28 |
| Pt565 | La3-9 | Lb2-29 | Pt566 | La3-9 | Lb2-30 |
| Pt567 | La3-9 | Lb3-1 | Pt568 | La3-9 | Lb3-2 |
| Pt569 | La3-9 | Lb3-3 | Pt570 | La3-9 | Lb3-4 |
| Pt571 | La3-9 | Lb3-5 | Pt572 | La3-9 | Lb3-6 |
| Pt573 | La3-9 | Lb3-7 | Pt574 | La3-9 | Lb3-8 |
| Pt575 | La3-9 | Lb3-9 | Pt576 | La3-9 | Lb3-10 |
| Pt577 | La3-9 | Lb3-11 | Pt578 | La3-9 | Lb3-12 |
| Pt579 | La3-9 | Lb3-13 | Pt580 | La3-9 | Lb3-14 |
| Pt581 | La3-9 | Lb3-15 | Pt582 | La3-9 | Lb3-16 |
| Pt583 | La3-9 | Lb3-17 | Pt584 | La3-9 | Lb3-18 |
| Pt585 | La3-9 | Lb3-19 | Pt586 | La3-9 | Lb3-20 |
| Pt587 | La3-9 | Lb3-21 | Pt588 | La3-9 | Lb3-22 |
| Pt589 | La3-9 | Lb3-23 | Pt590 | La3-9 | Lb3-24 |
| Pt591 | La3-9 | Lb3-25 | Pt592 | La3-9 | Lb3-26 |
| Pt593 | La4-1 | Lb1-1 | Pt594 | La4-1 | Lb1-2 |
| Pt595 | La4-1 | Lb1-4 | Pt596 | La4-1 | Lb1-5 |
| Pt597 | La4-1 | Lb1-6 | Pt598 | La4-1 | Lb1-7 |
| Pt599 | La4-1 | Lb1-8 | Pt600 | La4-1 | Lb1-9 |
| Pt601 | La4-1 | Lb1-10 | Pt602 | La4-1 | Lb1-11 |
| Pt603 | La4-1 | Lb1-13 | Pt604 | La4-1 | Lb1-14 |
| Pt605 | La4-1 | Lb1-15 | Pt606 | La4-1 | Lb1-16 |
| Pt607 | La4-1 | Lb1-17 | Pt608 | La4-1 | Lb1-18 |
| Pt609 | La4-1 | Lb1-19 | Pt610 | La4-1 | Lb1-20 |
| Pt611 | La4-1 | Lb1-21 | Pt612 | La4-1 | Lb1-22 |
| Pt613 | La4-1 | Lb2-1 | Pt614 | La4-1 | Lb2-2 |
| Pt615 | La4-1 | Lb2-3 | Pt616 | La4-1 | Lb2-4 |
| Pt617 | La4-1 | Lb2-5 | Pt618 | La4-1 | Lb2-6 |
| Pt619 | La4-1 | Lb2-7 | Pt620 | La4-1 | Lb2-8 |
| Pt621 | La4-1 | Lb2-9 | Pt622 | La4-1 | Lb2-10 |
| Pt623 | La4-1 | Lb2-11 | Pt624 | La4-1 | Lb2-12 |
| Pt625 | La4-1 | Lb2-13 | Pt626 | L24-1 | Lb2-14 |
| Pt627 | La4-1 | Lb2-15 | Pt628 | La4-1 | Lb2-16 |
| Pt629 | La4-1 | L62-17 | Pt630 | La4-1 | Lb2-18 |
| Pt631 | La4-1 | Lb2-19 | Pt632 | La4-1 | Lb2-20 |
| Pt633 | La4-1 | Lb2-21 | Pt634 | La4-1 | Lb2-22 |
| Pt635 | La4-1 | Lb2-23 | Pt636 | La4-1 | Lb2-24 |
| Pt637 | La4-1 | Lb2-25 | Pt638 | L24-1 | Lb2-26 |
| Pt639 | La4-1 | Lb2-27 | Pt640 | La4-1 | Lb2-28 |
| Pt641 | La4-1 | Lb2-29 | Pt642 | La4-1 | Lb2-30 |
| Pt643 | La4-1 | Lb3-1 | Pt644 | La4-1 | Lb3-2 |
| Pt645 | La4-1 | Lb3-3 | Pt646 | La4-1 | Lb3-4 |
| Pt647 | La4-1 | Lb3-5 | Pt648 | La4-1 | Lb3-6 |
| Pt649 | La4-1 | Lb3-7 | Pt650 | La4-1 | Lb3-8 |
| Pt651 | La4-1 | Lb3-9 | Pt652 | La4-1 | Lb3-10 |
| Pt653 | La4-1 | Lb3-11 | Pt654 | La4-1 | Lb3-12 |
| Pt655 | La4-1 | Lb3-13 | Pt656 | La4-1 | Lb3-14 |
| Pt657 | La4-1 | Lb3-15 | Pt658 | La4-1 | Lb3-16 |
| Pt659 | La4-1 | Lb3-17 | Pt660 | La4-1 | Lb3-18 |
| Pt661 | La4-1 | Lb3-19 | Pt662 | La4-1 | Lb3-20 |
| Pt663 | La4-1 | Lb3-21 | Pt664 | La4-1 | Lb3-22 |
| Pt665 | La4-1 | Lb3-23 | Pt666 | La4-1 | Lb3-24 |
| Pt667 | La4-1 | Lb3-25 | Pt668 | La4-1 | Lb3-26 |

optionally, hydrogens in structures of Compound Pt1 to Compound Pt668 can be partially or fully substituted with deuterium.

14. An organic electroluminescent device, comprising:
an anode,
a cathode, and
an organic layer disposed between the anode and the cathode, wherein the organic layer comprises the compound of claim 1.

15. The organic electroluminescent device of claim 14, wherein the organic layer is a light-emitting layer, and the compound is a light-emitting material.

16. The organic electroluminescent device of claim 15, wherein the device emits blue light or white light.

17. The organic electroluminescent device of claim 15, wherein the light-emitting layer comprises at least one host material; preferably, the light-emitting layer comprises at least two host materials; and more preferably, the host material comprises at least one chemical group selected from the group consisting of: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

18. A compound composition, comprising the compound of claim 1.
